(19) United States
(12) Patent Application Publication
(10) Pub. No.: US 2024/0377745 A1
(43) Pub. Date: Nov. 14, 2024

(54) SILICON-CONTAINING RESIST UNDERLAYER FILM-FORMING COMPOSITION AND SILICON-CONTAINING RESIST UNDERLAYER FILM

(71) Applicant: NISSAN CHEMICAL CORPORATION, Tokyo (JP)

(72) Inventors: Wataru SHIBAYAMA, Toyama (JP); Satoshi TAKEDA, Toyama (JP); Shuhei SHIGAKI, Toyama (JP); Makoto NAKAJIMA, Toyama (JP)

(73) Assignee: NISSAN CHEMICAL CORPORATION, Tokyo (JP)

(21) Appl. No.: 18/292,733

(22) PCT Filed: Jul. 28, 2022
(86) PCT No.: PCT/JP2022/029045

§ 371 Date: Jan. 26, 2024

(30) Foreign Application Priority Data
Jul. 29, 2021 (JP) 2021-124709

(51) Int. Cl. G03F 7/11; C08G 77/26; C09D 183/08; H01L 21/311

(52) U.S. Cl. CPC G03F 7/11; C08G 77/26; C09D 183/08; H01L 21/31127; H01L 21/31144

(57) ABSTRACT

A silicon-containing resist underlayer film having a maximum optical absorption coefficient (k value) in a wavelength range from 220 nm to 300 nm of 0.05 or greater.

### TECHNICAL FIELD

The present invention relates to a silicon-containing resist underlayer film-forming composition and to a silicon-containing resist underlayer film.

### BACKGROUND ART

In the manufacturing of semiconductor devices, microfabrication through lithography using a photoresist has been implemented. Microfabrication is a processing method in which a thin film of a photoresist is formed on a semiconductor substrate such as a silicon wafer, the thin film is irradiated with actinic rays such as ultraviolet rays through a mask pattern having a pattern of a semiconductor device drawn thereon, the thin film is developed, and the substrate is etched using the resulting photoresist pattern as a protective film, and thereby fine irregularities corresponding to the pattern are formed in the substrate surface.

In recent years, the degree of integration of semiconductor devices has increased, and the wavelength of the actinic ray used has been shortened from KrF excimer lasers (248 nm) to ArF excimer lasers (193 nm). However, as the wavelength of the actinic ray becomes shorter, the influence of reflection of the actinic ray from the semiconductor substrate has become a serious issue. Thus, a method of providing a resist underlayer film called a bottom anti-reflective coating (BARC) between the photoresist and the substrate to be processed has been widely used.

As an underlayer film between the semiconductor substrate and the photoresist, a film known as a hard mask which contains a metal element such as silicon or titanium is used. In this case, the constituent components of the resist differ significantly from those of the hard mask. The speeds at which the resist and the hard mask are removed by dry etching largely depend on the type of gas that is used for dry etching. With appropriate selection of the type of gas, the hard mask can be removed by dry etching without significant reduction in the film thickness of the photoresist. Thus, in the manufacture of semiconductor devices in recent years, a resist underlayer film has been disposed between the semiconductor substrate and the photoresist in this manner in order to achieve various effects including an antireflection effect.

Although compositions for resist underlayer films have been examined in a related art, because the properties required are quite diverse, demands still exist for the development of a novel material for a resist underlayer film. For example, Patent Document 1 discloses a coating-type composition for forming a boron phosphorus glass (BPSG) film containing a structure having a specific silicic acid as a skeleton in response to the issue of forming a wet-etchable film, and Patent Document 2 discloses a composition for forming a silicon-containing resist underlayer film with the composition thereof containing a carbonyl structure in response to the issue of providing a method for removing a mask residue with a chemical liquid after lithography.

### CITATION LIST

### Patent Literature

Patent Document 1: JP 2016-74774 A
Patent Document 2: WO 2018/181989

### SUMMARY OF INVENTION

### Technical Problem

With further miniaturization of resist patterns in cutting edge semiconductor devices in recent years, the demand for a resist underlayer film that can prevent a collapse of the resist pattern has increased.

The present invention was developed in light of such circumstances, and an object thereof is to provide a silicon-containing resist underlayer film that can improve the resolution of a resist pattern by preventing the collapse of a fine resist pattern, and to provide a silicon-containing resist underlayer film-forming composition that can form the silicon-containing resist underlayer film.

### Solution to Problem

As a result of intensive studies to solve the above issues, the present inventors discovered a measure for solving the above issues, and thereby arrived at the present invention, which is outlined as follows.

That is, the present invention includes the following aspects.

[1] A silicon-containing resist underlayer film having a maximum optical absorption coefficient (k value) in a wavelength range from 220 nm to 300 nm of 0.05 or greater.

[2] The silicon-containing resist underlayer film according to [1], including at least one of a nitrophenyl group, a methoxyphenyl sulfonyl group, or a phenanthryl group.

[3] The silicon-containing resist underlayer film according to [1] or [2], wherein the silicon-containing resist underlayer film is a resist underlayer film for use in extreme ultraviolet (EUV) lithography.

[4] A silicon-containing resist underlayer film-forming composition containing:
a polysiloxane as a component [A]; and
a solvent as a component [C],
the polysiloxane including a constituent unit derived from a hydrolyzable silane (A) having at least one of a nitrophenyl group, a methoxyphenyl sulfonyl group, or a phenanthryl group.

[5] A silicon-containing resist underlayer film-forming composition containing:
a polysiloxane as a component [A′];
a hydrolyzable silane (A) as a component [B], the hydrolyzable silane (A) having at least one of a nitrophenyl group, a methoxyphenyl sulfonyl group, or a phenanthryl group; and
a solvent as a component [C].

[6] The silicon-containing resist underlayer film-forming composition according to [4] or [5], wherein the hydrolyzable silane (A) is a compound represented by Formula (A-1):

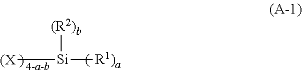

where
a represents an integer from 1 to 3;
b represents an integer from 0 to 2;
a+b represents an integer from 1 to 3;
R¹ represents a group having at least one of a nitrophenyl group, a methoxyphenyl sulfonyl group, or a phenanthryl group, and which may have an ionic bond;
R² represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group (with the proviso that a methoxyphenyl sulfonyl group is excluded), or an organic group having a cyano group, or a combination of two or more thereof;
X represents an alkoxy group, an aralkyloxy group, an acyloxy group, or a halogen atom.
when a plurality of R¹ is present, the plurality of R¹ may be the same or different,
when a plurality of R² is present, the plurality of R² may be the same or different, and
when a plurality of X is present, the plurality of X may be the same or different.

[7] The silicon-containing resist underlayer film-forming composition according to [6], in which R¹ in the Formula (A-1) is represented by Formula (A-2a), Formula (A-2b), or Formula (A-2c):

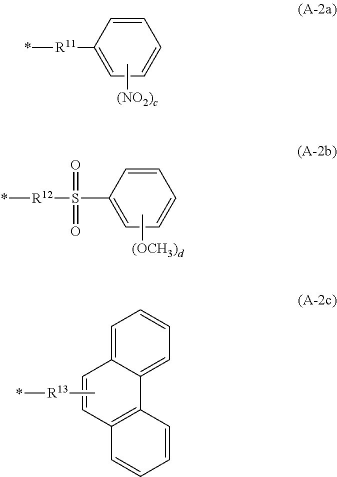

where,
in Formula (A-2a),
R¹¹ represents a single bond or a divalent organic group which may have an ionic bond, c represents an integer from 1 to 5;
in Formula (A-2b),
R¹² represents a divalent organic group that may have an ionic bond, d represents an integer from 1 to 5; and
in Formula (A-2c),
R¹³ represents a single bond or a divalent organic group that may have an ionic bond; and
* represents a bond.

[8] The silicon-containing resist underlayer film-forming composition according to [4], in which the polysiloxane that is the component [A] is a polysiloxane modified product where some silanol groups are alcohol-modified or acetal-protected.

[9] The silicon-containing resist underlayer film-forming composition according to [5], in which the polysiloxane that is the component [A′] is a polysiloxane modified product where some silanol groups are alcohol-modified or acetal-protected.

[10] The silicon-containing resist underlayer film-forming composition according to any one of [4] to [9], in which the component [C] contains an alcohol-based solvent.

[11] The silicon-containing resist underlayer film-forming composition according to [10], in which the component [C] contains a propylene glycol monoalkyl ether.

[12] The silicon-containing resist underlayer film-forming composition according to any one of [4] to [11], further containing a curing catalyst as a component [D].

[13] The silicon-containing resist underlayer film-forming composition according to any one of [4] to [12], further containing nitric acid as a component [E].

[14] The silicon-containing resist underlayer film-forming composition according to any one of [4] to [13], in which the component [C] contains water.

[15] The silicon-containing resist underlayer film-forming composition according to any one of [4] to [14], in which the composition is for forming a resist underlayer film for use in extreme ultraviolet (EUV) lithography.

[16] A silicon-containing resist underlayer film containing a cured product of the silicon-containing resist underlayer film-forming composition described in any one of [4] to [15].

[17] A semiconductor processing substrate including:
a semiconductor substrate; and
the silicon-containing resist underlayer film described in any one of [1] to [3], or the silicon-containing resist underlayer film described in [16].

[18] A method for manufacturing a semiconductor element, the method including:
forming an organic underlayer film on a substrate;
forming a resist underlayer film on the organic underlayer film using the silicon-containing resist underlayer film-forming composition described in any one of [4] to [15]; and
forming a resist film on the resist underlayer film.

[19] The method for manufacturing a semiconductor element according to [18], in which the resist film is formed from a resist for EUV lithography.

[20] The method for manufacturing a semiconductor element according to [18] or [19], in which in the forming the resist underlayer film, a silicon-containing resist underlayer film-forming composition that has been filtered through a nylon filter is used.

[21] A pattern forming method including:
forming an organic underlayer film on a semiconductor substrate;
applying the silicon-containing resist underlayer film-forming composition described in any one of [4] to [15] onto the organic underlayer film and baking the silicon-containing resist underlayer film-forming composition applied thereon to form a resist underlayer film;
applying a resist film-forming composition onto the resist underlayer film to form a resist film;
exposing and developing the resist film to form a resist pattern;
etching the resist underlayer film using the resist pattern as a mask; and
etching the organic underlayer film using the patterned resist underlayer film as a mask.

[22] The pattern forming method according to [21], further including:
removing the resist underlayer film by a wet method using a chemical liquid after etching the organic underlayer film.

[23] The pattern forming method according to [21] or [22], in which the resist film is formed from a resist for EUV lithography.

### Advantageous Effects of Invention

According to the present invention, a silicon-containing resist underlayer film that can improve the resolution of a resist pattern by preventing the collapse of a fine resist pattern, and a silicon-containing resist underlayer film-forming composition that can form the silicon-containing resist underlayer film can be provided.

### DESCRIPTION OF EMBODIMENTS

### Silicon-Containing Resist Underlayer Film

In the silicon-containing resist underlayer film of the present invention, the maximum value of an optical absorption coefficient (k value) in a wavelength range from 220 nm to 300 nm is 0.05 or greater.

The present inventors made the following considerations.

When the silicon-containing resist underlayer film is designed such that the maximum optical absorption coefficient (k value) in a wavelength range from 220 nm to 300 nm is 0.05 or greater, the silicon-containing resist underlayer film can efficiently absorb secondary electrons generated by EUV light. Through such a configuration, high contrast is imparted from the silicon-containing resist underlayer film to the resist for EUV lithography. Therefore, the collapse of the fine resist pattern can be prevented, and as a result, the resolution of the resist pattern can be increased.

The optical absorption coefficient (k value) in the wavelength range from 220 nm to 300 nm can be determined using a spectroscopic ellipsometer (for example, the VUV-VASE VU-302, available from the J.A. Woollam Company). The k value is calculated by the Cauchy dispersion equation and point-by-point fitting.

The upper limit value of the maximum optical absorption coefficient (k value) in the wavelength range from 220 nm to 300 nm is not particularly limited, but the maximum optical absorption coefficient (k value) in the wavelength range from 220 nm to 300 nm may be, for example, 0.30 or less, 0.25 or less, or 0.20 or less.

The silicon-containing resist underlayer film preferably has at least one of a nitrophenyl group, a methoxyphenyl sulfonyl group, or a phenanthryl group. A nitrophenyl group, a methoxyphenyl sulfonyl group, and a phenanthryl group are groups having high absorption of light in a wavelength range from 200 to 300 nm.

The silicon-containing resist underlayer film preferably has a group represented by Formula (A-2a), Formula (A-2b) or Formula (A-2c), which are described later.

The type of lithography in which the silicon-containing resist underlayer film is used is not particularly limited, but EUV lithography is preferable. That is, the silicon-containing resist underlayer film is preferably a resist underlayer film for EUV lithography.

The thickness of the silicon-containing resist underlayer film is, for example, from 10 nm to 10000 nm, from 100 nm to 2000 nm, from 200 nm to 1000 nm, or from 30 nm to 200 nm.

The method for manufacturing the silicon-containing resist underlayer film of the present invention is not particularly limited, but the silicon-containing resist underlayer film of the present invention is preferably formed from the below-described silicon-containing resist underlayer film-forming composition of the present invention.

### Silicon-Containing Resist Underlayer Film-Forming Composition

### First Embodiment

A first embodiment of a silicon-containing resist underlayer film-forming composition of the present invention contains a polysiloxane as a component [A], and a solvent as a component [C], and may further contain other components as necessary.

The polysiloxane as the component [A] includes a constituent unit (monomer unit or repeating unit) derived from a hydrolyzable silane (A) having at least one of a nitrophenyl group, a methoxyphenyl sulfonyl group, or a phenanthryl group.

Hereinafter, “at least one of a nitrophenyl group, a methoxyphenyl sulfonyl group, or a phenanthryl group” may be referred to as a “specific group”.

### Second Embodiment

A second embodiment of the silicon-containing resist underlayer film-forming composition of the present invention contains a polysiloxane as a component [A′], a hydrolyzable silane (A) as a component [B], the hydrolyzable silane (A) having at least one of a nitrophenyl group, a methoxyphenyl sulfonyl group, or a phenanthryl group, and a solvent as a component [C], and may further contain other components as necessary.

Note that in the present invention, the phenyl group of the nitrophenyl group may be substituted with a plurality of nitro groups.

Also, in the present invention, the phenyl group of the methoxyphenyl sulfonyl group may be substituted with a plurality of methoxy groups.

In addition, in the present invention, an oxygen atom other than the oxygen atom constituting the sulfonyl (—SO₂—) may be bonded to the sulfur atom of the methoxyphenyl sulfonyl group, or a nitrogen atom may be bonded to the sulfur atom thereof.

The present inventors made the following considerations.

When the silicon-containing resist underlayer film formed from the silicon-containing resist underlayer film-forming composition of the present invention has the specific group, collapse of a fine resist pattern can be prevented, and as a result, the resolution of the resist pattern can be increased. When the silicon-containing resist underlayer film has a group having high absorption with respect to light of wavelengths from 200 to 300 nm, such as the specific group, secondary electrons generated from the resist and the resist underlayer film by irradiation with EUV light can be efficiently absorbed. Through such a configuration, high contrast is imparted from the resist underlayer film to the resist for EUV lithography. Therefore, the collapse of the fine resist pattern can be prevented, and as a result, the resolution of the resist pattern can be increased.

### Hydrolyzable Silane (A) Having Specific Group

The specific group of the hydrolyzable silane (A) having the specific group is usually bonded to a silicon atom via a linking group.

The hydrolyzable silane (A) may have two or more specific groups. In this case, each of the two or more specific groups may be bonded to one linking group that is bonded to the silicon atom, or each of the two or more specific groups may be bonded to the silicon atom via different linking groups.

The linking group is, for example, an organic group. The linking group may have an ionic bond. When the linking group has an ionic bond, the linking group may have an ionic bond in a row of atoms connecting the specific group and the silicon atom, or may have an ionic bond in a row of atoms branched from the row of atoms connecting the specific group and the silicon atom.

The number of carbon atoms of the linking group is not particularly limited, but the number of carbon atoms of the linking group is preferably from 1 to 30, and more preferably from 1 to 20.

The linking group usually has a hydrogen atom. The linking group may have an oxygen atom or may have a nitrogen atom.

The hydrolyzable silane (A) having the specific group is preferably a compound represented by Formula (A-1).

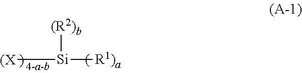

In Formula (A-1), a represents an integer from 1 to 3.
b represents an integer from 0 to 2.
a+b represents an integer from 1 to 3.
R¹ represents a group having at least one of a nitrophenyl group, a methoxyphenyl sulfonyl group, or a phenanthryl group and which may have an ionic bond.
R² represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group (with the proviso that a methoxyphenyl sulfonyl group is excluded), or an organic group having a cyano group, or a combination of two or more thereof.
X represents an alkoxy group, an aralkyloxy group, an acyloxy group, or a halogen atom.
when a plurality of R¹ is present, the plurality of R¹ may be the same or different,
when a plurality of R² is present, the plurality of R² may be the same or different, and
when a plurality of X is present, the plurality of X may be the same or different.

### R¹ in Formula (A-1)

R¹ may have one specific group or a plurality of specific groups.

The number of carbon atoms in R¹ is not particularly limited, but is preferably from 1 to 30, and more preferably from 1 to 20.

R¹ usually has a hydrogen atom. R¹ may have an oxygen atom or a nitrogen atom in addition to the specific group and hydrogen atom.

R¹ may have an ionic bond. When R¹ has an ionic bond, the R¹ may have an ionic bond in a row of atoms connecting the specific group and the silicon atom, or may have an ionic bond in a row of atoms branched from the row of atoms connecting the specific group and the silicon atom.

R¹ in Formula (A-1) is preferably represented by Formula (A-2a), Formula (A-2b), or Formula (A-2c).

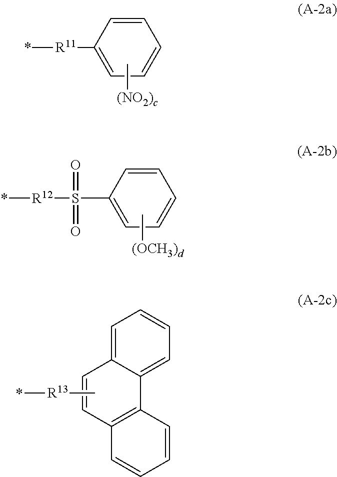

In Formula (A-2a), R¹¹ represents a single bond or a divalent organic group which may have an ionic bond. c represents an integer from 1 to 5.

In Formula (A-2b), R¹² represents a divalent organic group that may have an ionic bond. d represents an integer from 1 to 5.

In Formula (A-2c), R¹³ represents a single bond or a divalent organic group that may have an ionic bond.

* represents a bond.

The number of carbon atoms of each of R¹¹ to R¹³ is not particularly limited, but the number of carbon atoms of each of R¹¹ to R¹³ is independently preferably from 1 to 25, and more preferably from 1 to 15.

R¹ may have, in addition to the specific group, a hydrogen atom, an oxygen atom, or a nitrogen atom.

R¹ may have an ionic bond. When R¹ has an ionic bond, the R¹ may have an ionic bond in a row of atoms connecting the specific group and the silicon atom, or may have a nitro group in a row of atoms branched from the row of atoms connecting the specific group and the silicon atom.

c is preferably an integer from 1 to 3.

d is preferably an integer from 1 to 3, and more preferably 1.

In Formula (A-2a), the nitro group is preferably bonded to the benzene ring at the ortho-position or the para-position in relation to the position to which R¹¹ is bonded, and is more preferably bonded to the benzene ring at the para-position.

In Formula (A-2b), the methoxy group is preferably bonded to the benzene ring at the ortho-position or the para-position, and more preferably at the para-position, in relation to the position at which the sulfur atom is bonded.

R¹¹ to R¹³

R¹¹ is preferably a single bond or any one of divalent organic groups represented by Formula (A-2-1) to Formula (A-2-7), Formula (A-2-10), and Formula (A-2-11).

R¹² is preferably any one of divalent organic groups represented by Formulas (A-2-1), (A-2-3), (A-2-8) and (A-2-9).

R¹³ is preferably a single bond or any one of divalent organic groups represented by Formula (A-2-1) to Formula (A-2-7), Formula (A-2-10), and Formula (A-2-11).

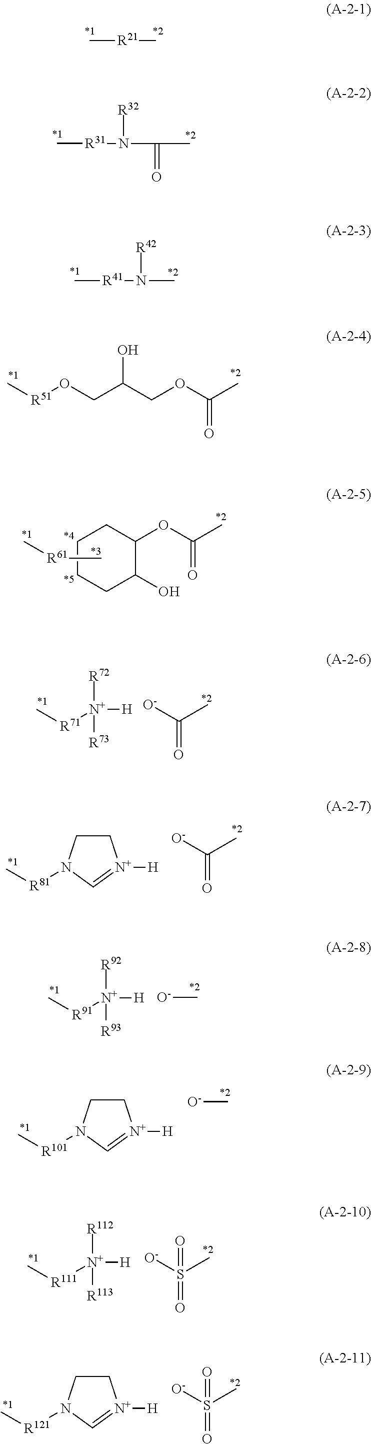

In Formula (A-2-1), R²¹ represents an alkylene group having from 1 to 6 carbon atoms.

In Formula (A-2-2), R³¹ represents an alkylene group having from 1 to 6 carbon atoms. R³² represents a hydrogen atom or an alkyl group having from 1 to 4 carbon atoms.

In Formula (A-2-3), R⁴¹ represents an alkylene group having from 1 to 6 carbon atoms. R⁴² represents a hydrogen atom or an alkyl group having from 1 to 4 carbon atoms.

In Formula (A-2-4), R⁵¹ represents an alkylene group having from 1 to 6 carbon atoms.

In Formula (A-2-5), R⁶¹ represents an alkylene group having from 1 to 6 carbon atoms.

In Formula (A-2-6), R⁷¹ represents an alkylene group having from 1 to 6 carbon atoms. R⁷² and R⁷³ each independently represent a hydrogen atom or an alkyl group having from 1 to 4 carbon atoms.

In Formula (A-2-7), R⁸¹ represents an alkylene group having from 1 to 6 carbon atoms.

In formula (A-2-8), R⁹¹ represents an alkylene group having from 1 to 6 carbon atoms. R⁹² and R⁹³ each independently represent a hydrogen atom or an alkyl group having from 1 to 4 carbon atoms.

In Formula (A-2-9), R¹⁰¹ represents an alkylene group having from 1 to 6 carbon atoms.

In Formula (A-2-10), R¹¹¹ represents an alkylene group having from 1 to 6 carbon atoms. R¹¹² and R¹¹³ each independently represent a hydrogen atom or an alkyl group having from 1 to 4 carbon atoms.

In Formula (A-2-11), R¹²¹ represents an alkylene group having from 1 to 6 carbon atoms.

In Formula (A-2-1) to Formula (A-2-11), *1 represents a bond bonded to Si. Further, *2 represents a bond bonded to the benzene ring in Formula (A-2a), a bond bonded to the sulfur atom in Formula (A-2b), or a bond bonded to the phenanthrene ring in Formula (A-2c).

In Formula (A-2-5), *3 represents a bond bonded to a carbon atom of *4 or *5.

Note that in the silicon-containing resist underlayer film-forming composition and the resist underlayer film, the amino group (—N(R⁴²)—) in Formula (A-2-3) may be cationized. For example, when nitric acid is added to the silicon-containing resist underlayer film-forming composition, the amino group (—N(R⁴²)—) in Formula (A-2-3) may be cationized to form a nitrate.

The alkylene group having from 1 to 6 carbon atoms in R²¹, R³¹, R⁴¹, R¹, R⁶¹, R⁷¹ R⁸¹, R⁹¹, R¹⁰¹, R¹¹¹, and R¹²¹ may be linear or branched. Examples of the alkylene group having from 1 to 6 carbon atoms include linear alkylene groups such as a methylene group, an ethylene group, a trimethylene group, a tetramethylene group, a pentamethylene group, and a hexamethylene group. Among these, a methylene group, an ethylene group, a trimethylene group and a tetramethylene group are preferable.

The alkyl group having from 1 to 4 carbon atoms in R³², R⁴², R⁷², R⁷³, R⁹², R⁹³ R¹¹², and R¹¹³ may be linear or branched. Examples of the alkyl group having from 1 to 4 carbon atoms include a methyl group, an ethyl group, an n-propyl group, an i-propyl group, an n-butyl group, an i-butyl group, an s-butyl group, and a t-butyl group.

R³², R⁴², R⁷², R⁷³, R⁹², R⁹³, R¹¹², and R¹¹³ are preferably a hydrogen atom, a methyl group, or an ethyl group.

### R² in Formula (A-1)

The alkyl group may be linear, branched, or cyclic, and the number of carbon atoms thereof is not particularly limited, but is preferably 40 or less, more preferably 30 or less, even more preferably 20 or less, and still more preferably 10 or less.

For the alkyl group, specific examples of linear or branched alkyl groups include a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

Note that in the present specification, “i” means “iso”, “s” means “sec”, and “t” means “tert”.

Specific examples of cyclic alkyl groups include cycloalkyl groups, such as a cyclopropyl group, a cyclobutyl group, a i-methyl-cyclopropyl group, a 2-methyl-cyclopropyl group, a cyclopentyl group, a i-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a i-ethyl-cyclopropyl group, a 2-ethyl-cyclopropyl group, a cyclohexyl group, a i-methyl-cyclopentyl group, a 2-methyl-cyclopentyl group, a 3-methyl-cyclopentyl group, a i-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group, and bridged cyclic-type cycloalkyl groups, such as a bicyclobutyl group, a bicyclopentyl group, a bicyclohexyl group, a bicycloheptyl group, a bicyclooctyl group, a bicyclononyl group, and a bicyclodecyl group.

The aryl group may be any of a phenyl group, a monovalent group derived by removing one hydrogen atom from a condensed ring aromatic hydrocarbon compound, and a monovalent group derived by removing one hydrogen atom from a ring-linked aromatic hydrocarbon compound, and the number of carbon atoms thereof is not particularly limited, but is preferably 40 or less, more preferably 30 or less, and still more preferably 20 or less.

Examples of the aryl group include aryl groups having from 6 to 20 carbon atoms, and specific examples include, but are not limited to, a phenyl group, a 1-naphthyl group, a 2-naphthyl group, a 1-anthryl group, a 2-anthryl group, a 9-anthryl group, a 1-naphthacenyl group, a 2-naphthacenyl group, a 5-naphthacenyl group, a 2-chrysenyl group, a 1-pyrenyl group, a 2-pyrenyl group, a pentacenyl group, a benzopyrenyl group, a triphenylenyl group, a biphenyl-2-yl group (o-biphenylyl group), a biphenyl-3-yl group (m-biphenylyl group), a biphenyl-4-yl group (p-biphenylyl group), a para-terphenyl-4-yl group, a meta-terphenyl-4-yl group, an ortho-terphenyl-4-yl group, a 1,1′-binaphthyl-2-yl group, and a 2,2′-binaphthyl-1-yl group.

The aralkyl group is an alkyl group substituted with an aryl group, and specific examples of such aryl groups and alkyl groups are the same as those described above. The number of carbon atoms of the aralkyl group is not particularly limited, but is preferably 40 or less, more preferably 30 or less, and even more preferably 20 or less.

Specific examples of the aralkyl group include, but are not limited to, a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, and a 10-phenyl-n-decyl group.

The halogenated alkyl group, the halogenated aryl group, and the halogenated aralkyl group are, respectively, an alkyl group, an aryl group, and an aralkyl group, which are substituted with one or more halogen atoms, and specific examples of such alkyl groups, aryl groups, and aralkyl groups are the same as those described above.

Examples of the halogen atom include a fluorine atom, a chlorine atom, a bromine atom, and an iodine atom.

The number of carbon atoms of the halogenated alkyl group is not particularly limited, but is preferably 40 or less, more preferably 30 or less, even more preferably 20 or less, and still more preferably 10 or less.

Specific examples of the halogenated alkyl group include, but are not limited to, a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1,1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropan-2-yl group, a 3-bromo-2-methylpropyl group, a 4-bromobutyl group, and a perfluoropentyl group.

The number of carbon atoms of the halogenated aryl group is not particularly limited, but is preferably 40 or less, more preferably 30 or less, and even more preferably 20 or less.

Specific examples of the halogenated aryl group include, but are not limited to, a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, a 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, a heptafluoro-2-naphthyl group, and also groups in which a fluorine atom (fluoro group) of these groups is optionally substituted with a chlorine atom (chloro group), a bromine atom (bromo group), or an iodine atom (iodine group).

The number of carbon atoms of the halogenated aralkyl group is not particularly limited, but is preferably 40 or less, more preferably 30 or less, and still more preferably 20 or less.

Specific examples of the halogenated aralkyl group include, but are not limited to, a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, a 2,3,4,5,6-pentafluorobenzyl group, and also groups in which a fluorine atom (fluoro group) of these groups is optionally substituted with a chlorine atom (chloro group), a bromine atom (bromo group), or an iodine atom (iodo group).

The alkoxyalkyl group, the alkoxyaryl group, and the alkoxyaralkyl group are, respectively, an alkyl group, an aryl group, and an aralkyl group, substituted with one or more alkoxy groups, and specific examples of such alkyl groups, aryl groups, and aralkyl groups include the same groups as those described above.

Examples of the alkoxy group as a substituent include alkoxy groups having at least any of a linear, branched, or cyclic alkyl moiety having from 1 to 20 carbon atoms.

Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

Specific examples of the alkoxyalkyl group include, but are not limited to, lower (around 5 carbon atoms or less) alkyloxy-lower (around 5 carbon atoms or less) alkyl groups, such as a methoxymethyl group, an ethoxymethyl group, a 1-ethoxyethyl group, a 2-ethoxyethyl group, and an ethoxymethyl group.

Specific examples of the alkoxyaryl group include, but are not limited to, a 2-methoxyphenyl group, a 3-methoxyphenyl group, a 4-methoxyphenyl group, a 2-(1-ethoxy)phenyl group, a 3-(1-ethoxy)phenyl group, a 4-(1-ethoxy)phenyl group, a 2-(2-ethoxy)phenyl group, a 3-(2-ethoxy)phenyl group, a 4-(2-ethoxy)phenyl group, a 2-methoxynaphthalen-1-yl group, a 3-methoxynaphthalen-1-yl group, a 4-methoxynaphthalen-1-yl group, a 5-methoxynaphthalen-1-yl group, a 6-methoxynaphthalen-1-yl group, and a 7-methoxynaphthalen-1-yl group.

Specific examples of the alkoxyaralkyl group include, but are not limited to, a 3-(methoxyphenyl)benzyl group and a 4-(methoxyphenyl)benzyl group.

The alkenyl group may be linear or branched, and the number of carbon atoms thereof is not particularly limited, but is preferably 40 or less, more preferably 30 or less, even more preferably 20 or less, and still more preferably 10 or less.

Specific examples of the alkenyl group include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group, and can also include a bridged cyclic-type alkenyl group, such as a bicycloheptenyl group (norbornyl group).

Examples of substituents in the above-described alkyl groups, aryl groups, aralkyl groups, halogenated alkyl groups, halogenated aryl groups, halogenated aralkyl groups, alkoxyalkyl groups, alkoxyaryl groups, alkoxyaralkyl groups, and alkenyl groups include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group, and specific examples of such substituents and the preferable numbers of carbon atoms thereof are the same as those described above and below.

The aryloxy group mentioned as a substituent is a group in which an aryl group is bonded via an oxygen atom (—O−), and specific examples of such an aryl group include the same groups as those mentioned above. The number of carbon atoms of the aryloxy group is not particularly limited, but is preferably 40 or less, more preferably 30 or less, and even more preferably 20 or less, and specific examples thereof include, but are not limited to, a phenoxy group and a naphthalen-2-yloxy group.

Further, when two or more substituents are present, the substituents may be bonded to each other to form a ring.

Examples of the organic group having an epoxy group include a glycidoxymethyl group, a glycidoxyethyl group, a glycidoxypropyl group, a glycidoxybutyl group, and an epoxycyclohexyl group.

Examples of the organic group having an acryloyl group include an acryloyloxymethyl group, an acryloyloxyethyl group, and an acryloyloxypropyl group.

Examples of the organic group having a methacryloyl group include a methacryloyloxymethyl group, a methacryloyloxyethyl group, and a methacryloyloxypropyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include, but are not limited to, an amino group, an aminomethyl group, an aminoethyl group, an aminophenyl group, a dimethylaminoethyl group, and a dimethylaminopropyl group. The organic group having an amino group will be described in more detail later.

Examples of the organic group having an alkoxy group include, but are not limited to, a methoxymethyl group and a methoxyethyl group. However, a group in which an alkoxy group is directly bonded to a silicon atom is excluded.

Examples of the organic group having a sulfonyl group include, but are not limited to, a sulfonylalkyl group and a sulfonylaryl group.

Examples of the organic group having a cyano group include a cyanoethyl group, a cyanopropyl group, a cyanophenyl group, and a thiocyanate group.

Examples of the organic group having an amino group include an organic group having at least one of a primary amino group, a secondary amino group, or a tertiary amino group. A hydrolysis-condensation product produced by hydrolyzing a hydrolyzable silane having a tertiary amino group with a strong acid to form a counter cation having a tertiary ammonium group can be preferably used. The organic group may contain a hetero atom such as an oxygen atom or a sulfur atom in addition to the nitrogen atom constituting the amino group.

Preferred examples of the amino group-containing organic group include groups represented by Formula (A1).

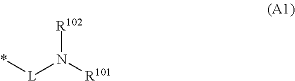

In Formula (A1), R¹⁰¹ and R¹⁰² each independently represent a hydrogen atom or a hydrocarbon group, and each L independently represents an optionally substituted alkylene group. * represents a bond.

Examples of the hydrocarbon group include, but are not limited to, an alkyl group, an alkenyl group, and an aryl group. Specific examples of these alkyl groups, alkenyl groups, and aryl groups are the same as those described above for R².

The alkylene group may be linear or branched, and the number of carbon atoms thereof is usually from 1 to 10, and preferably from 1 to 5. Examples thereof include linear alkylene groups, such as a methylene group, an ethylene group, a trimethylene group, a tetramethylene group, a pentamethylene group, a hexamethylene group, a heptamethylene group, an octamethylene group, a nonamethylene group, and a decamethylene group.

Examples of the organic group having an amino group include, but are not limited to, an amino group, an aminomethyl group, an aminoethyl group, an aminophenyl group, a dimethylaminoethyl group, and a dimethylaminopropyl group.

### X in Formula (A-1)

Examples of the alkoxy group in X include the alkoxy groups exemplified in the description of R².

Examples of the halogen atom in X include the halogen atoms exemplified in the description of R².

The aralkyloxy group is a monovalent group derived by removing a hydrogen atom from a hydroxy group of an aralkyl alcohol, and specific examples of the aralkyl group in the aralkyloxy group include the same groups as those described above.

The number of carbon atoms of the aralkyloxy group is not particularly limited, and may be, for example, 40 or less, preferably 30 or less, and more preferably 20 or less.

Specific examples of the aralkyloxy group include, but are not limited to, a phenylmethyloxy group (benzyloxy group), a 2-phenylethyleneoxy group, a 3-phenyl-n-propyloxy group, a 4-phenyl-n-butyloxy group, a 5-phenyl-n-pentyloxy group, a 6-phenyl-n-hexyloxy group, a 7-phenyl-n-heptyloxy group, an 8-phenyl-n-octyloxy group, a 9-phenyl-n-nonyloxy group, and a 10-phenyl-n-decyloxy group.

The acyloxy group is a monovalent group derived by removing a hydrogen atom from a carboxyl group (—COOH) of a carboxylic acid compound, and typical examples thereof include, but are not limited to, an alkylcarbonyloxy group, an arylcarbonyloxy group, and an aralkylcarbonyloxy group, which are derived by removing a hydrogen atom from a carboxyl group of an alkylcarboxylic acid, an arylcarboxylic acid, or an aralkylcarboxylic acid. Specific examples of the alkyl group, the aryl group, and the aralkyl group in the alkylcarboxylic acid, the arylcarboxylic acid, and the aralkylcarboxylic acid include the same groups as those described above.

Specific examples of the acyloxy group include acyloxy groups having from 2 to 20 carbon atoms, such as a methylcarbonyloxy group, an ethylcarbonyloxy group, an n-propylcarbonyloxy group, an i-propylcarbonyloxy group, an n-butylcarbonyloxy group, an i-butylcarbonyloxy group, an s-butylcarbonyloxy group, a t-butylcarbonyloxy group, an n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, an n-hexylcarbonyloxy group, a 1-methyl-n-pentylcarbonyloxy group, a 2-methyl-n-pentylcarbonyloxy group, a 3-methyl-n-pentylcarbonyloxy group, a 4-methyl-n-pentylcarbonyloxy group, a 1,1-dimethyl-n-butylcarbonyloxy group, a 1,2-dimethyl-n-butylcarbonyloxy group, a 1,3-dimethyl-n-butylcarbonyloxy group, a 2,2-dimethyl-n-butylcarbonyloxy group, a 2,3-dimethyl-n-butylcarbonyloxy group, a 3,3-dimethyl-n-butylcarbonyloxy group, a 1-ethyl-n-butylcarbonyloxy group, a 2-ethyl-n-butylcarbonyloxy group, a 1,1,2-trimethyl-n-propylcarbonyloxy group, a 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, and a tosylcarbonyloxy group.

Specific examples of the hydrolyzable silane (A) having the specific group include the following compounds, but the hydrolyzable silane (A) having the specific group is not limited to these compounds:

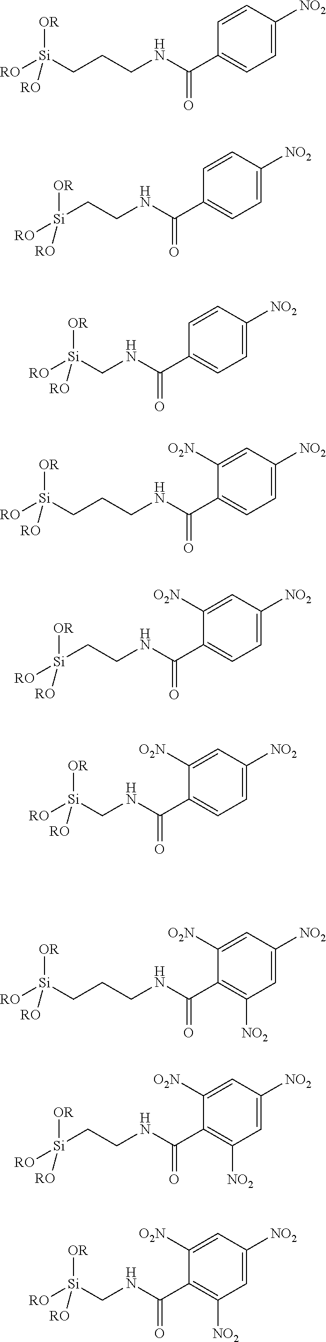

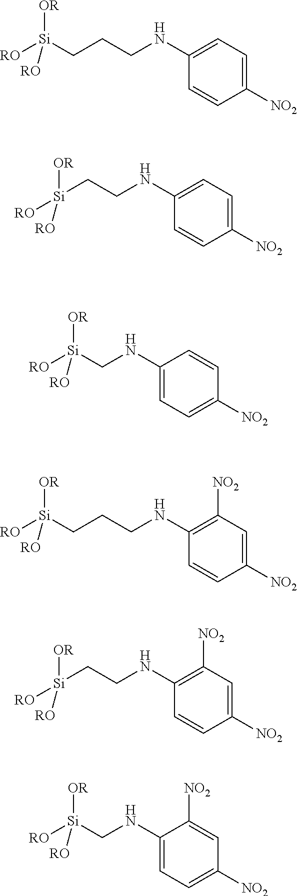

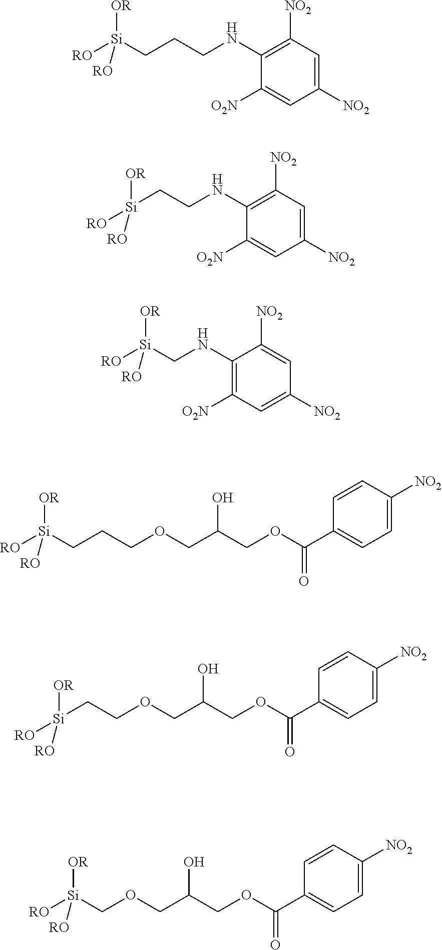

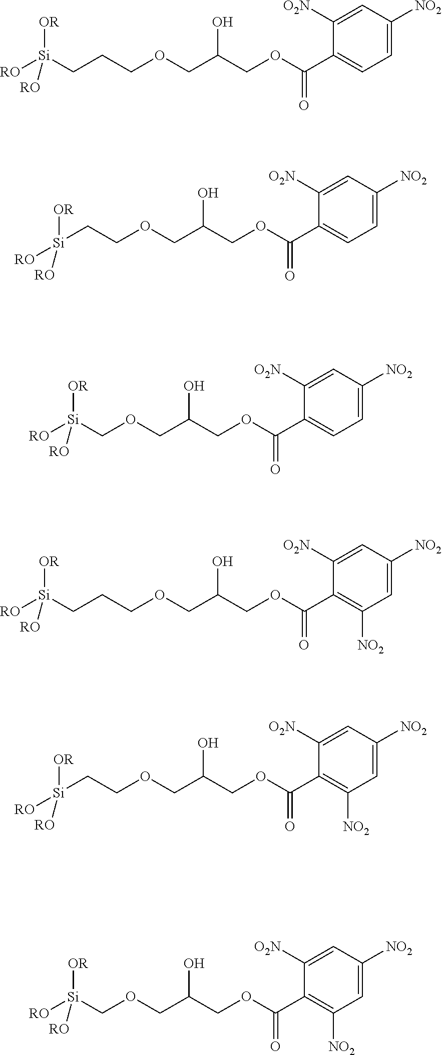

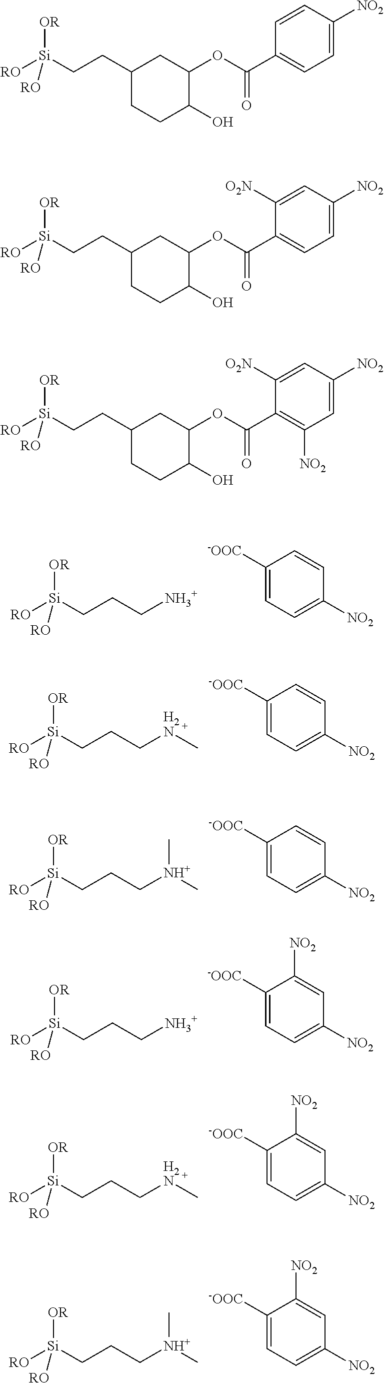

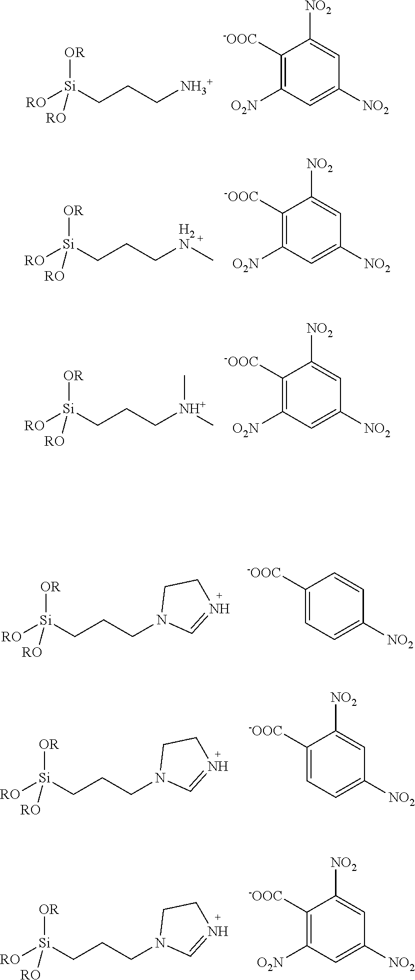

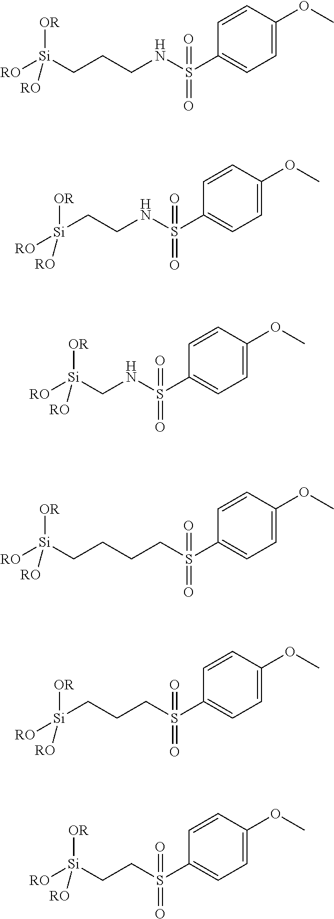

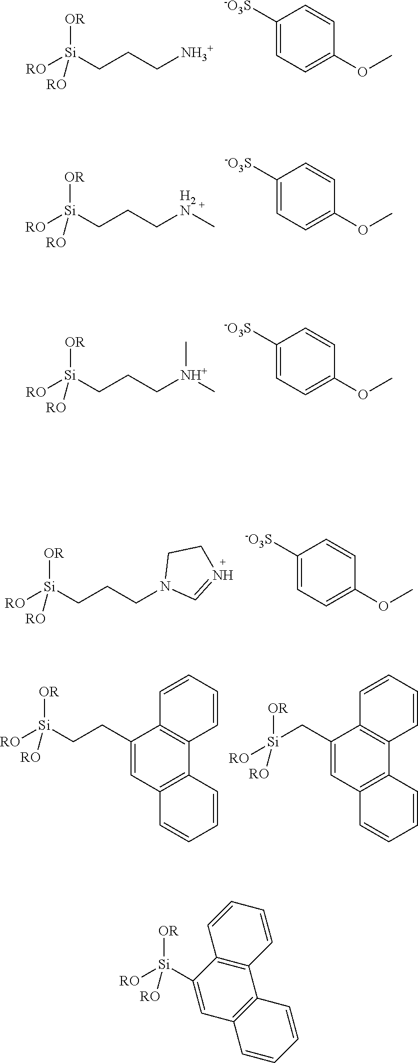

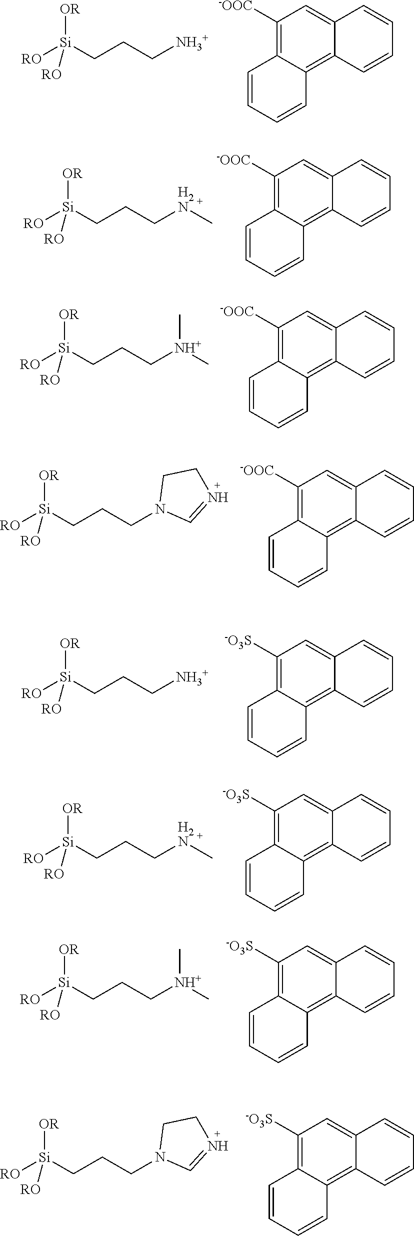

where R represents a methyl group or an ethyl group.

In the first embodiment, from the viewpoint of more sufficiently achieving the effects of the present invention, the amount of the hydrolyzable silane (A) having the specific group when synthesizing the polysiloxane [A] containing a structural unit derived from the hydrolyzable silane (A) is preferably from 0.01 to 100 parts by mass, more preferably from 0.05 to 50 parts by mass, even more preferably from 0.1 to 30 parts by mass, and particularly preferably 1 to 20 parts by mass, per a total amount of 100 parts by mass of the hydrolyzable silane used in synthesizing the polysiloxane.

In the second embodiment, from the viewpoint of more sufficiently achieving the effects of the present invention, the content of the component [B], namely the hydrolyzable silane (A) having the specific group, in the silicon-containing resist underlayer film-forming composition is preferably from 0.01 to 100 parts by mass, more preferably from 0.05 to 50 parts by mass, and even more preferably from 0.1 to 30 parts by mass, and particularly preferably from 1 to 20 parts by mass, per 100 parts by mass of the polysiloxane [A′].

### Component [A] and Component [A′]: Polysiloxane

The polysiloxane as the component [A] is not particularly limited as long as it is a polymer having a siloxane bond and containing a structural unit derived from a hydrolyzable silane (A) having the specific group.

The polysiloxane as the component [A′] is not particularly limited as long as it is a polymer having a siloxane bond. The polysiloxane as the component [A′] may be the polysiloxane of the component [A].

The polysiloxane may be a modified polysiloxane in which some of the silanol groups are modified, such as for example, a polysiloxane modified product in which some of the silanol groups are alcohol-modified or acetal-protected.

In addition, the polysiloxane may be, as one example, a hydrolysis-condensation product of a hydrolyzable silane, and may be a modified product in which at least some silanol groups of the hydrolysis-condensation product are alcohol-modified or acetal-protected (hereinafter, may be referred to as a “modified product of a hydrolysis-condensation product”). The hydrolyzable silane pertaining to the hydrolysis-condensation product may include one type or two or more types of hydrolyzable silanes.

The polysiloxane as the component [A] or the component [A′] may have a structure having any one of a cage-type, a ladder-type, a linear-type, or a branched-type main chain. Furthermore, commercially available polysiloxanes can be used for the polysiloxane as the component [A′].

In the present invention, the “hydrolysis-condensation product” of the hydrolyzable silane, that is, the product of hydrolysis and condensation, includes not only a polyorganosiloxane polymer that is a condensate in which condensation is fully completed, but also a polyorganosiloxane polymer that is a partial hydrolysis-condensation product in which condensation is not fully completed. Similar to the condensate in which condensation is fully completed, such a partial hydrolysis-condensation product is also a polymer that is resulting from hydrolysis and condensation of a hydrolyzable silane, but the reaction is terminated by partial hydrolysis such that condensation does not fully occur, and therefore, Si—OH groups remain. Furthermore, in the silicon-containing resist underlayer film-forming composition, a non-condensed hydrolysate (complete hydrolysate or partial hydrolysate) or monomer (hydrolyzable silane) may remain in addition to the hydrolysis-condensation product.

Note that in the present specification, the term “hydrolyzable silane” may be simply referred to as a “silane compound”.

Examples of the polysiloxane as the component [A] include hydrolysis-condensation products of hydrolyzable silanes, or modified products thereof, the hydrolyzable silanes including the hydrolyzable silane (A) having the specific group.

Examples of the polysiloxane as the component [A] include hydrolysis-condensation products of hydrolyzable silanes, or modified products thereof, the hydrolyzable silanes including the hydrolyzable silane (A) having the specific group and at least one type of hydrolyzable silane represented by Formula (1).

Examples of the polysiloxane of the component [A′] include hydrolysis-condensation products of hydrolyzable silanes, or modified products thereof, the hydrolyzable silanes including at least one hydrolyzable silane represented by Formula (1).

Formula (1)

R¹ₐSi(R²)₄₋ₐ (1)

In Formula (1), R¹ is a group bonded to a silicon atom and each independently represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group (with the proviso that a methoxyphenyl sulfonyl group is excluded), or an organic group having a cyano group, or a combination of two or more thereof.

R² is a group or atom bonded to a silicon atom, and each independently represents an alkoxy group, an aralkyloxy group, an acyloxy group, or a halogen atom.

a represents an integer from 0 to 3.

Specific examples of each group and atoms of R¹ in Formula (1) and the preferable number of carbon atoms thereof include the groups and number of carbon atoms described above with regard to R² in Formula (A-1).

Specific examples of each group and atoms of R² in Formula (1) and the preferable number of carbon atoms thereof include the groups, atoms, and number of carbon atoms described above with regard to X in Formula (A-1).

Specific Examples of Hydrolyzable Silane Represented by Formula (1) Specific examples of the hydrolyzable silane represented by Formula (1) include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyl trimethoxysilane, methyl trichlorosilane, methyl triacetoxysilane, methyl triethoxysilane, methyl tripropoxysilane, methyl tributoxysilane, methyl triamyloxysilane, methyl triphenoxysilane, methyl tribenzyloxysilane, methyl triphenethyloxysilane, glycidoxymethyl trimethoxysilane, glycidoxymethyl triethoxysilane, α-glycidoxyethyl trimethoxysilane, α-glycidoxyethyl triethoxysilane, β-glycidoxyethyl trimethoxysilane, β-glycidoxyethyl triethoxysilane, α-glycidoxypropyl trimethoxysilane, α-glycidoxypropyl triethoxysilane, β-glycidoxypropyl trimethoxysilane, β-glycidoxypropyl triethoxysilane, γ-glycidoxypropyl trimethoxysilane, γ-glycidoxypropyl triethoxysilane, γ-glycidoxypropyl tripropoxysilane, γ-glycidoxypropyl tributoxysilane, γ-glycidoxypropyl triphenoxysilane, α-glycidoxybutyl trimethoxysilane, α-glycidoxybutyl triethoxysilane, β-glycidoxybutyl triethoxysilane, γ-glycidoxybutyl trimethoxysilane, γ-glycidoxybutyl triethoxysilane, δ-glycidoxybutyl trimethoxysilane, δ-glycidoxybutyl triethoxysilane, (3,4-epoxycyclohexyl)methyl trimethoxysilane, (3,4-epoxycyclohexyl)methyl triethoxysilane, β-(3,4-epoxycyclohexyl)ethyl trimethoxysilane, β-(3,4-epoxycyclohexyl)ethyl triethoxysilane, β-(3,4-epoxycyclohexyl)ethyl tripropoxysilane, β-(3,4-epoxycyclohexyl)ethyl tributoxysilane, β-(3,4-epoxycyclohexyl)ethyl triphenoxysilane, γ-(3,4-epoxycyclohexyl)propyl trimethoxysilane, γ-(3,4-epoxycyclohexyl)propyl triethoxysilane, δ-(3,4-epoxycyclohexyl)butyl trimethoxysilane, δ-(3,4-epoxycyclohexyl)butyl triethoxysilane, glycidoxymethylmethyl dimethoxysilane, glycidoxymethylmethyl diethoxysilane, α-glycidoxyethylmethyl dimethoxysilane, α-glycidoxyethylmethyl diethoxysilane, J-glycidoxyethylmethyl dimethoxysilane, β-glycidoxyethylethyl dimethoxysilane, α-glycidoxypropylmethyl dimethoxysilane, α-glycidoxypropylmethyl diethoxysilane, β-glycidoxypropylmethyl dimethoxysilane, β-glycidoxypropylethyl dimethoxysilane, γ-glycidoxypropylmethyl dimethoxysilane, γ-glycidoxypropylmethyl diethoxysilane, γ-glycidoxypropylmethyl dipropoxysilane, γ-glycidoxypropylmethyl dibutoxysilane, γ-glycidoxypropylmethyl diphenoxysilane, γ-glycidoxypropylethyl dimethoxysilane, γ-glycidoxypropylethyl diethoxysilane, γ-glycidoxypropylvinyl dimethoxysilane, γ-glycidoxypropylvinyl diethoxysilane, ethyl trimethoxysilane, ethyl triethoxysilane, vinyl trimethoxysilane, vinyl triethoxysilane, vinyl trichlorosilane, vinyl triacetoxysilane, methylvinyl dimethoxysilane, methylvinyl diethoxysilane, methylvinyl dichlorosilane, methylvinyl diacetoxysilane, dimethylvinyl methoxysilane, dimethylvinyl ethoxysilane, dimethylvinyl chlorosilane, dimethylvinyl acetoxysilane, divinyl dimethoxysilane, divinyl diethoxysilane, divinyl dichlorosilane, divinyl diacetoxysilane, γ-glycidoxypropylvinyl dimethoxysilane, γ-glycidoxypropylvinyl diethoxysilane, allyl trimethoxysilane, ally triethoxysilane, allyl trichlorosilane, allyl triacetoxysilane, allyl methyl dimethoxysilane, allyl methyl diethoxysilane, allyl methyl dichlorosilane, allyl methyl diacetoxysilane, allyl dimethyl methoxysilane, allyl dimethyl ethoxysilane, allyl dimethyl chlorosilane, allyl dimethyl acetoxysilane, diallyl dimethoxysilane, diallyl diethoxysilane, diallyl dichlorosilane, diallyl diacetoxysilane, 3-allylaminopropyl trimethoxysilane, 3-allylaminopropyl triethoxysilane, p-styryl trimethoxysilane, phenyl trimethoxysilane, phenyl triethoxysilane, phenyl trichlorosilane, phenyl triacetoxysilane, phenylmethyl dimethoxysilane, phenylmethyl diethoxysilane, phenylmethyl dichlorosilane, phenylmethyl diacetoxysilane, phenyldimethyl methoxysilane, phenyldimethyl ethoxysilane, phenyldimethyl chlorosilane, phenyldimethyl acetoxysilane, diphenylmethyl methoxysilane, diphenylmethyl ethoxysilane, diphenylmethyl chlorosilane, diphenylmethyl acetoxysilane, diphenyl dimethoxysilane, diphenyl diethoxysilane, diphenyl dichlorosilane, diphenyl diacetoxysilane, triphenyl methoxysilane, triphenyl ethoxysilane, triphenyl acetoxysilane, triphenyl chlorosilane, 3-phenylaminopropyl trimethoxysilane, 3-phenylaminopropyl triethoxysilane, dimethoxymethyl-3-(3-phenoxypropylthiopropyl)silane, triethoxy((2-methoxy-4-(methoxymethyl)phenoxy)methyl)silane, benzyl trimethoxysilane, benzyl triethoxysilane, benzylmethyl dimethoxysilane, benzylmethyl diethoxysilane, benzyldimethyl methoxysilane, benzyldimethyl ethoxysilane, benzyldimethyl chlorosilane, phenethyl trimethoxysilane, phenethyl triethoxysilane, phenethyl trichlorosilane, phenethyl triacetoxysilane, phenethylmethyl dimethoxysilane, phenethylmethyl diethoxysilane, phenethylmethyl dichlorosilane, phenethylmethyl diacetoxysilane, methoxyphenyl trimethoxysilane, methoxyphenyl triethoxysilane, methoxyphenyl triacetoxysilane, methoxyphenyl trichlorosilane, methoxybenzyl trimethoxysilane, methoxybenzyl triethoxysilane, methoxybenzyl triacetoxysilane, methoxybenzyl trichlorosilane, methoxyphenethyl trimethoxysilane, methoxyphenethyl triethoxysilane, methoxyphenethyl triacetoxysilane, methoxyphenethyl trichlorosilane, ethoxyphenyl trimethoxysilane, ethoxyphenyl triethoxysilane, ethoxyphenyl triacetoxysilane, ethoxyphenyl trichlorosilane, ethoxybenzyl trimethoxysilane, ethoxybenzyl triethoxysilane, ethoxybenzyl triacetoxysilane, ethoxybenzyl trichlorosilane, i-propoxyphenyl trimethoxysilane, i-propoxyphenyl triethoxysilane, i-propoxyphenyl triacetoxysilane, i-propoxyphenyl trichlorosilane, i-propoxybenzyl trimethoxysilane, i-propoxybenzyl triethoxysilane, i-propoxybenzyl triacetoxysilane, i-propoxybenzyl trichlorosilane, t-butoxyphenyl trimethoxysilane, t-butoxyphenyl triethoxysilane, t-butoxyphenyl triacetoxysilane, t-butoxyphenyl trichlorosilane, t-butoxybenzyl trimethoxysilane, t-butoxybenzyl triethoxysilane, t-butoxybenzyl triacetoxysilane, t-butoxybenzyl trichlorosilane, methoxynaphthyl trimethoxysilane, methoxynaphthyl triethoxysilane, methoxynaphthyl triacetoxysilane, methoxynaphthyl trichlorosilane, ethoxynaphthyl trimethoxysilane, ethoxynaphthyl triethoxysilane, ethoxynaphthyl triacetoxysilane, ethoxynaphthyl trichlorosilane, γ-chloropropyl trimethoxysilane, γ-chloropropyl triethoxysilane, γ-chloropropyl triacetoxysilane, 3,3,3-trifluoropropyl trimethoxysilane, γ-methacryloxypropyl trimethoxysilane, γ-mercaptopropyl trimethoxysilane, γ-mercaptopropyl triethoxysilane, β-cyanoethyl triethoxysilane, thiocyanatopropyl triethoxysilane, chloromethyl trimethoxysilane, chloromethyl triethoxysilane, triethoxysilylpropyl diallylisocyanurate, bicycle[2,2,1]heptenyl triethoxysilane, benzenesulfonylpropyl triethoxysilane, benzenesulfonamide propyltriethoxysilane, dimethylaminopropyl trimethoxysilane, dimethyl dimethoxysilane, phenylmethyl dimethoxysilane, dimethyl diethoxysilane, phenylmethyl diethoxysilane, γ-chloropropylmethyl dimethoxysilane, γ-chloropropylmethyl diethoxysilane, dimethyl diacetoxysilane, γ-methacryloxypropylmethyl dimethoxysilane, γ-methacryloxypropylmethyl diethoxysilane, γ-mercaptopropylmethyl dimethoxysilane, γ-mercaptomethyl diethoxysilane, methylvinyl dimethoxysilane, methylvinyl diethoxysilane, silanes represented by Formulas (A-1) to (A-41),and silanes represented by Formulas (1-1) to (1-225) and (1-246) to (1-290).

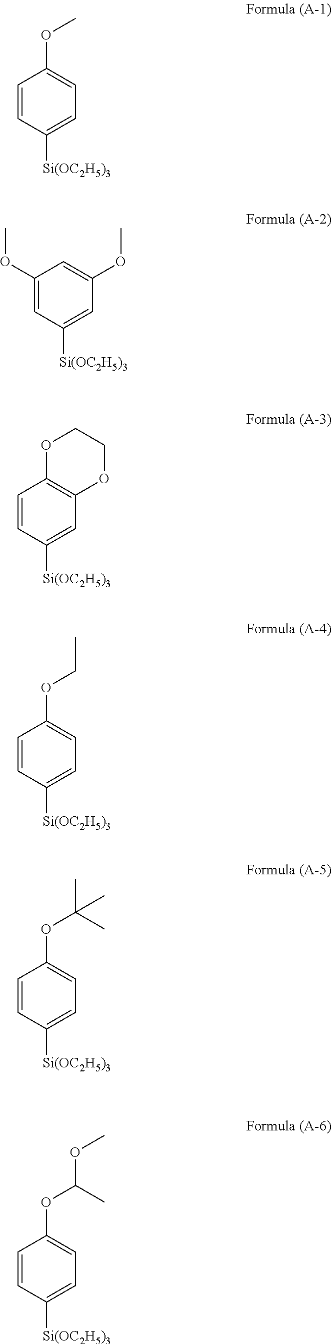

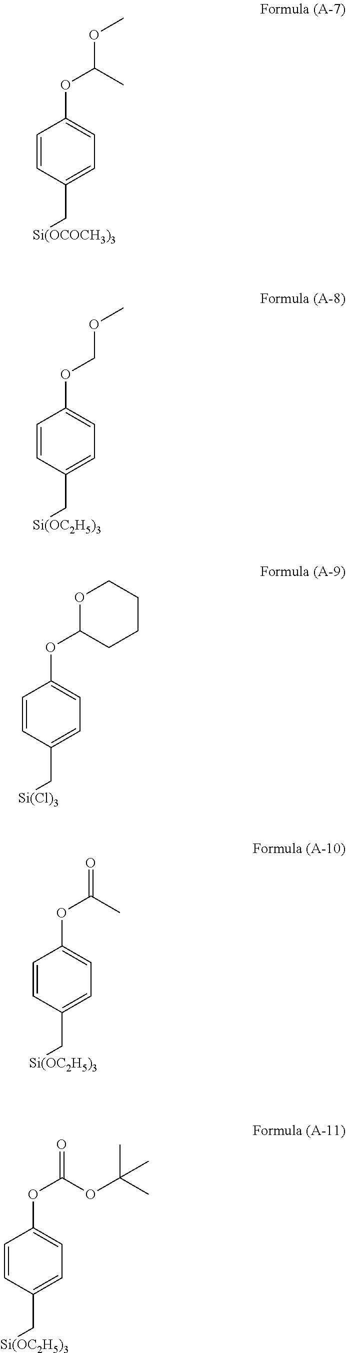

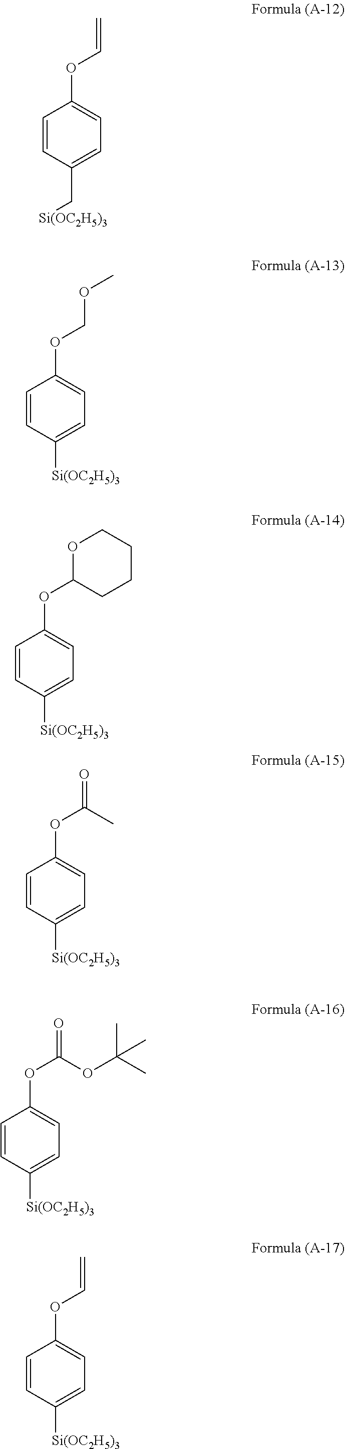

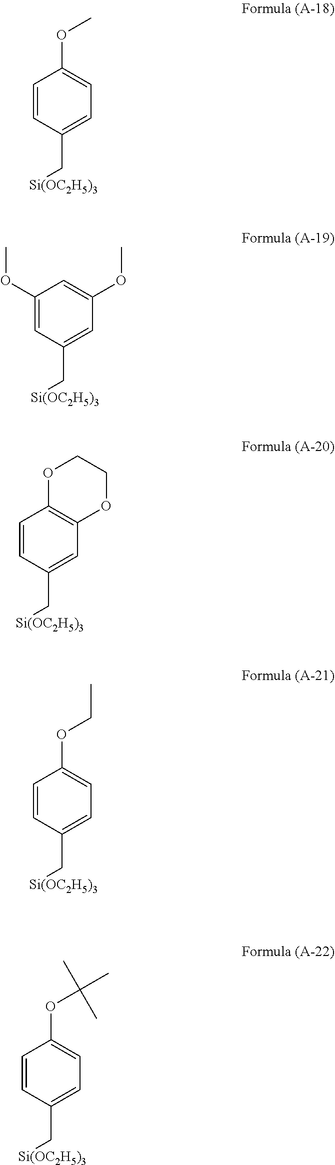

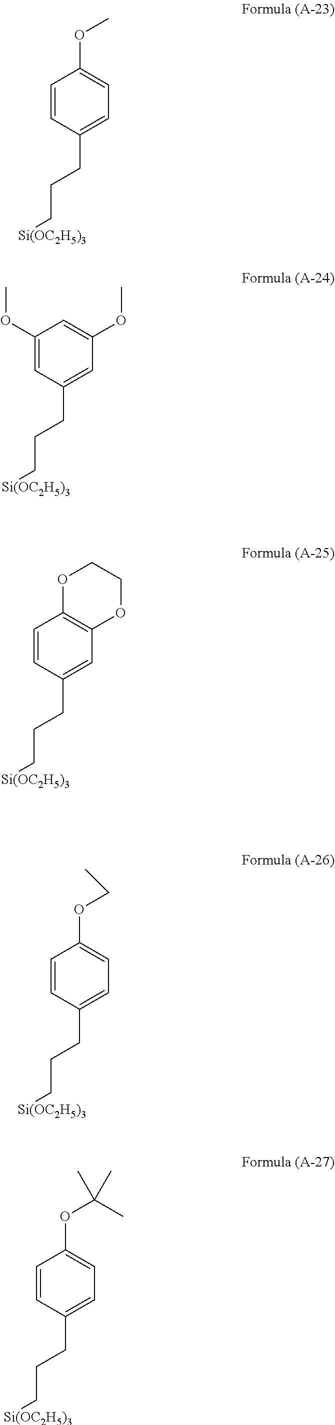

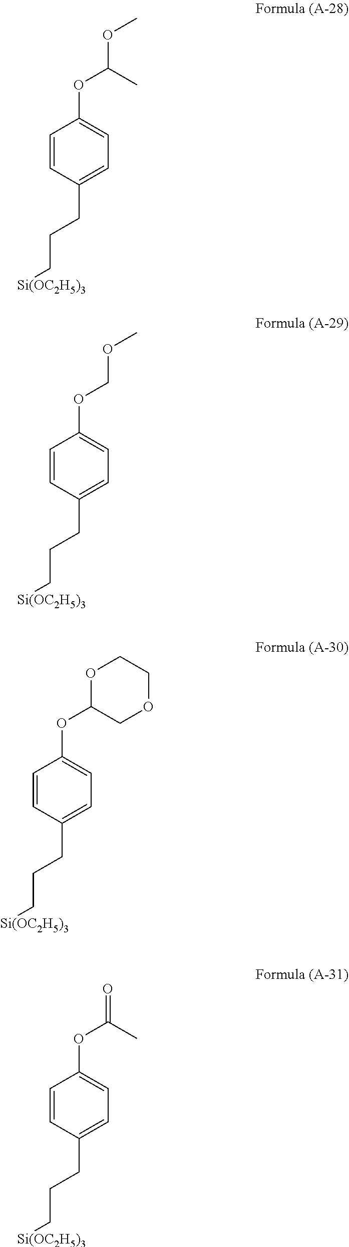

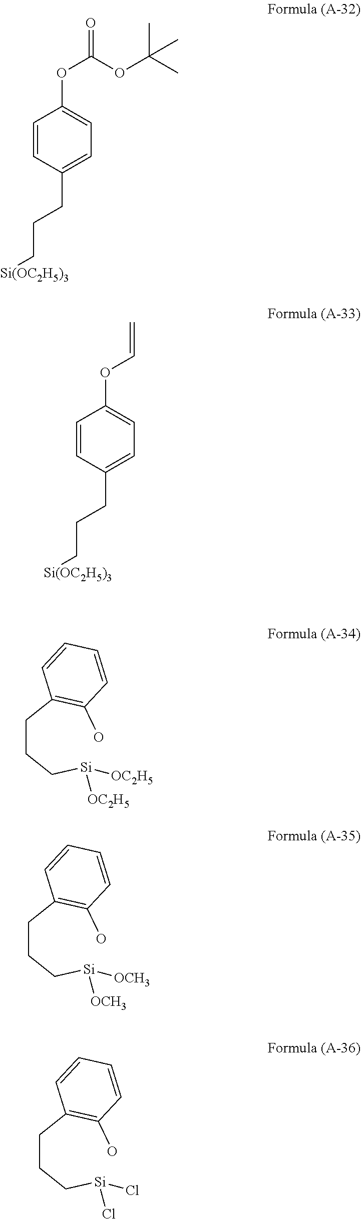

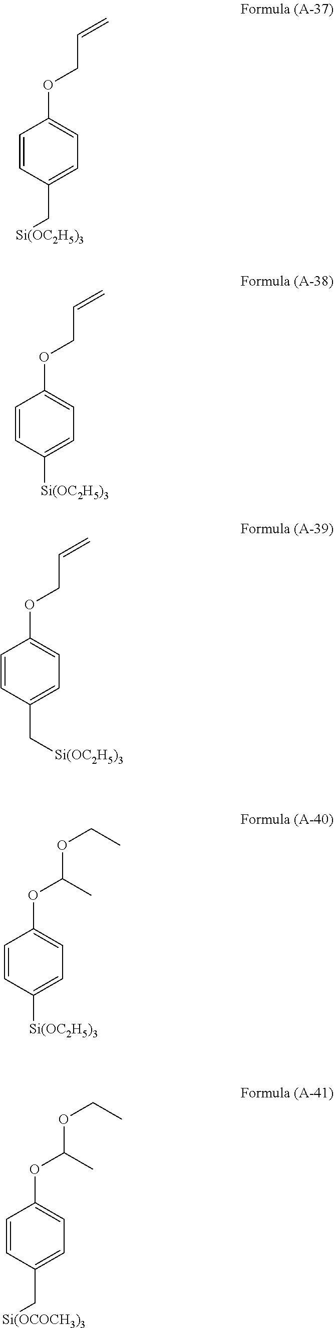

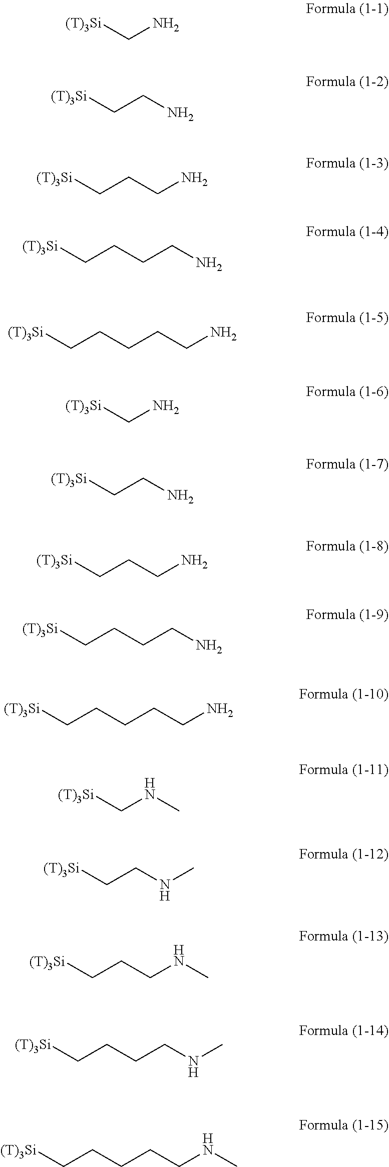

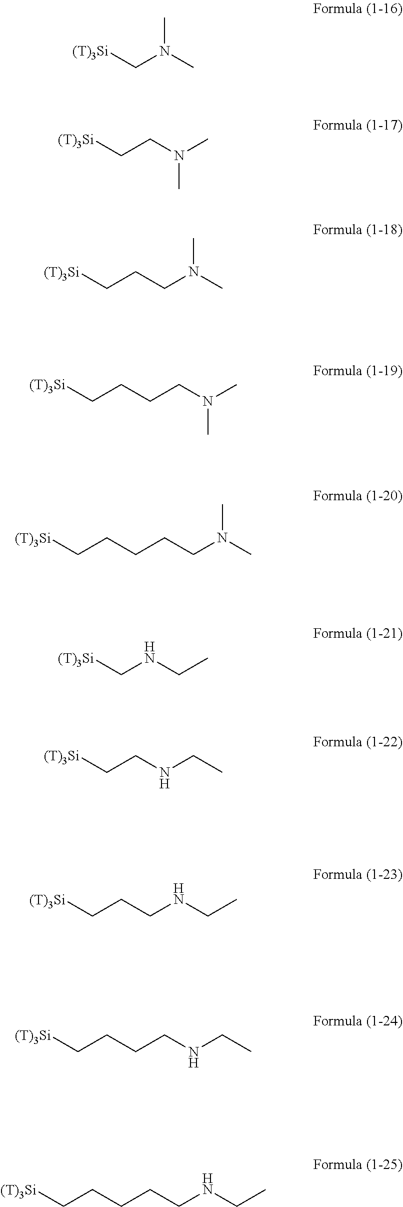

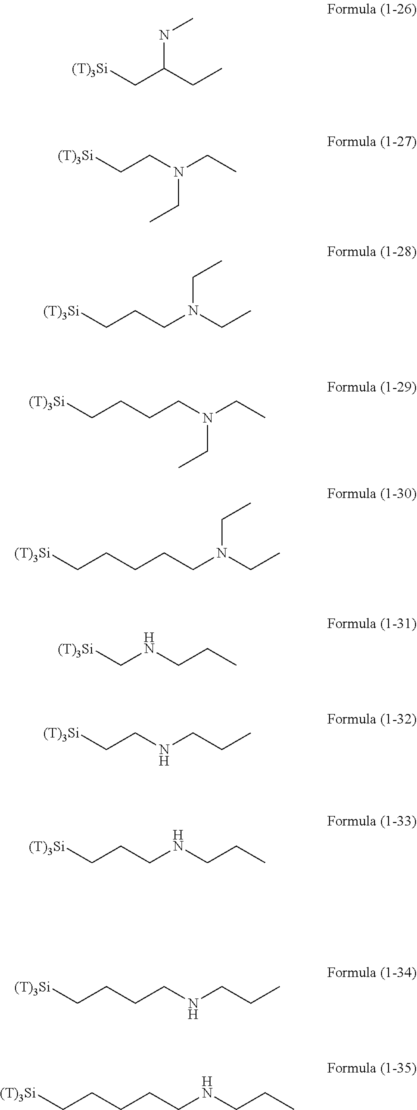

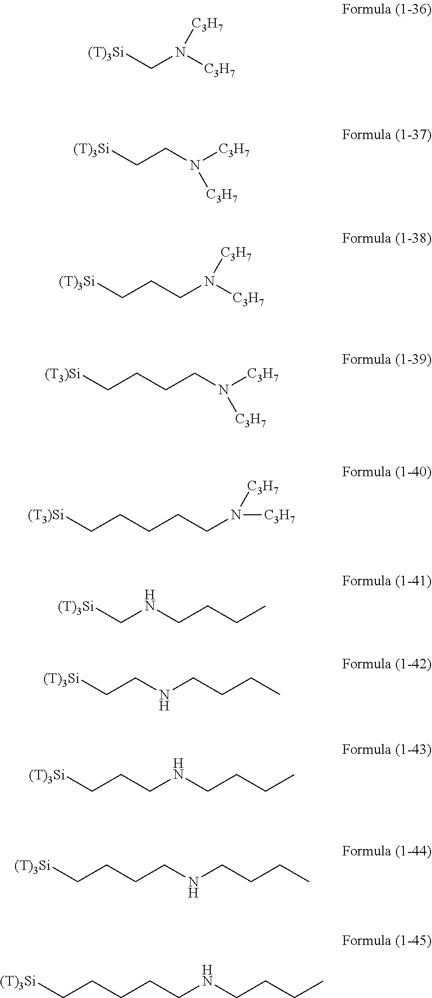

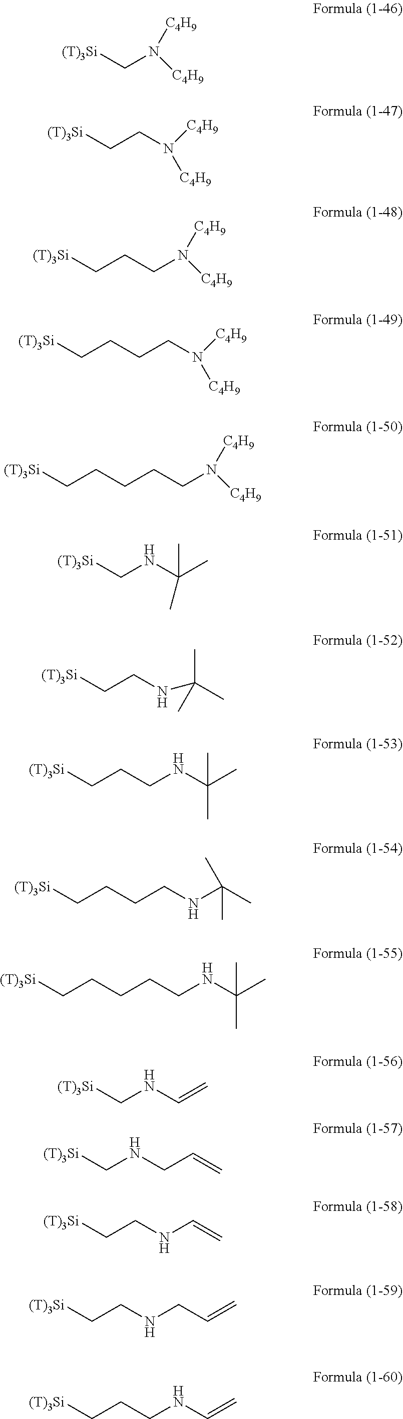

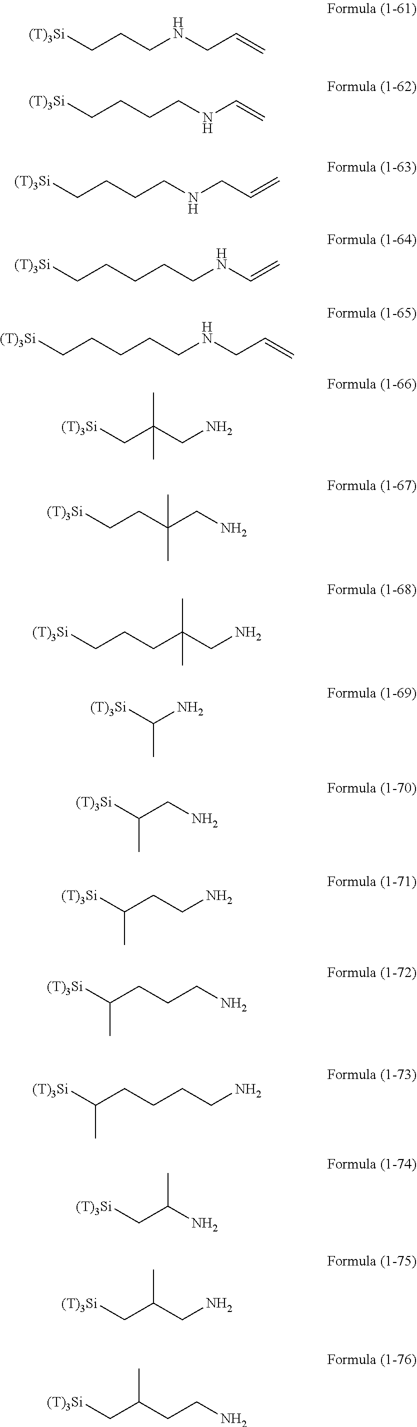

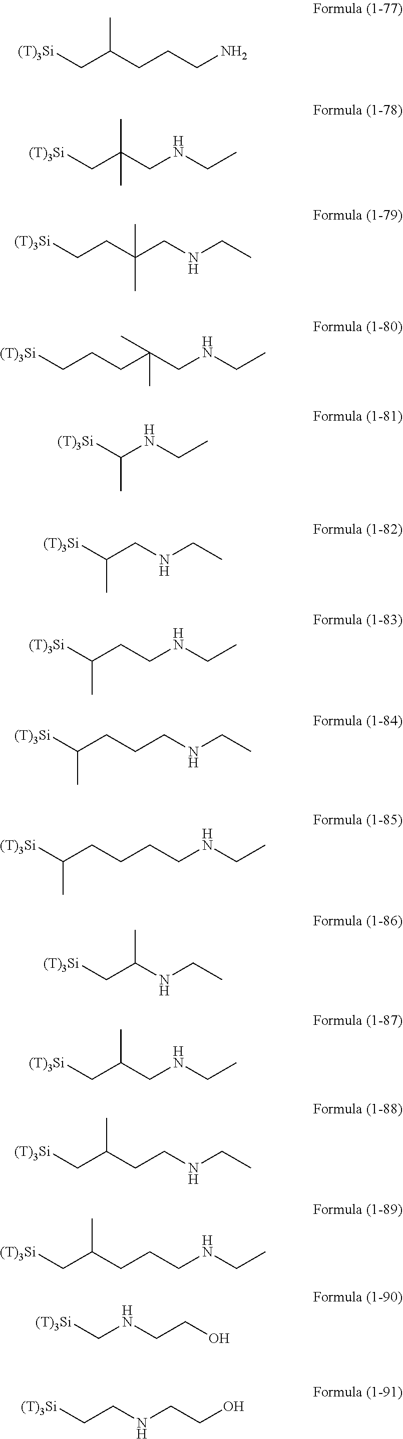

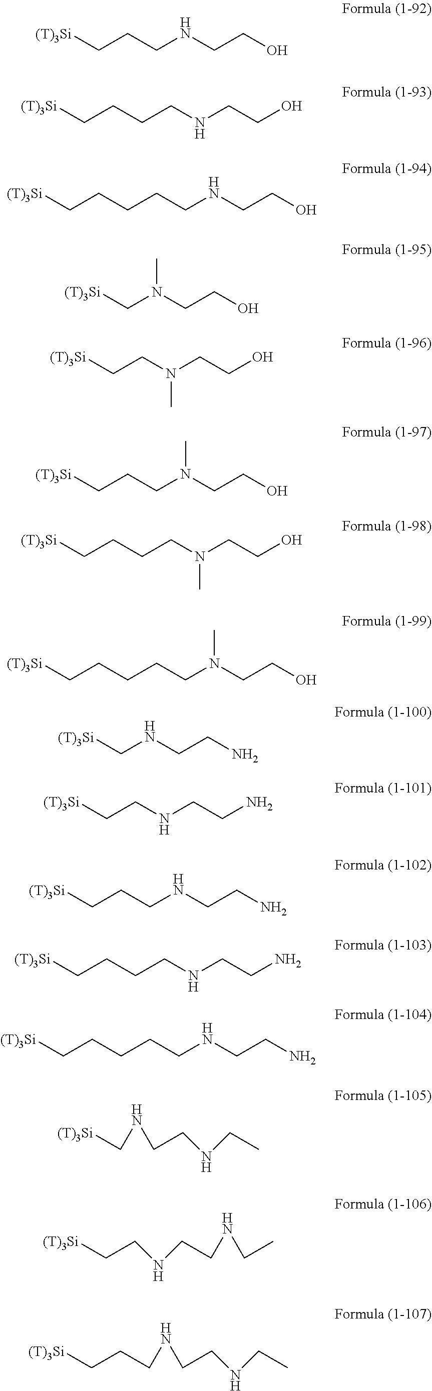

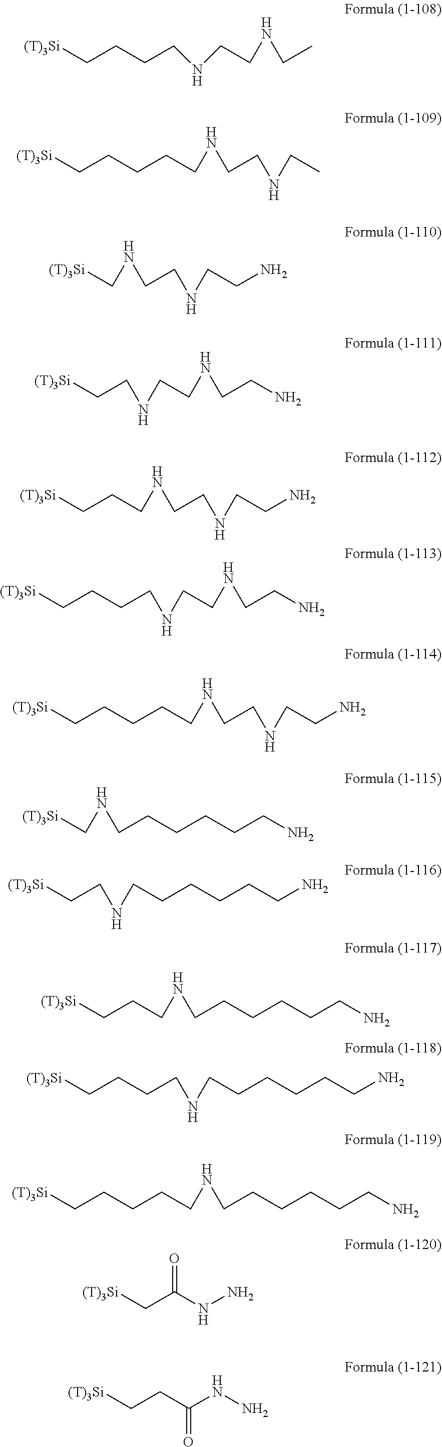

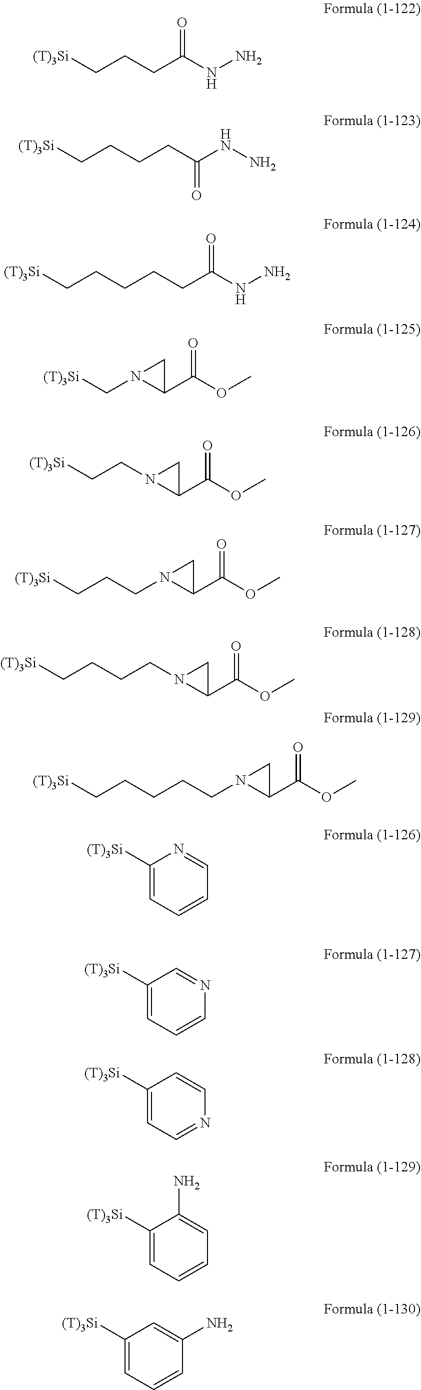

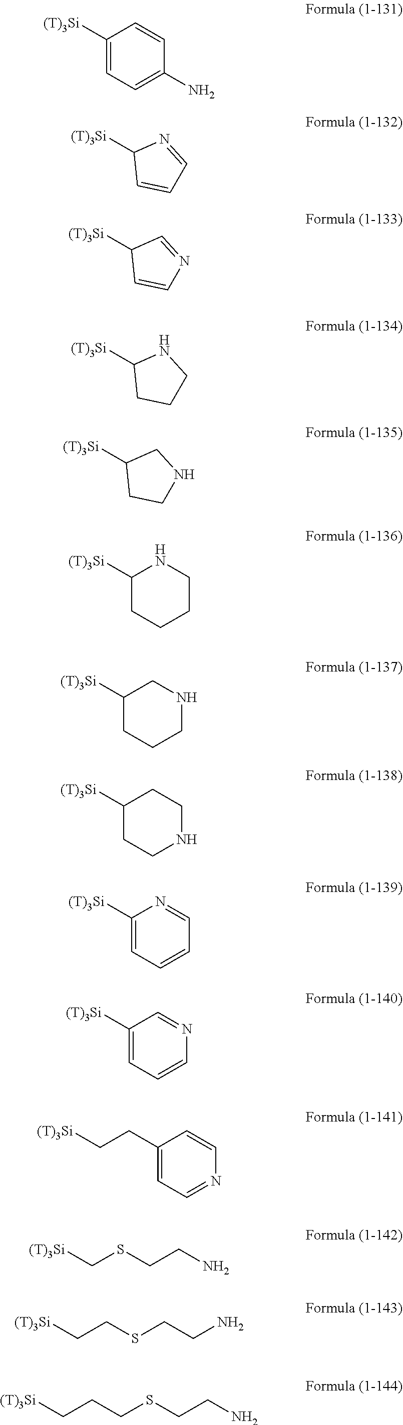

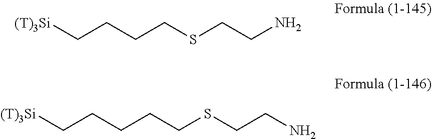

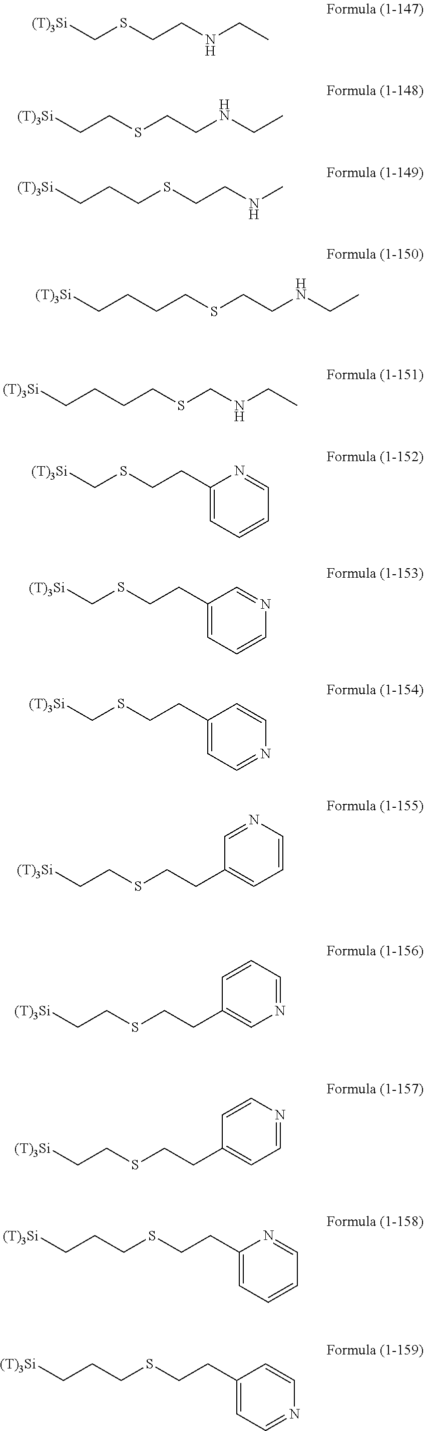

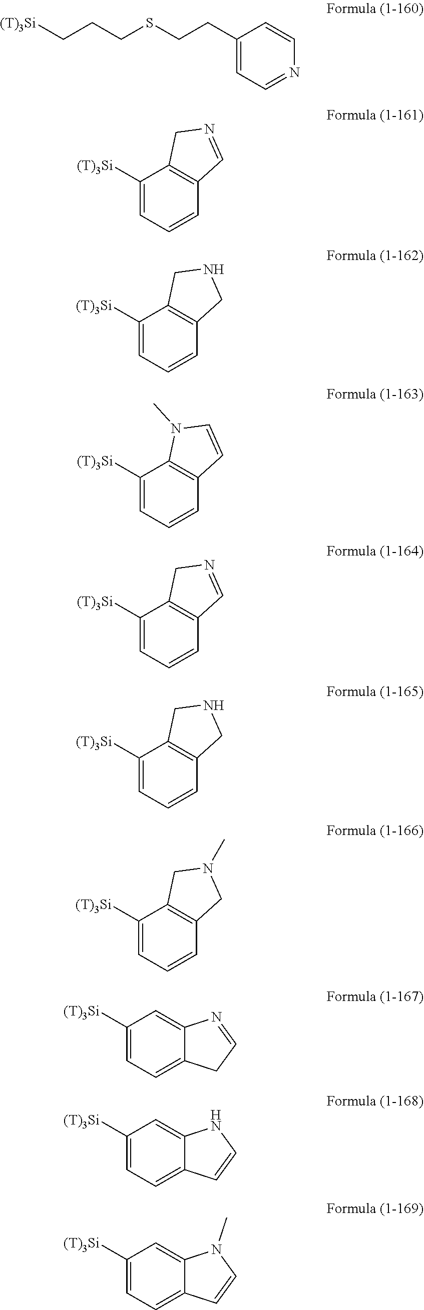

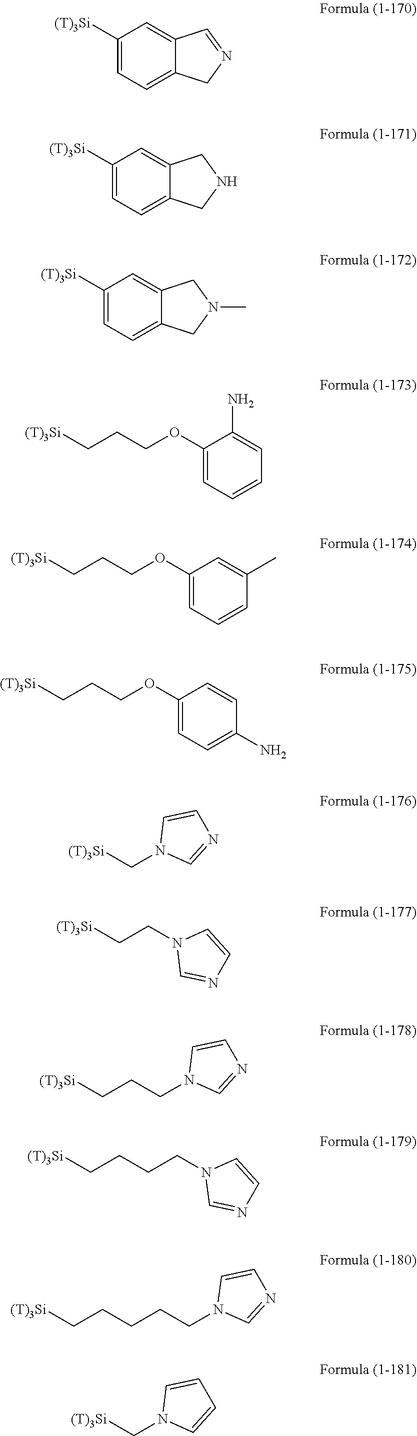

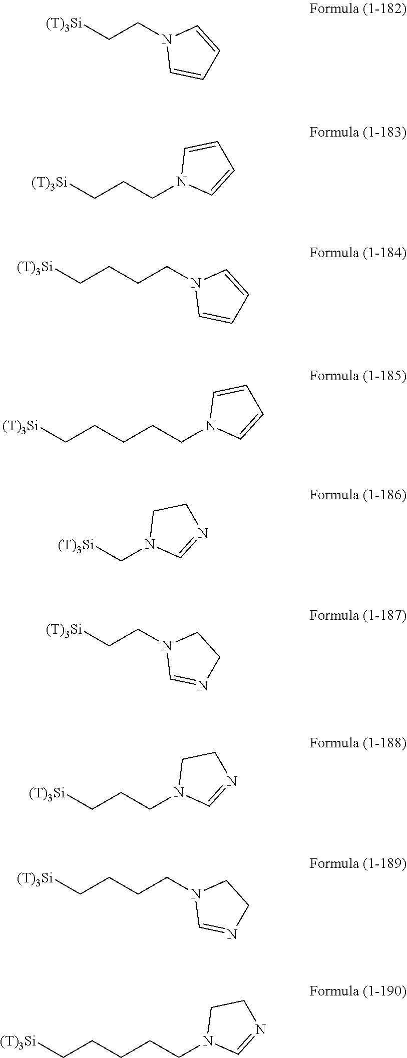

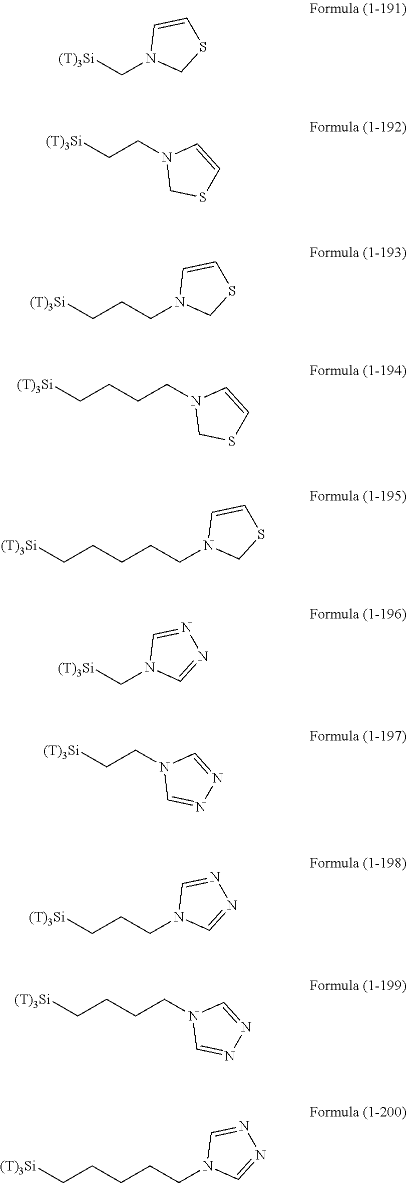

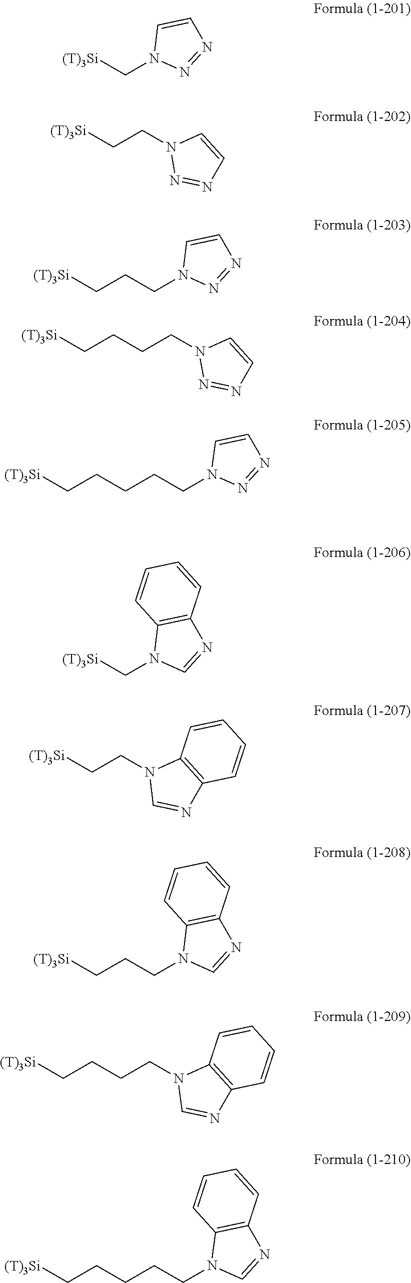

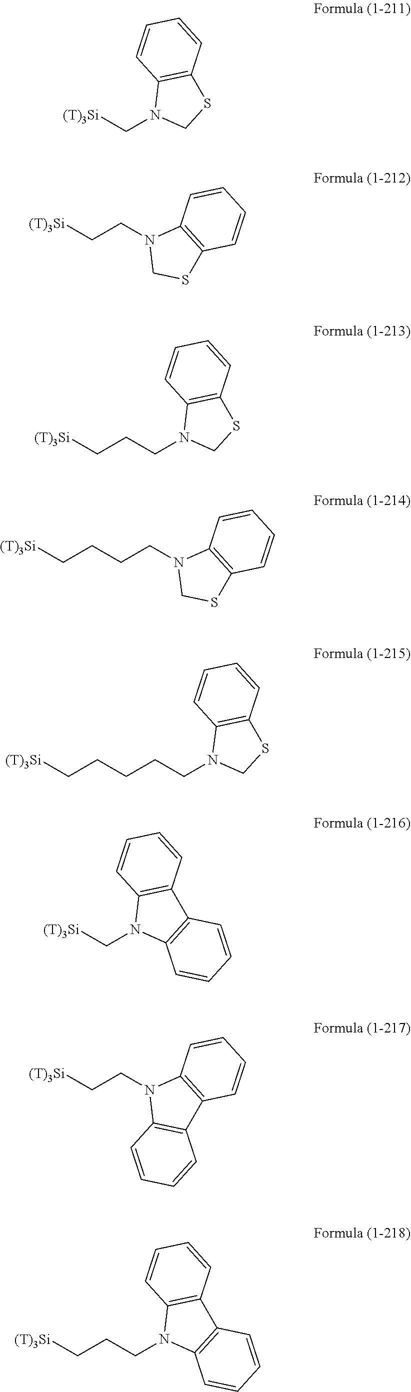

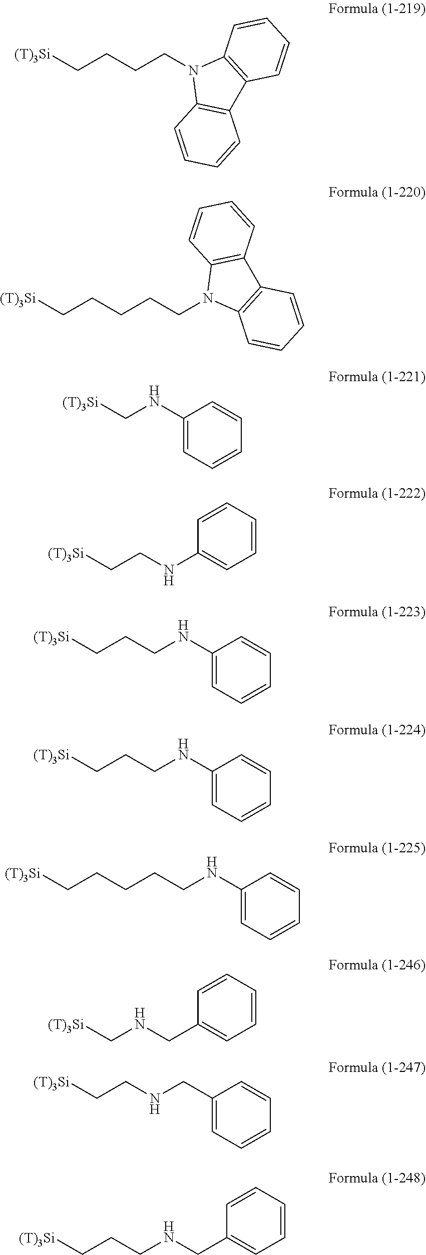

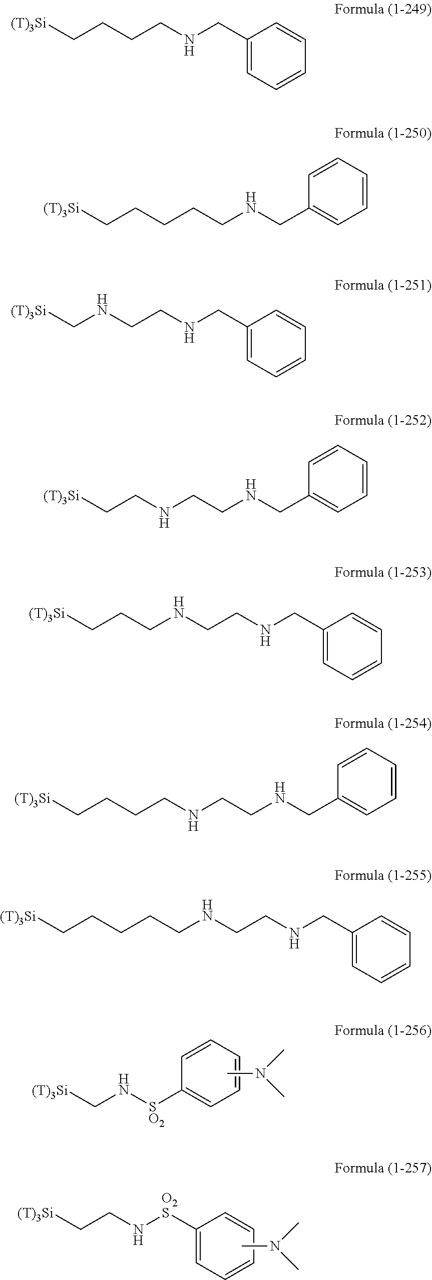

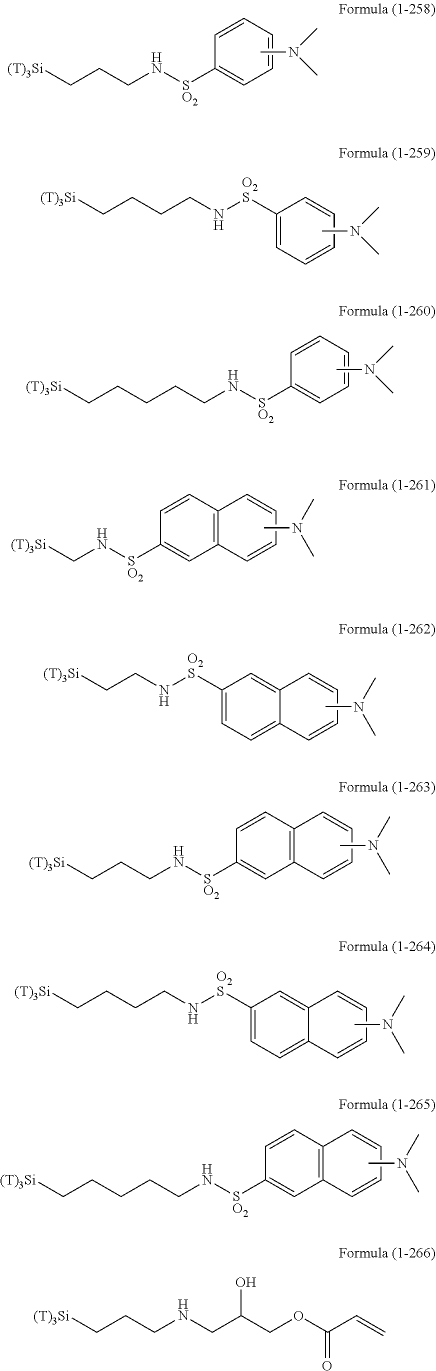

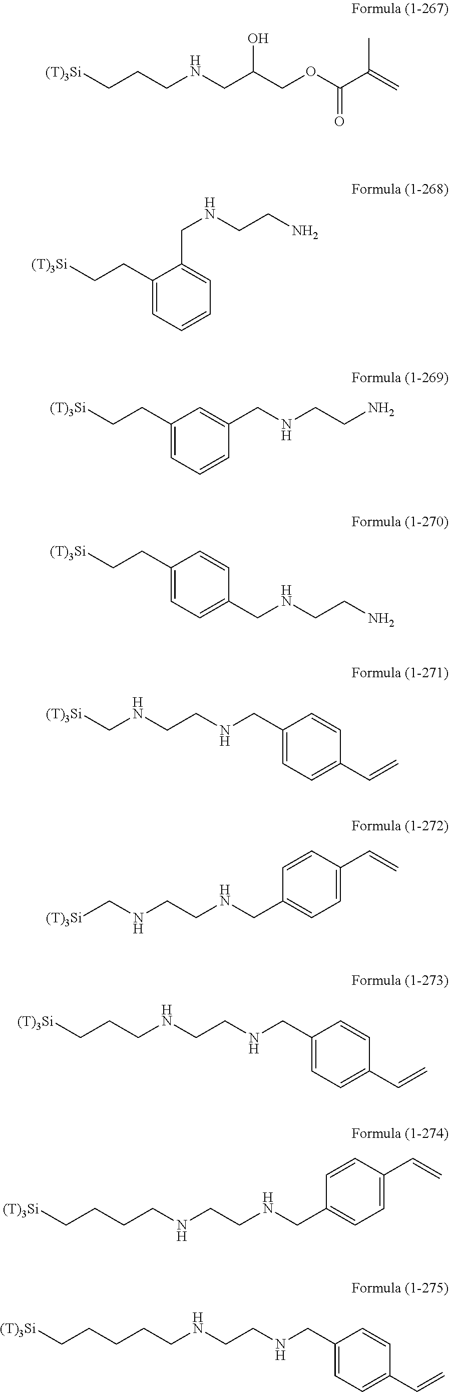

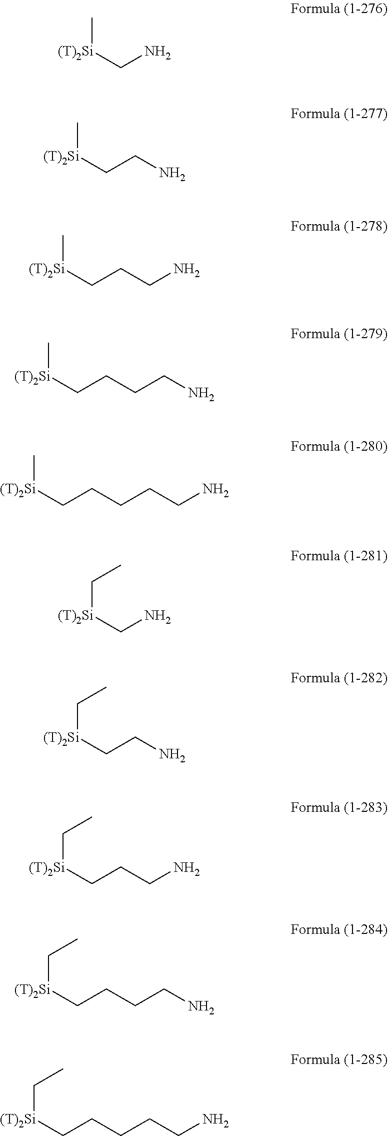

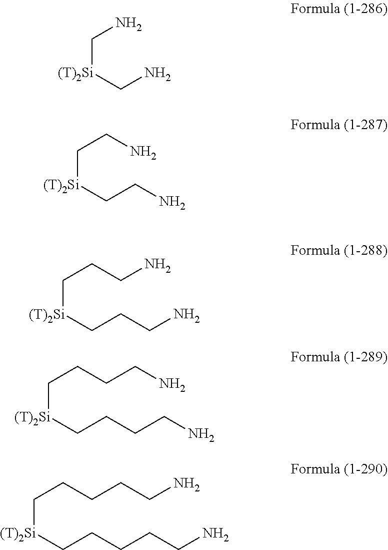

In Formulas (1-1) to (1-225) and (1-246) to (1-290), each T independently represents an alkoxy group, an acyloxy group, or a halogen group, and preferably represents, for example, a methoxy group or an ethoxy group.

In addition, examples of the polysiloxane [A] include hydrolysis-condensation products of hydrolyzable silanes, or modified products thereof, the hydrolyzable silanes including the hydrolyzable silane (A) having the specific group and hydrolyzable silanes represented by Formula (2).

In addition, examples of the polysiloxane [A] can include hydrolysis-condensation products of hydrolyzable silanes, or modified products thereof, the hydrolyzable silanes including the hydrolyzable silane (A) having the specific group, hydrolyzable silanes represented by Formula (1), and hydrolyzable silanes represented by Formula (2). Examples of the polysiloxane [A′] include hydrolysis-condensation products of hydrolyzable silanes, or modified products thereof, the hydrolyzable silanes including hydrolyzable silanes represented by Formula (1), or hydrolyzable silanes represented by Formula (2) instead of the hydrolyzable silanes represented by Formula (1).

Formula (2)

[R³_{b}Si(R⁴)_{3-b}]₂R⁵_{c} (2)

In Formula (2), R³ is a group bonded to a silicon atom and each independently represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group (with the proviso that a methoxyphenyl sulfonyl group is excluded), or an organic group having a cyano group, or a combination of two or more thereof.

In addition, R⁴ is a group or atom bonded to a silicon atom, and each independently represents an alkoxy group, an aralkyloxy group, an acyloxy group, or a halogen atom.

R⁵ is a group bonded to a silicon atom, and each independently represents an alkylene group or an arylene group.

b represents 0 or 1, and c represents 0 or 1.

Specific examples of each group and atoms of R³ and the preferable number of carbon atoms thereof include the groups and number of carbon atoms described above with regard to R² in Formula (A-1).

Specific examples of each group and atom of R⁴ and the preferable number of carbon atoms thereof include the groups, atoms, and number of carbon atoms described above with regard to X in Formula (A-1).

Specific examples of the alkylene group in R⁵ include, but are not limited to, alkylene groups such as linear alkylene groups including, for example, a methylene group, an ethylene group, a trimethylene group, a tetramethylene group, a pentamethylene group, a hexamethylene group, a heptamethylene group, an octamethylene group, a nonamethylene group, and a decamethylene group, and branched alkylene groups including, for example, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; and alkanetriyl groups, such as a methanetriyl group, an ethane-1,1,2-triyl group, an ethane-1,2,2-triyl group, an ethane-2,2,2-triyl group, a propane-1,1,1-triyl group, a propane-1,1,2-triyl group, a propane-1,2,3-triyl group, a propane-1,2,2-triyl group, a propane-1,1,3-triyl group, a butane-1,1,1-triyl group, a butane-1,1,2-triyl group, a butane-1,1,3-triyl group, a butane-1,2,3-triyl group, a butane-1,2,4-triyl group, a butane-1,2,2-triyl group, a butane-2,2,3-triyl group, a 2-methylpropane-1,1,1-triyl group, a 2-methylpropane-1,1,2-triyl group, and a 2-methylpropane-1,1,3-triyl group.

Specific examples of the arylene group in R⁵ include, but are not limited to, a 1,2-phenylene group, a 1,3-phenylene group, and a 1,4-phenylene group; groups derived by removing two hydrogen atoms on the aromatic ring of a condensed ring aromatic hydrocarbon compound, such as a 1,5-naphthalene-diyl group, a 1,8-naphthalene-diyl, a 2,6-naphthalene-diyl group, a 2,7-naphthalene-diyl group, a 1,2-anthracene-diyl group, a 1,3-anthracene-diyl group, a 1,4-anthracene-diyl group, a 1,5-anthracene-diyl group, a 1,6-anthracene-diyl group, a 1,7-anthracene-diyl group, a 1,8-anthracene-diyl group, a 2,3-anthracene-diyl group, a 2,6-anthracene-diyl group, a 2,7-anthracene-diyl group, a 2,9-anthracene-diyl group, a 2,10-anthracene-diyl group, and a 9,10-anthracene-diyl group; and groups derived by removing two hydrogen atoms on the aromatic ring of a ring-linked aromatic hydrocarbon compound, such as a 4,4′-biphenyl-diyl group and a 4,4″-paraterphenyl-diyl group.

b is preferably 0.

c is preferably 1.

Specific examples of the hydrolyzable silane represented by Formula (2) include, but are not limited to, methylene bistrimethoxysilane, methylene bistrichlorosilane, methylene bistriacetoxysilane, ethylene bistriethoxysilane, ethylene bistrichlorosilane, ethylene bistriacetoxysilane, propylene bistriethoxysilane, butylene bistrimethoxysilane, phenylene bistrimethoxysilane, phenylene bistriethoxysilane, phenylene bismethyldiethoxysilane, phenylene bismethyldimethoxysilane, naphthylene bistrimethoxysilane, bistrimethoxydisilane, bistriethoxydisilane, bisethyldiethoxydisilane, and bis-methyldimethoxydisilane.

Examples of the polysiloxane [A] include hydrolysis-condensation products of hydrolyzable silanes, or modified products thereof, the hydrolyzable silanes including the hydrolyzable silane (A) having the specific group, a hydrolyzable silane represented by Formula (1) and/or a hydrolyzable silane represented by Formula (2), as well as another hydrolyzable silane described below.

Examples of the polysiloxane [A′] include hydrolysis-condensation products of hydrolyzable silanes, or modified products thereof, the hydrolyzable silanes including a hydrolyzable silane represented by Formula (1) and/or a hydrolyzable silane represented by Formula (2), as well as another hydrolyzable silane described below.

Examples of other hydrolyzable silanes include, but are not limited to, silane compounds having an onium group in the molecule, and silane compounds having a cyclic urea skeleton in the molecule.

### Silane Compounds (Hydrolyzable Organosilanes) Having Onium Group in Molecule

The silane compound having an onium group in the molecule is expected to effectively and efficiently promote a crosslinking reaction of the hydrolyzable silane.

A preferable example of the silane compound having an onium group in the molecule is a silane compound represented by Formula (3).

R¹¹_{f}R¹²_{g}Si(R¹³)_{4-(f+g)} (3)
R¹¹ is a group bonded to a silicon atom and represents an onium group or an organic group having an onium group.
R¹² is a group bonded to a silicon atom and each independently represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having a cyano group, or a combination of two or more thereof.
R¹³ is a group or atom bonded to a silicon atom, and each independently represents an alkoxy group, an aralkyloxy group, an acyloxy group, or a halogen atom.
f represents 1 or 2, g represents 0 or 1, and 1<(f+g)<2 is satisfied.

Specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, the alkenyl group, the organic group having an epoxy group, the organic group having an acryloyl group, the organic group having a methacryloyl group, the organic group having a mercapto group, the organic group having an amino group, the organic group having a cyano group, the alkoxy group, the aralkyloxy group, the acyloxy group, and the halogen atoms, specific examples of the substituents of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group, and the preferred number of carbon atoms thereof include, for R¹², those described above with regard to R² in Formula (A-1), and for R¹³, those described above with regard to X in Formula (A-1).

More specifically, specific examples of the onium group include a cyclic ammonium group and a chain-shaped ammonium group, and a tertiary ammonium group and a quaternary ammonium group are preferable.

That is, specific preferable examples of the onium group or the organic group having the onium group include a cyclic ammonium group, a chain-shaped ammonium group, or an organic group having at least one of these, and a tertiary ammonium group, a quaternary ammonium group, or an organic group having at least one of these is preferable.

Note that when the onium group is a cyclic ammonium group, the nitrogen atom constituting the ammonium group also serves as an atom constituting the ring. In this case, the silicon atom and the nitrogen atom constituting the ring may be bonded directly or via a divalent linking group, or the silicon atom and a carbon constituting the ring may be bonded directly or via a divalent linking group.

In one preferred embodiment, R¹¹, which is a group bonded to the silicon atom, is a heteroaromatic cyclic ammonium group represented by Formula (S1).

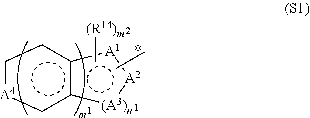

In Formula (S1), A¹, A², A³, and A⁴ each independently represent a group represented by any one of Formulas (J1) to (J3), but at least one of A¹ to A⁴ is a group represented by Formula (J2). Furthermore, the bond between each of A¹ to A⁴ and the atom adjacent thereto and constituting the ring is determined to be a single bond or a double bond according to which of A¹ to A⁴ the silicon atom in Formula (3) is bonded to, such that the constituted ring exhibits aromaticity. * represents a bond.

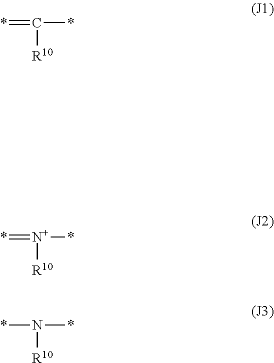

In Formulas (J1) to (J3), each R¹⁰ independently represents a single bond, a hydrogen atom, an alkyl group, an aryl group, an aralkyl group, a halogenated alkyl group, a halogenated aryl group, a halogenated aralkyl groups, or an alkenyl group, and specific examples of the alkyl group, aryl group, aralkyl group, halogenated alkyl group, halogenated aryl group, halogenated aralkyl group, and alkenyl group and preferable numbers of carbon atoms thereof are the same as those described above. * represents a bond.

In Formula (S1), each R¹⁴ independently represents an alkyl group, an aryl group, an aralkyl group, a halogenated alkyl group, a halogenated aryl group, a halogenated aralkyl group, an alkenyl group, or a hydroxy group, and when two or more R¹⁴ are present, the two R¹⁴ may be bonded to each other to form a ring. Further, a ring formed by two R¹⁴ may have a bridged ring structure, and in such a case, the cyclic ammonium group has an adamantane ring, a norbornene ring, a spiro ring or the like.

Specific examples of such an alkyl group, aryl group, aralkyl group, halogenated alkyl group, halogenated aryl group, halogenated aralkyl group, and alkenyl group, and the preferable number of carbon atoms thereof are the same as those described above.

In Formula (S1), n¹ is an integer from 1 to 8, m¹ is 0 or 1, and m² is 0 or a positive integer from 1 to the maximum number that can be substituted on a monocyclic or polycyclic ring.

When m¹ is 0, a (4+n¹)-membered ring including A¹ to A⁴ is formed. That is, a 5-membered ring is formed when n¹ is 1, a 6-membered ring is formed when n¹ is 2, a 7-membered ring is formed when n¹ is 3, an 8-membered ring is formed when n¹ is 4, a 9-membered ring is formed when n¹ is 5, a 10-membered ring is formed when n¹ is 6, an 11-membered ring is formed when n¹ is 7, and a 12-membered ring is formed when n¹ is 8.

When m¹ is 1, a condensed ring in which a (4+n¹)-membered ring containing A¹ to A³ and a 6-membered ring containing A⁴ are condensed is formed.

Depending on which formulas of Formulas (J1) to (J3) represent the groups A¹ to A⁴, each of A¹ to A⁴ may or may not have a hydrogen atom on the atom constituting the ring, but in a case in which A¹ to A⁴ each has a hydrogen atom on the atom constituting the ring, the hydrogen atoms may be substituted with R¹⁴. In addition, the ring-constituting atoms other than the ring-constituting atoms in A¹ to A⁴ may be substituted with R¹⁴. In view of such circumstances, as described above, m² is selected from 0 or integers from 1 to the maximum number that can be substituted on a monocyclic or polycyclic ring.

The bond of the heteroaromatic cyclic ammonium group represented by Formula (S1) is present at any carbon atom or nitrogen atom present in such a single ring or condensed ring, and is directly bonded to a silicon atom, or is bonded to a linking group to form an organic group having a cyclic ammonium, and the organic group is bonded to the Si atom.

Examples of such a linking group include, but are not limited to, an alkylene group, an arylene group, and an alkenylene group.

Specific examples of the alkylene group and the arylene group and the preferable number of carbon atoms thereof are the same as those described above.

The alkenylene group is a divalent group derived by further removing one hydrogen atom from an alkenyl group, and specific examples of such an alkenyl group include the same groups as those described above. The number of carbon atoms of the alkenylene group is not particularly limited, but is preferably 40 or less, more preferably 30 or less, and even more preferably 20 or less.

Specific examples thereof include, but are not limited to, vinylene, 1-methylvinylene, propenylene, 1-butenylene, 2-butenylene, 1-pentenylene, and 2-pentenylene groups.

Specific examples of the silane compound (hydrolyzable organosilane) represented by Formula (3) and having a heteroaromatic cyclic ammonium group represented by Formula (S1) include, but are not limited to, silanes represented by the following Formulas (I-1) to (I-50).

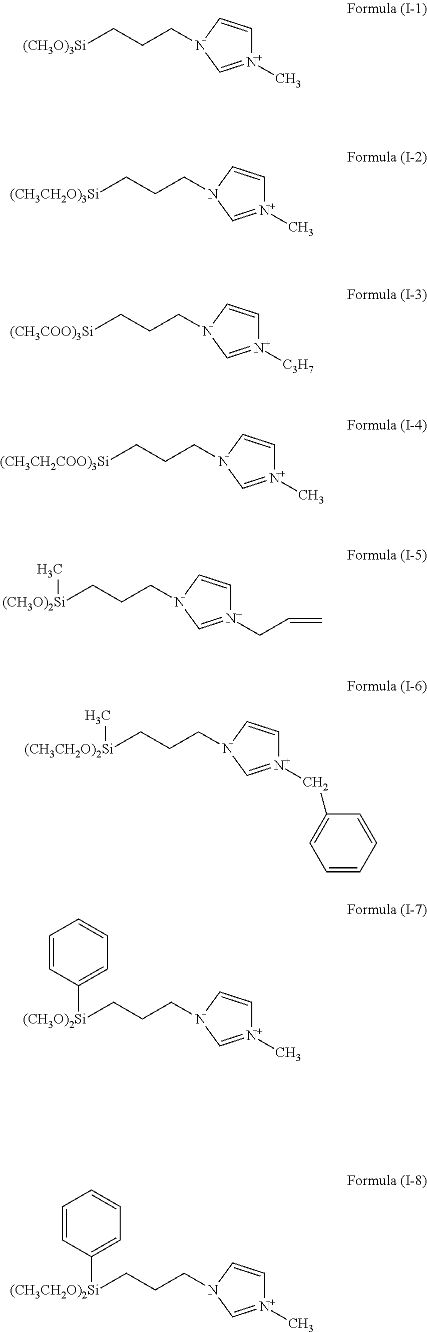

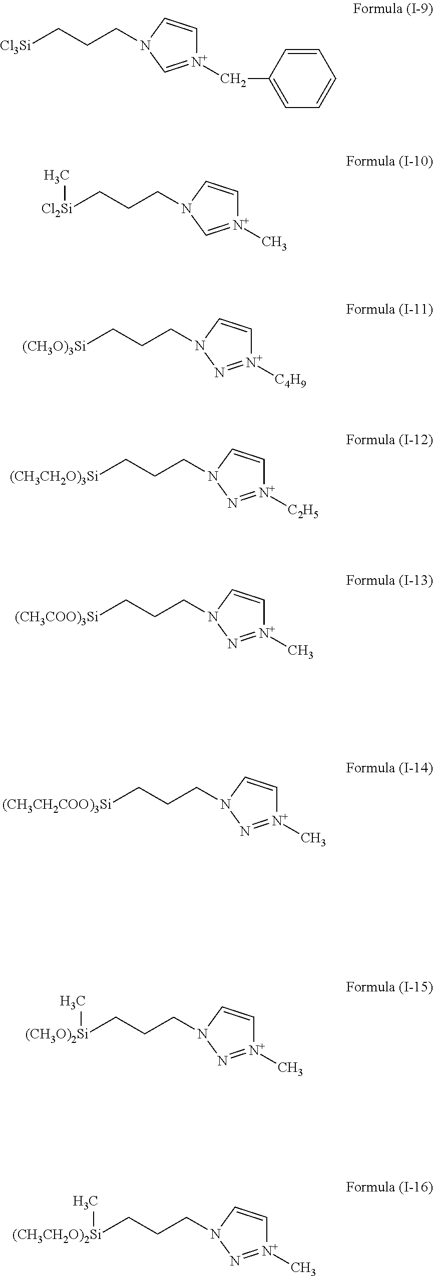

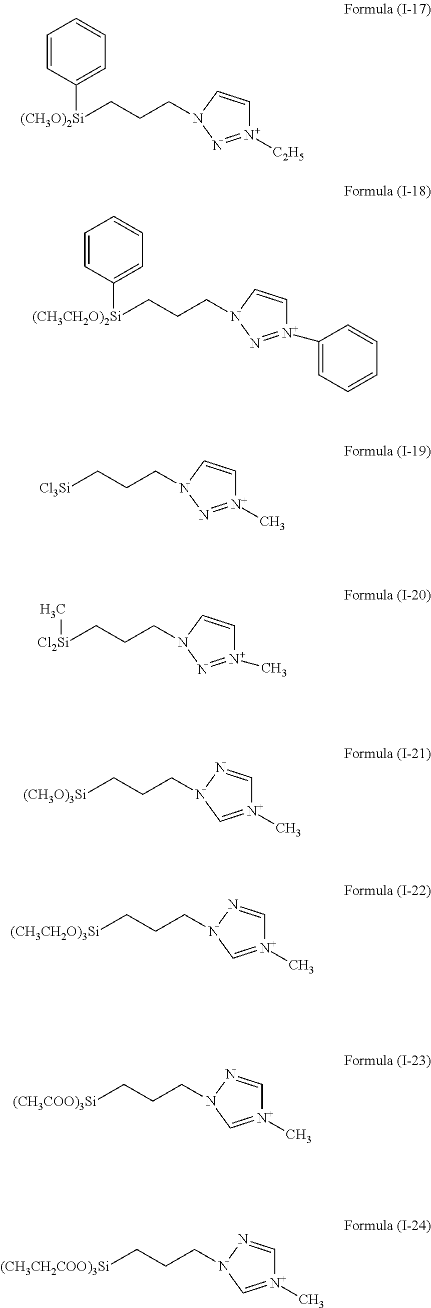

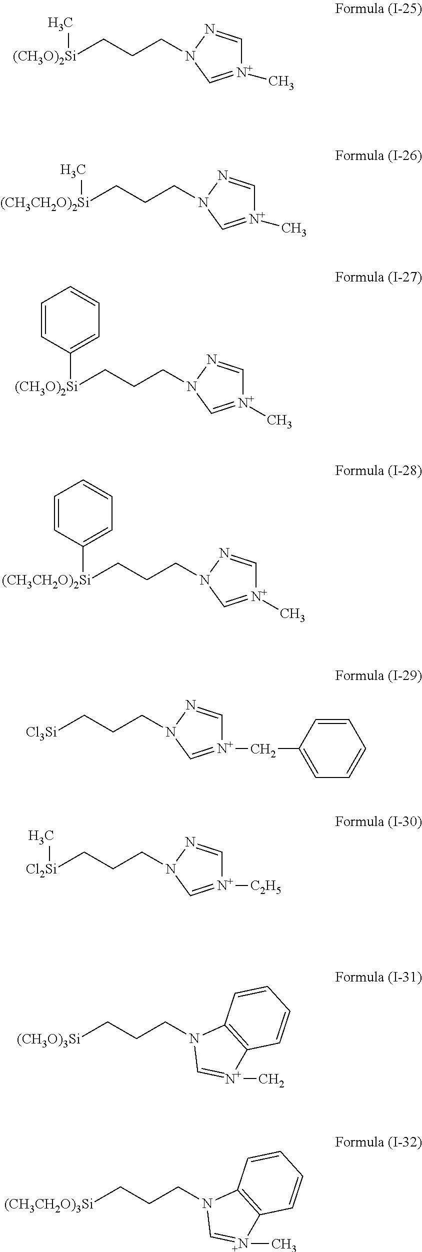

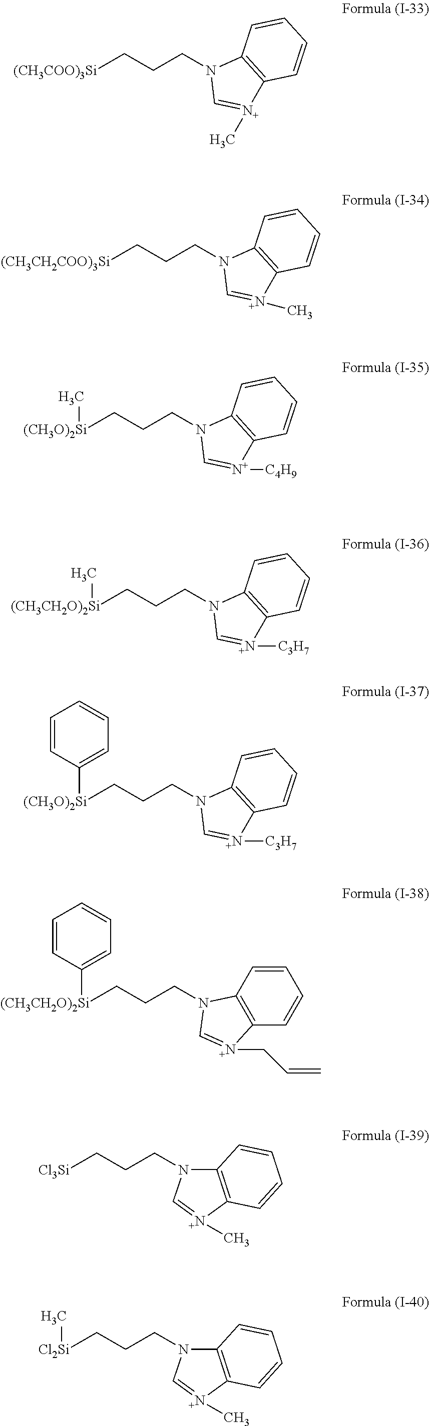

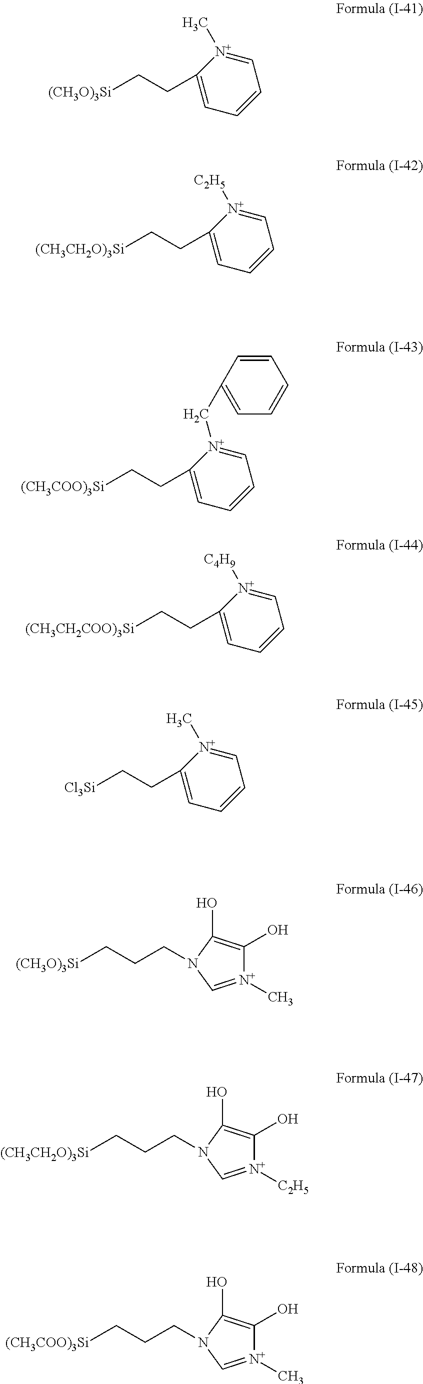

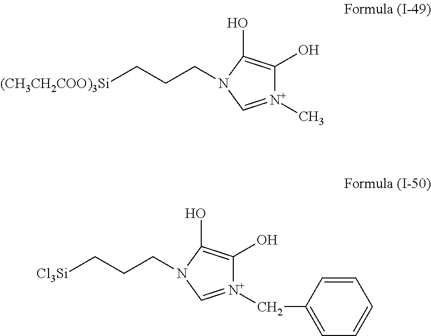

In another example, R¹¹, which is a group that bonds to the silicon atom in Formula (3), can be a heteroaliphatic cyclic ammonium group represented by Formula (S2).

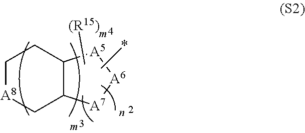

In Formula (S2), A⁵, A⁶, A⁷, and A⁸ each independently represent a group represented by any one of Formulas (J4) to (J6), but at least one of A⁵ to A⁸ is a group represented by Formula (J5). Depending on which of A⁵ to A⁸ the silicon atom in Formula (3) is bonded to, the bond between each of A⁵ to A⁸ and the respective atom adjacent thereto and forming the ring is determined to be a single bond or a double bond such that the ring that is formed is non-aromatic. * represents a bond.

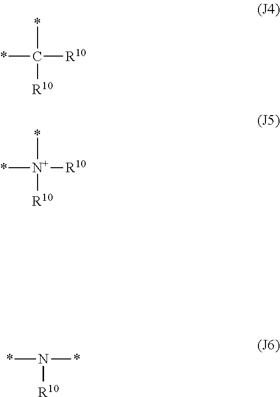

In Formulas (J4) to (J6), each R¹⁰ independently represents a single bond, a hydrogen atom, an alkyl group, an aryl group, an aralkyl group, a halogenated alkyl group, a halogenated aryl group, a halogenated aralkyl groups or an alkenyl group, and specific examples of the alkyl group, aryl group, aralkyl group, halogenated alkyl group, halogenated aryl group, halogenated aralkyl group, and alkenyl group and the preferable number of carbon atoms thereof are the same as those described above. * represents a bond.

In Formula (S2), each R¹⁵ independently represents an alkyl group, an aryl group, an aralkyl group, a halogenated alkyl group, a halogenated aryl group, a halogenated aralkyl group, an alkenyl group, or a hydroxy group, and when two or more R are present, the two R¹⁵ may be bonded to each other to form a ring, a ring formed by two R⁵ may have a bridged ring structure, and in such a case, the cyclic ammonium group has an adamantane ring, a norbornene ring, a spiro ring or the like.

Specific examples of the alkyl group, aryl group, aralkyl group, halogenated alkyl group, halogenated aryl group, halogenated aralkyl group, and alkenyl group, and the preferable number of carbon atoms thereof are the same as those described above.

In Formula (S2), n² is an integer from 1 to 8, m³ is 0 or 1, and m⁴ is 0 or a positive integer from 1 to the maximum number that can be substituted on a monocyclic or polycyclic ring.

When m³ is 0, a (4+n²)-membered ring including A⁵ to A⁸ is formed. That is, a 5-membered ring is formed when n² is 1, a 6-membered ring is formed when n² is 2, a 7-membered ring is formed when n² is 3, an 8-membered ring is formed when n² is 4, a 9-membered ring is formed when n² is 5, a 10-membered ring is formed when n² is 6, an 11-membered ring is formed when n² is 7, and a 12-membered ring is formed when n² is 8.

When m³ is 1, a condensed ring in which a (4+n²)-membered ring containing A⁵ to A⁷ and a 6-membered ring containing A⁸ are condensed is formed.

Depending on which formulas of formulas (J4) to (J6) represent the groups A⁵ to A⁸, each of A⁵ to A⁸ may or may not have a hydrogen atom on the atom constituting the ring, but in a case in which A⁵ to A⁸ each has a hydrogen atom on the atom constituting the ring, the hydrogen atoms may be substituted with R¹⁵. In addition, the ring-constituting atoms other than the ring-constituting atoms in A⁵ to A⁸ may be substituted with R¹⁵.

In view of such circumstances, as described above, m⁴ is selected from 0 or integers from 1 to the maximum number that can be substituted on a monocyclic or polycyclic ring.

The bond of the heteroaliphatic cyclic ammonium group represented by the Formula (S2) is present at any carbon atom or nitrogen atom present in such a single ring or condensed ring, and is directly bonded to a silicon atom, or is bonded to a linking group to form an organic group having a cyclic ammonium, and the organic group is bonded to the Si atom.

Examples of such a linking group include an alkylene group, an arylene group, or an alkenylene group, and specific examples of the alkylene group, arylene group and alkenylene group and the preferable number of carbon atoms thereof are the same as described above.

Specific examples of the silane compound (hydrolyzable organosilane) represented by Formula (3) and having a heteroaliphatic cyclic ammonium group represented by Formula (S2) include, but are not limited to, silanes represented by Formulas (II-1) to (II-30).

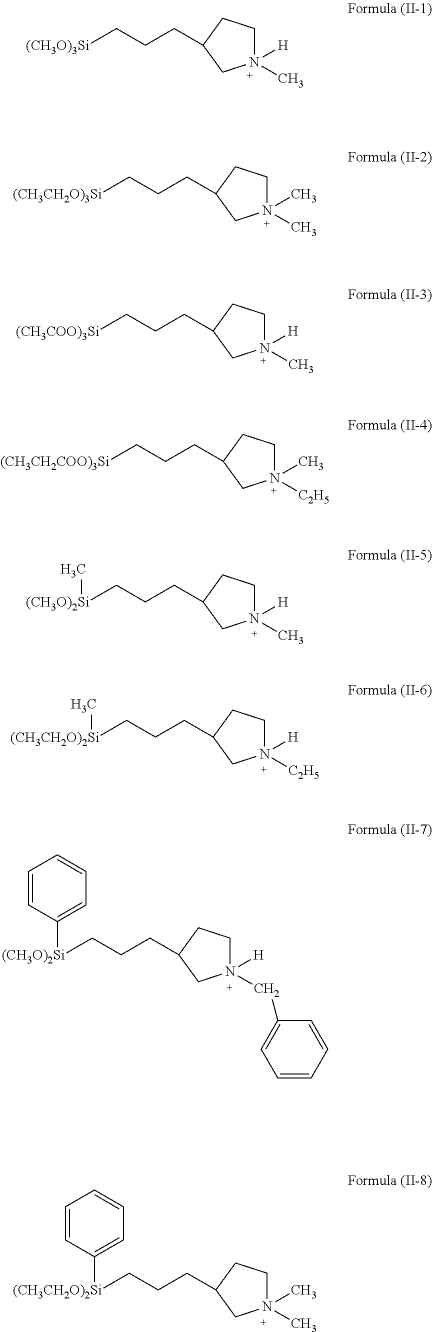

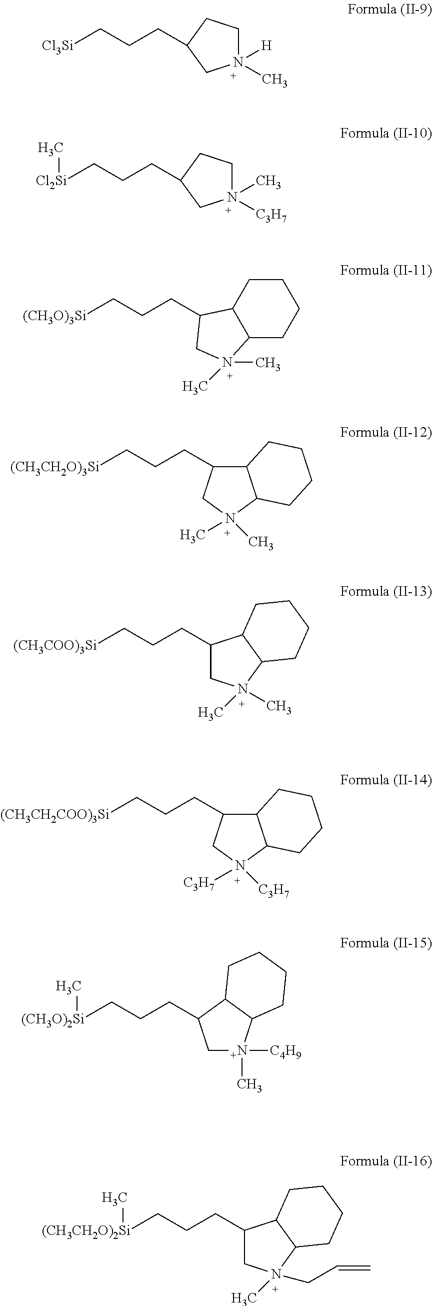

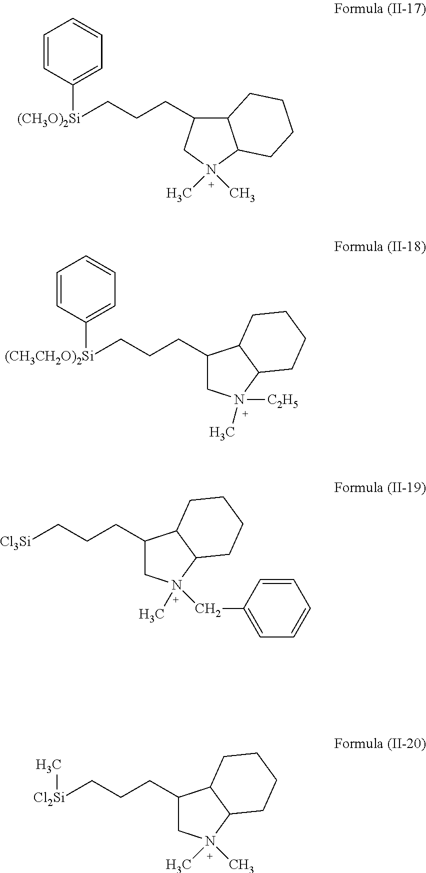

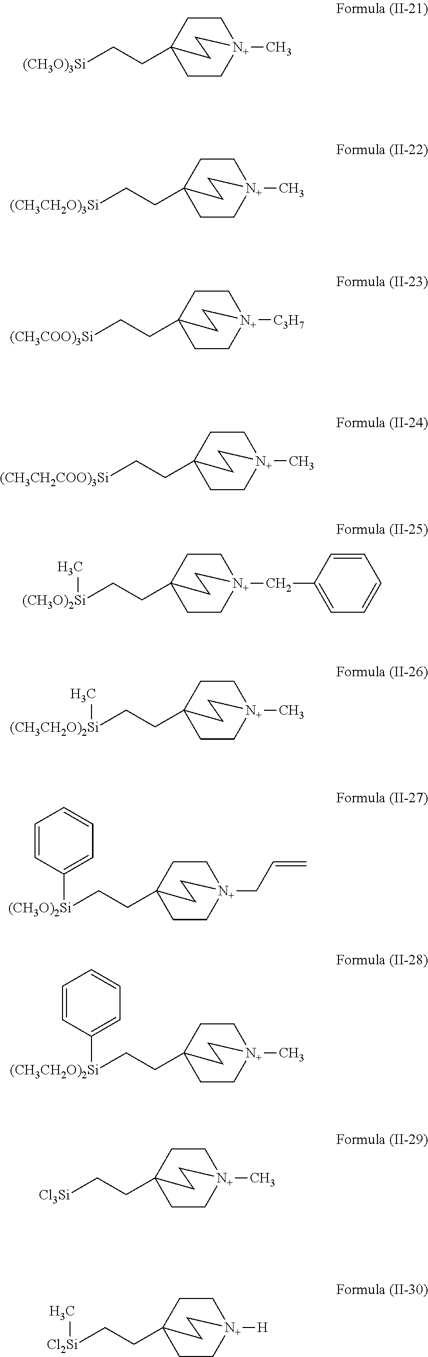

In yet another example, R¹¹, which is group that bonds to the silicon atom in Formula (3), can be a chain-shaped ammonium group represented by Formula (S3).

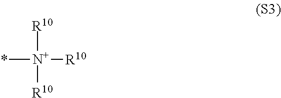

In Formula (S3), each R¹⁰ independently represents a hydrogen atom, an alkyl group, an aryl group, an aralkyl group, a halogenated alkyl group, a halogenated aryl group, a halogenated aralkyl groups or an alkenyl group, and specific examples of the alkyl group, aryl group, aralkyl group, halogenated alkyl group, halogenated aryl group, halogenated aralkyl group, and alkenyl group and preferable numbers of carbon atoms thereof are the same as those described above. * represents a bond.

The chain-shaped ammonium group represented by Formula (S3) is directly bonded to a silicon atom, or is bonded to a linking group to form an organic group having a chain-shaped ammonium group, and the organic group is bonded to the Si atom.

Examples of such a linking group include an alkylene group, an arylene group, or an alkenylene group, and specific examples of the alkylene group, arylene group, and alkenylene group include the same groups as described above.

Specific examples of the silane compound (hydrolyzable organosilane) represented by Formula (3) and having a chain-shaped ammonium group represented by Formula (S3) include, but are not limited to, silanes represented by Formulas (III-1) to (III-28).

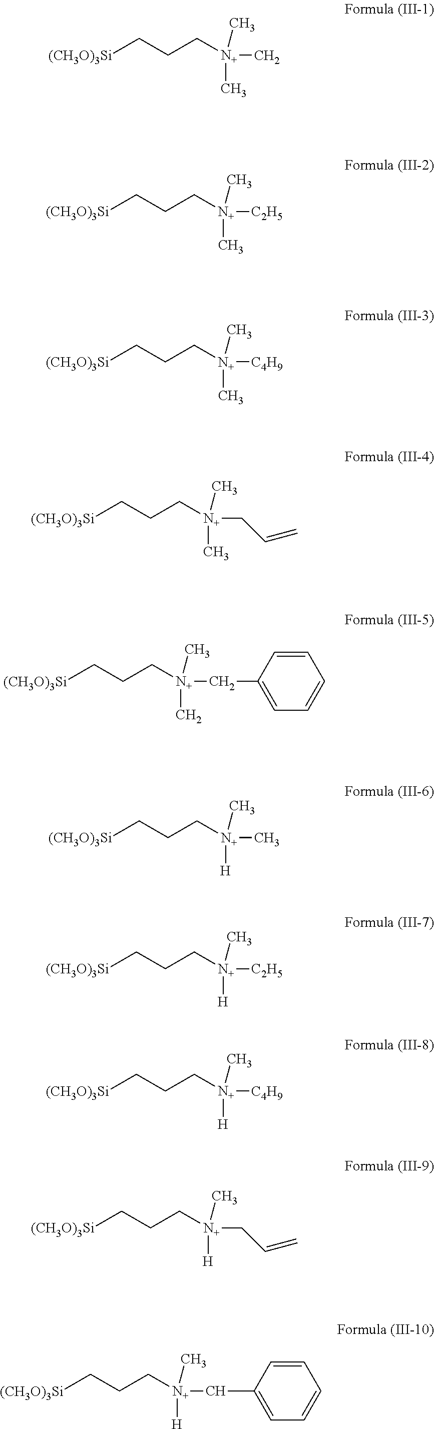

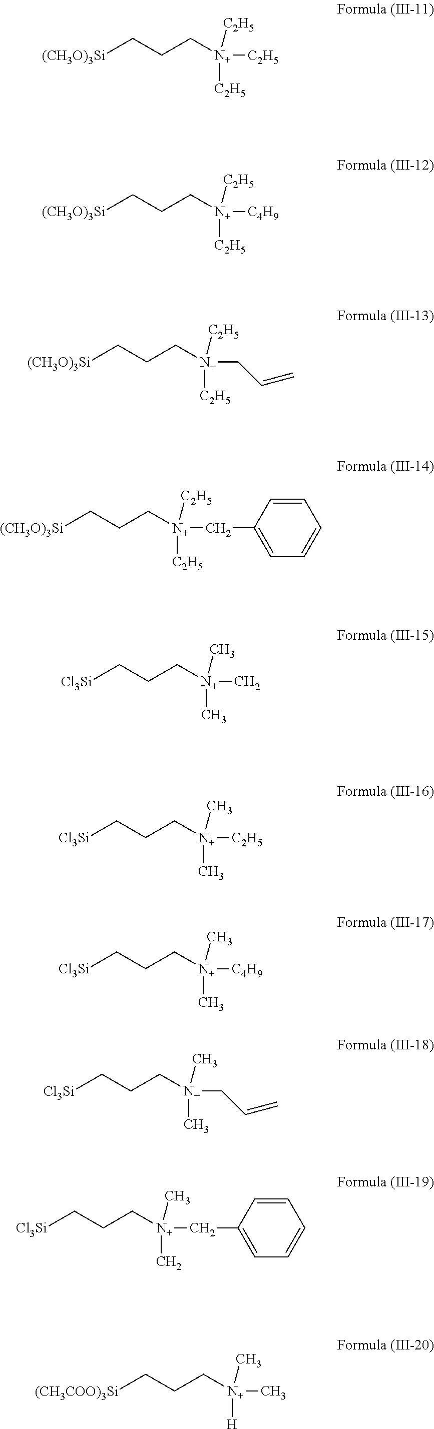

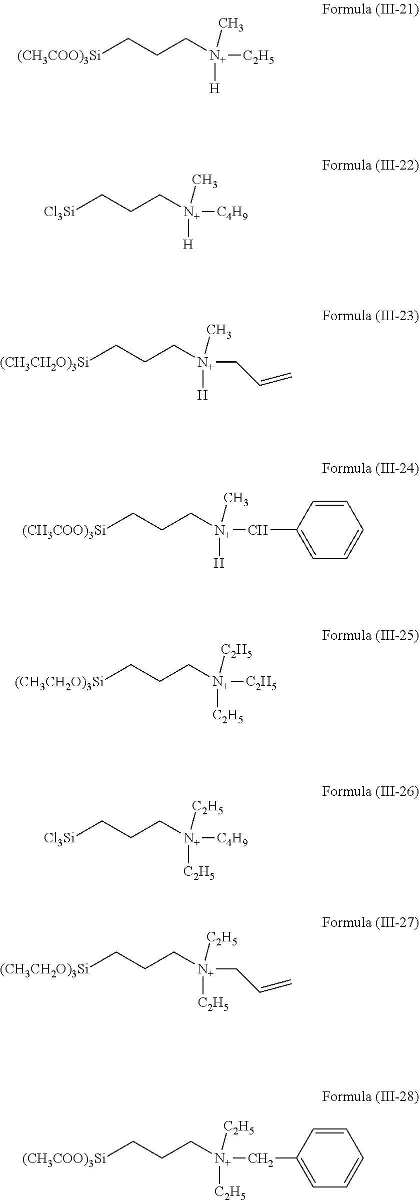

### Silane Compounds (Hydrolyzable Organosilanes) Having Cyclic Urea Skeleton in Molecule

Examples of hydrolyzable organosilanes having a cyclic urea skeleton in the molecule include hydrolyzable organosilanes represented by Formula (4-1).

R⁴⁰¹ₓR⁴⁰²_{y}Si(R⁴⁰³)_{4-(x+y)} (4-1)

In Formula (4-1), R⁴⁰¹ is a group bonded to a silicon atom, and each independently represents a group represented by Formula (4-2).
R⁴⁰² is a group bonded to a silicon atom, and each represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having a cyano group, or a combination of two or more thereof.
R⁴⁰³ is a group or an atom bonded to a silicon atom, and each independently represents an alkoxy group, an aralkyloxy group, an acyloxy group, or a halogen atom.
x is 1 or 2, y is 0 or 1, and (x+y)<2 is satisfied.

With regard to R⁴⁰², specific examples of the alkyl group, aryl group, aralkyl group, halogenated alkyl group, halogenated aryl group, halogenated aralkyl group, alkoxyalkyl group, alkoxyaryl group, alkoxyaralkyl group, alkenyl group, organic group having an epoxy group, organic group having an acryloyl group, organic group having a methacryloyl group, organic group having a mercapto group, and organic group having a cyano group, and with regard to R⁴⁰³, specific examples of the alkoxy group, aralkyloxy group, acyloxy group, and halogen atom, and substituents thereof, and the preferable number of carbon atoms and the like are the same as described above with regard to R² and X in Formula (A-1).

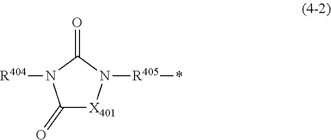

In Formula (4-2), each R⁴⁰⁴ independently represents a hydrogen atom, an optionally substituted alkyl group, an optionally substituted alkenyl group, or an organic group having an epoxy group, or an organic group having a sulfonyl group (with the proviso that a methoxyphenyl sulfonyl group is excluded), and each R⁴⁰⁵ independently represents an alkylene group, a hydroxyalkylene group, a sulfide bond (—S—), an ether bond (—O—), or an ester bond (—CO—O— or —O—CO—). * represents a bond.

Note that with regard to R⁴⁰⁴, specific examples of the optionally substituted alkyl group, the optionally substituted alkenyl group, and the organic group having an epoxy group, and the preferable number of carbon atoms are the same as those described above with regard to R² in Formula (A-1). Furthermore, the optionally substituted alkyl group of R⁴⁰⁴ is preferably an alkyl group in which a terminal hydrogen atom is substituted with a vinyl group, and specific examples thereof include an allyl group, a 2-vinylethyl group, a 3-vinylpropyl group, and a 4-vinylbutyl group.

The organic group having a sulfonyl group is not particularly limited as long as it contains a sulfonyl group, and examples thereof include an optionally substituted alkylsulfonyl group, an optionally substituted arylsulfonyl group, an optionally substituted aralkylsulfonyl group, an optionally substituted halogenated alkylsulfonyl group, an optionally substituted halogenated arylsulfonyl group, an optionally substituted halogenated aralkylsulfonyl group, an optionally substituted alkoxyalkylsulfonyl group, an optionally substituted alkoxyarylsulfonyl group, an optionally substituted alkoxyaralkylsulfonyl group, and an optionally substituted alkenylsulfonyl group.

Specific examples of the alkyl group, aryl group, aralkyl group, halogenated alkyl group, halogenated aryl group, halogenated aralkyl group, alkoxyalkyl group, alkoxyaryl group, alkoxyaralkyl group, and alkenyl group, and substituents of these groups, and the preferable number of carbon atoms are the same as those described above with regard to R² in Formula (A-1).

The alkylene group is a divalent group derived by further removing one hydrogen atom from an alkyl group, and may be linear, branched, or cyclic, and specific examples of the alkylene group include the same groups as those described above. The number of carbon atoms of the alkylene group is not particularly limited, but is preferably 40 or less, more preferably 30 or less, even more preferably 20 or less, and still more preferably 10 or less.

Further, the alkylene group of R⁴⁰⁵ may have one or two or more types of bonds selected from a sulfide bond, an ether bond, and an ester bond at terminal ends or in the middle, and preferably in the middle.

Specific examples of the alkylene group include, but are not limited to, linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group; branched alkylene groups such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; cyclic alkylene groups such as a 1,2-cyclopropanediyl group, a 1,2-cyclobutanediyl group, a 1,3-cyclobutanediyl group, a 1,2-cyclohexanediyl group, and a 1,3-cyclohexanediyl group; and alkylene groups containing an ether group and the like such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂-.

The hydroxyalkylene group is a group in which at least one hydrogen atom of the above-described alkylene group is replaced with a hydroxy group, and specific examples of the hydroxyalkylene group include, but are not limited to, a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group.

In Formula (4-2), each X₄₀₁ independently represents any one of groups represented by Formulas (4-3) to (4-5), and a carbon atom of a ketone group in Formulas (4-4) and (4-5) is bonded to a nitrogen atom to which R⁴⁰⁵ in Formula (4-2) is bonded.

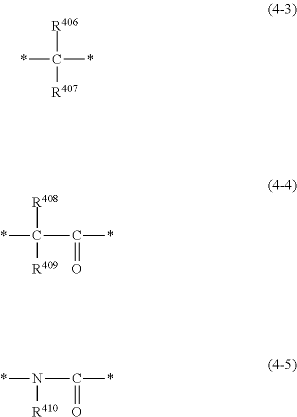

In Formulas (4-3) to (4-5), R⁴⁰⁶ to R⁴¹⁰ each independently represent a hydrogen atom, an optionally substituted alkyl group, an optionally substituted alkenyl group, or an organic group having an epoxy group or a sulfonyl group (with the proviso that a methoxyphenyl sulfonyl group is excluded). Specific examples of the optionally substituted alkyl group, the optionally substituted alkenyl group, and the organic group having an epoxy group or a sulfonyl group (with the proviso that a methoxyphenyl sulfonyl group is excluded), and the preferable number of carbon atoms are the same as those described above with regard to R² in Formula (A-1). Specific examples of the organic group having a sulfonyl group (with the proviso that a methoxyphenyl sulfonyl group), and the preferable number of carbon atoms are the same as those described above with regard to R⁴⁰⁴. * represents a bond.

Among these, from the viewpoint of providing excellent lithography properties with good reproducibility, X₄₀₁ is preferably a group represented by Formula (4-5).

From the viewpoint of providing excellent lithography properties with good reproducibility, at least one of R⁴⁰⁴ and R⁴⁰⁶ to R⁴¹⁰ is preferably an alkyl group in which a terminal hydrogen atom is substituted with a vinyl group.

A commercially available product may be used as the hydrolyzable organosilane represented by Formula (4-1), or the hydrolyzable organosilane thereof can be synthesized by a known method described in WO 2011/102470 or the like.

Specific examples of the hydrolyzable organosilane represented by Formula (4-1) include, but are not limited to, silanes represented by Formulas (4-1-1) to (4-1-29).

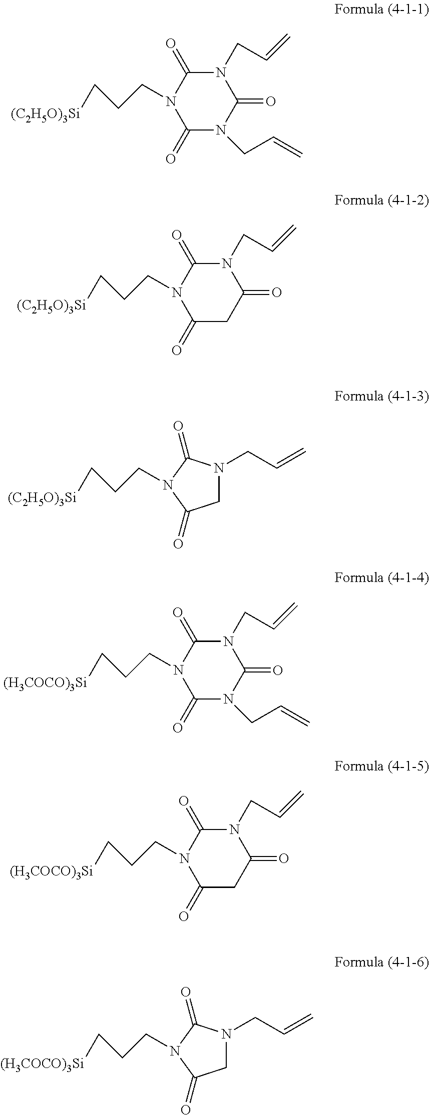

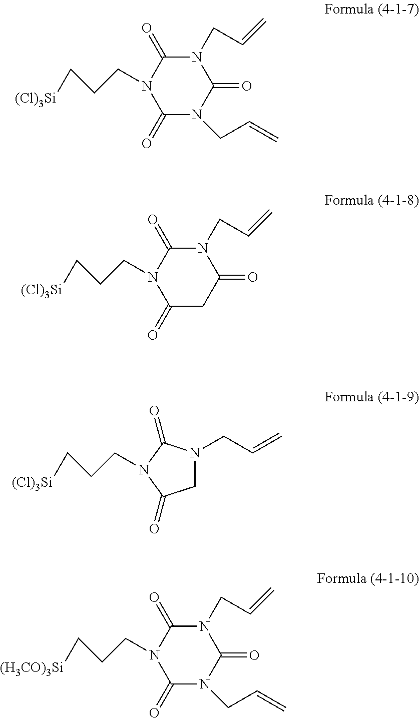

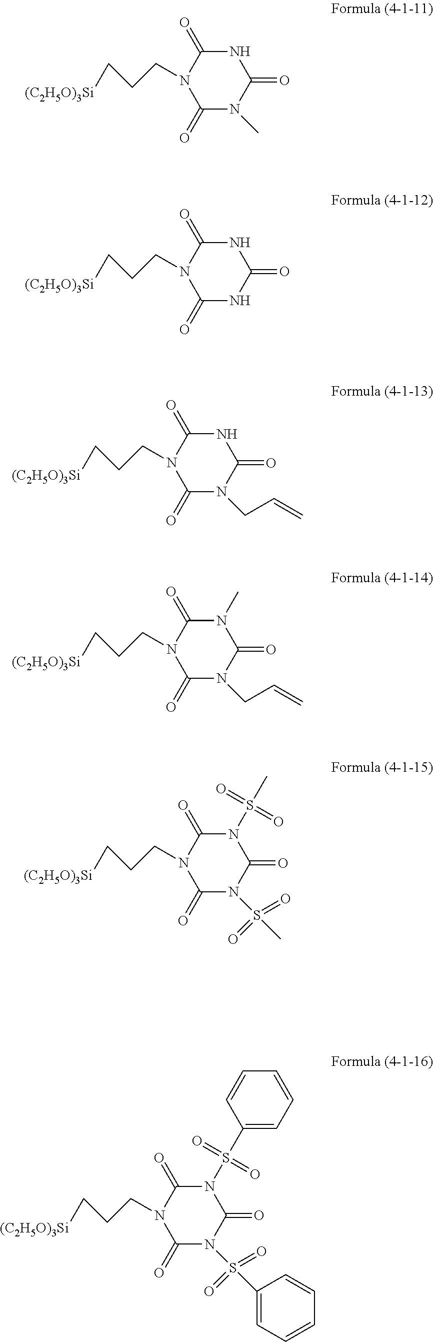

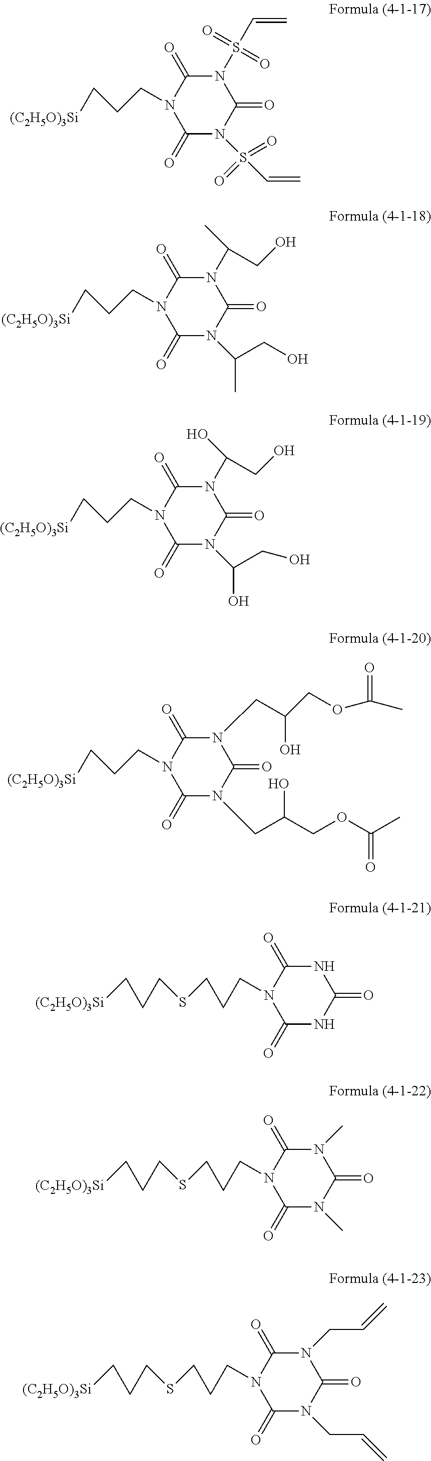

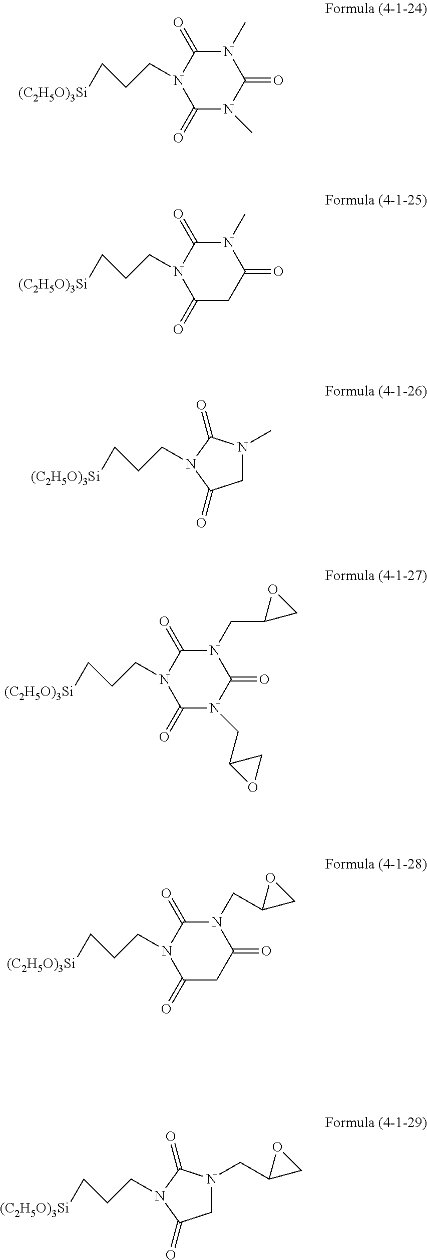

The polysiloxane [A] and the polysiloxane [A′] may be hydrolysis-condensation products of a hydrolyzable silane including a silane compound other than those exemplified above, or a modified product thereof, as long as the effects of the present invention are not impaired.

As described above, a modified product in which at least some of the silanol groups of the hydrolysis-condensation product are modified can be used as the polysiloxane [A] and the polysiloxane [A′]. For example, a modified product in which some of the silanol groups are alcohol-modified, or a modified product in which some of the silanol groups are acetal-protected can be used.

Examples of the polysiloxane that is the modified product include a reaction product produced by a reaction between a hydroxy group of an alcohol and at least some of the silanol groups contained in the condensate of a hydrolysis-condensation product of the hydrolyzable silane described above, a dehydration reaction product of the condensate and an alcohol, and a modified product in which at least some of the silanol groups of the condensate are protected with an acetal group.

A monohydric alcohol can be used as the alcohol, and examples thereof include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-I-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

In addition, an alkoxy group-containing alcohol can be used, such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), and propylene glycol monobutyl ether (1-butoxy-2-propanol).

The reaction between the silanol group of the hydrolysis-condensation product and the hydroxy group of the alcohol is carried out by bringing the hydrolysis-condensation product and the alcohol into contact with each other, and reacting these at a temperature from 40 to 160° C., for example 60° C., for 0.1 to 48 hours, for example 24 hours, to thereby produce a silanol group-capped modified product. At this time, the alcohol of the capping agent can be used as a solvent in the composition containing the polysiloxane.

The dehydration reaction product of an alcohol and a hydrolysis-condensation product of a hydrolyzable silane can be produced by reacting the hydrolysis-condensation product with the alcohol in the presence of an acid as a catalyst, capping the silanol groups with the alcohol, and removing the water produced by dehydration from the reaction system.

For the acid, an organic acid having an acid dissociation constant (pka) from −1 to 5 and preferably from 4 to 5 can be used. For example, the acid may be trifluoroacetic acid, maleic acid, benzoic acid, isobutyric acid, acetic acid, or the like, among which benzoic acid, isobutyric acid, acetic acid, and the like can be exemplified.

Also, for the acid, an acid having a boiling point from 70 to 160° C. can be used, and examples thereof include trifluoroacetic acid, isobutyric acid, acetic acid, and nitric acid.

As described above, the acid preferably has a physical property of either an acid dissociation constant (pka) from 4 to 5 or a boiling point from 70 to 160° C. That is, an acid having weak acidity or an acid having strong acidity but a low boiling point can be used.

Either physical property of the acid dissociation constant or the boiling point can be used with regard to the acid.

A vinyl ether can be used for acetal protection of the silanol group of the hydrolysis-condensation product, and for example, a vinyl ether represented by Formula (5) can be used, and a partial structure represented by Formula (6) can be introduced into the polysiloxane by these reactions.

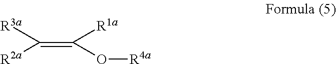

In Formula (5), R^{1a}, R^{2a}, and R^{3a} each represent a hydrogen atom or an alkyl group having from 1 to 10 carbon atoms, R^{4a} represents an alkyl group having from 1 to 10 carbon atoms, and R^{2a} and R^{4a} may be bonded to each other to form a ring. Examples of the alkyl groups include those described above.

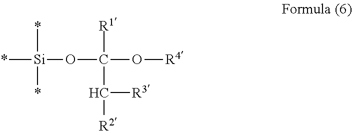

In Formula (6), R¹′, R²′, and R³′ each represent a hydrogen atom or an alkyl group having from 1 to 10 carbon atoms, R⁴′ represents an alkyl group having from 1 to 10 carbon atoms, and R²′ and R⁴′ may be bonded to each other to form a ring. In Formula (6), * represents a bond with an adjacent atom. Examples of the adjacent atom include an oxygen atom of a siloxane bond, an oxygen atom of a silanol group, and a carbon atom derived from R¹ in Formula (1). Examples of the alkyl groups include those described above.

Examples of the vinyl ether represented by Formula (5) include aliphatic vinyl ether compounds such as methyl vinyl ether, ethyl vinyl ether, isopropyl vinyl ether, n-butyl vinyl ether, 2-ethylhexyl vinyl ether, tert-butyl vinyl ether, and cyclohexyl vinyl ether; and cyclic vinyl ether compounds such as 2,3-dihydrofuran, 4-methyl-2,3-dihydrofuran and 3,4-dihydro-2H-pyran. In particular, ethyl vinyl ether, propyl vinyl ether, butyl vinyl ether, ethylhexyl vinyl ether, cyclohexylvinyl ether, 3,4-dihydro-2H-pyran, or 2,3-dihydrofuran can be preferably used.

Acetal protection of the silanol group can be carried out using a hydrolysis-condensation product, vinyl ether, an aprotic solvent such as propylene glycol monomethyl ether acetate, ethyl acetate, dimethylformamide, tetrahydrofuran, or 1,4-dioxane as the solvent, and a catalyst such as pyridium p-toluene sulfonate, trifluoromethane sulfonate, p-toluene sulfonate, methane sulfonate, hydrochloric acid, or sulfuric acid.

The capping of these silanol groups with an alcohol and the acetal protection may be carried out simultaneously with the hydrolysis and condensation of the hydrolyzable silane, which will be described below.

The hydrolysis-condensation product of the hydrolyzable silane, or a modified product thereof may have a weight average molecular weight of, for example, from 500 to 1000000. From the viewpoint of suppressing precipitation or the like of the hydrolysis-condensation product or modified product thereof in the composition, the weight average molecular weight may be preferably 500000 or less, more preferably 250000 or less, and even more preferably 100000 or less, and from the viewpoint of achieving both storage stability and coatability, the weight average molecular weight may be preferably 700 or greater, and more preferably 1000 or greater.

The weight average molecular weight is a molecular weight determined in terms of polystyrene by gel permeation chromatography (GPC) analysis. GPC analysis can be implemented using, for example, a GPC apparatus (product name: HLC-8220GPC, available from Tosoh Corporation), a GPC column (product name: Shodex (trade name) KF803L, KF802, KF801, available from Showa Denko K.K.), a column temperature of 40° C., tetrahydrofuran as an eluent (elution solvent), a flow rate (flow speed) of 1.0 mL/min, and polystyrene (Shodex (trade name), available from Showa Denko K.K.) as a standard sample.

The hydrolysis-condensation product of the hydrolyzable silane is produced by hydrolyzing and condensing the above-described silane compound (hydrolyzable silane).

The silane compound (hydrolyzable silane) contains an alkoxy group, an aralkyloxy group, an acyloxy group, or a halogen atom directly bonded to a silicon atom, that is, an alkoxysilyl group, an aralkyloxysilyl group, an acyloxysilyl group, or a halogenated silyl group (hereinafter, referred to as a hydrolyzable group).

Water is used in the hydrolysis of these hydrolyzable groups at an amount usually from 0.1 to 100 moles, for example, from 0.5 to 100 moles, and preferably from 1 to 10 moles, per mole of the hydrolyzable group.

At the time of hydrolysis and condensation, a hydrolysis catalyst may be used for the purpose of promoting the reaction or the like, or hydrolysis and condensation may be carried out without using a hydrolysis catalyst. When a hydrolysis catalyst is used, the hydrolysis catalyst can be used at an amount usually from 0.0001 to 10 moles, and preferably from 0.001 to 1 mole, per mole of the hydrolyzable group.

The reaction temperature when carrying out hydrolysis and condensation is usually in a range from room temperature to the reflux temperature at normal pressure of the organic solvent that can be used for hydrolysis, and may be, for example, a temperature from 20 to 110° C., or for example, from 20 to 80° C.

The hydrolysis may be complete hydrolysis in which all hydrolyzable groups are converted to silanol groups, or may be partial hydrolysis in which unreacted hydrolyzable groups remain.

Examples of the hydrolysis catalyst that can be used for hydrolysis and condensation include metal chelate compounds, organic acids, inorganic acids, organic bases, and inorganic bases.

Examples of the metal chelate compound as the hydrolysis catalyst include, but are not limited to, titanium chelate compounds, such as triethoxy-mono(acetylacetonato)titanium, tri-n-propoxy-mono(acetylacetonato)titanium, tri-i-propoxy-mono(acetylacetonato)titanium, tri-n-butoxy-mono(acetylacetonato)titanium, tri-sec-butoxy-mono(acetylacetonato)titanium, tri-t-butoxy-mono(acetylacetonato)titanium, diethoxy-bis(acetylacetonato)titanium, di-n-propoxy-bis(acetylacetonato)titanium, di-i-propoxy-bis(acetylacetonato)titanium, di-n-butoxy-bis(acetylacetonato)titanium, di-sec-butoxy-bis(acetylacetonato)titanium, di-t-butoxy-bis(acetylacetonato)titanium, monoethoxy-tris(acetylacetonato)titanium, mono-n-propoxy-tris(acetylacetonato)titanium, mono-i-propoxy-tris(acetylacetonato)titanium, mono-n-butoxy-tris(acetylacetonato)titanium, mono-sec-butoxy-tris(acetylacetonato)titanium, mono-t-butoxy-tris(acetylacetonato)titanium, tetrakis(acetylacetonato)titanium, triethoxy-mono(ethylacetoacetate)titanium, tri-n-propoxy-mono(ethylacetoacetate)titanium, tri-i-propoxy-mono(ethylacetoacetate)titanium, tri-n-butoxy-mono(ethylacetoacetate)titanium, tri-sec-butoxy-mono(ethylacetoacetate)titanium, tri-t-butoxy-mono(ethylacetoacetate)titanium, diethoxy-bis(ethylacetoacetate)titanium, di-n-propoxy-bis(ethylacetoacetate)titanium, di-i-propoxy-bis(ethylacetoacetate)titanium, di-n-butoxy-bis(ethylacetoacetate)titanium, di-sec-butoxy-bis(ethylacetoacetate)titanium, di-t-butoxy-bis(ethylacetoacetate)titanium, monoethoxy-tris(ethylacetoacetate)titanium, mono-n-propoxy-tris(ethylacetoacetate)titanium, mono-i-propoxy-tris(ethylacetoacetate)titanium, mono-n-butoxy-tris(ethylacetoacetate)titanium, mono-sec-butoxy-tris(ethylacetoacetate)titanium, mono-t-butoxy-tris(ethylacetoacetate)titanium, tetrakis(ethylacetoacetate)titanium, mono(acetylacetonato)tris(ethylacetoacetate)titanium, bis(acetylacetonato)bis(ethylacetoacetate)titanium, and tris(acetylacetonato)mono(ethylacetoacetate)titanium; zirconium chelate compounds, such as triethoxy-mono(acetylacetonato)zirconium, tri-n-propoxy-mono(acetylacetonato)zirconium, tri-i-propoxy-mono(acetylacetonato)zirconium, tri-n-butoxy-mono(acetylacetonato)zirconium, tri-sec-butoxy-mono(acetylacetonato)zirconium, tri-t-butoxy-mono(acetylacetonato)zirconium, diethoxy-bis(acetylacetonato)zirconium, di-n-propoxy-bis(acetylacetonato)zirconium, di-i-propoxy-bis(acetylacetonato)zirconium, di-n-butoxy-bis(acetylacetonato)zirconium, di-sec-butoxy-bis(acetylacetonato)zirconium, di-t-butoxy-bis(acetylacetonato)zirconium, monoethoxy-tris(acetylacetonato)zirconium, mono-n-propoxy-tris(acetylacetonato)zirconium, mono-i-propoxy-tris(acetylacetonato)zirconium, mono-n-butoxy-tris(acetylacetonato)zirconium, mono-sec-butoxy-tris(acetylacetonato)zirconium, mono-t-butoxy-tris(acetylacetonato)zirconium, tetrakis(acetylacetonato)zirconium, triethoxy-mono(ethylacetoacetate)zirconium, tri-n-propoxy-mono(ethylacetoacetate)zirconium, tri-i-propoxy-mono(ethylacetoacetate)zirconium, tri-n-butoxy-mono(ethylacetoacetate)zirconium, tri-sec-butoxy-mono(ethylacetoacetate)zirconium, tri-t-butoxy-mono(ethylacetoacetate)zirconium, diethoxy-bis(ethylacetoacetate)zirconium, di-n-propoxy-bis(ethylacetoacetate)zirconium, di-i-propoxy-bis(ethylacetoacetate)zirconium, di-n-butoxy-bis(ethylacetoacetate)zirconium, di-sec-butoxy-bis(ethylacetoacetate)zirconium, di-t-butoxy-bis(ethylacetoacetate)zirconium, monoethoxy-tris(ethylacetoacetate)zirconium, mono-n-propoxy-tris(ethylacetoacetate)zirconium, mono-i-propoxy-tris(ethylacetoacetate)zirconium, mono-n-butoxy-tris(ethylacetoacetate)zirconium, mono-sec-butoxy-tris(ethylacetoacetate)zirconium, mono-t-butoxy-tris(ethylacetoacetate)zirconium, tetrakis(ethylacetoacetate)zirconium, mono(acetylacetonato)tris(ethylacetoacetate)zirconium, bis(acetylacetonato)bis(ethylacetoacetate)zirconium, and tris(acetylacetonato)mono(ethylacetoacetate)zirconium; and aluminum chelate compounds, such as tris(acetylacetonato)aluminum and tris(ethylacetoacetate)aluminum.

Examples of the organic acid as the hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid as the hydrolysis catalyst include, but are not limited to, hydrochloric acid, nitric acid, sulfuric acid, hydrofluoric acid, and phosphoric acid.

Examples of the organic base as the hydrolysis catalyst include, but are not limited to, pyridine, pyrrole, piperazine, pyrrolidine, piperidine, picoline, trimethylamine, triethylamine, monoethanolamine, diethanolamine, dimethyl monoethanolamine, monomethyl diethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base as the hydrolysis catalyst include, but are not limited to, ammonia, sodium hydroxide, potassium hydroxide, barium hydroxide, and calcium hydroxide.

Among these catalysts, metal chelate compounds, organic acids, and inorganic acids are preferable, and a single type of these may be used alone or two or more types of these may be used in combination.

Among these, nitric acid can be suitably used as the hydrolysis catalyst in the present invention. By using nitric acid, the storage stability of the reaction solution after hydrolysis and condensation can be improved, and in particular, a change in the molecular weight of the hydrolysis-condensation product or modified product thereof can be suppressed. It is known that the stability of a hydrolysis-condensation product or modified product thereof in a liquid depends on the pH of the solution. Further, as a result of intensive studies, it was found that the pH of the solution is set to a stable range by using an appropriate amount of nitric acid.

In addition, as described above, since nitric acid can also be used in producing a modified product of a hydrolysis-condensation product, for example, in capping a silanol group with an alcohol, nitric acid is preferable in that nitric acid can contribute to both the hydrolysis and condensation reactions of the hydrolyzable silane and the reaction for alcohol capping of the hydrolysis-condensation product.

When hydrolysis and condensation are implemented, an organic solvent may be used as the solvent, and specific examples thereof include, but are not limited to aliphatic hydrocarbon-based solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon-based solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; mono-alcohol-based solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenyl methyl carbinol, diacetone alcohol, and cresol; polyhydric alcohol-based solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone-based solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethyl nonanone, cyclohexanone, methylcyclohexanone, 2,4-pentanedione, acetonylacetone, diacetone alcohol, acetophenone, and fenchone; ether-based solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether(1-methoxy-2-propanol), propylene glycol monoethyl ether(1-ethoxy-2-propanol), propylene glycol monopropyl ether, propylene glycol monobutyl ether, propylene glycol monomethyl ether acetate(1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester-based solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethylene glycol diacetate, triethylene glycolmethyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methyl formamide, N,N-dimethyl formamide, N,N-diethyl formamide, acetamide, N-methyl acetamide, N,N-dimethyl acetamide, N-methyl propionamide, and N-methyl-2-pyrrolidone; and sulfur-containing solvents, such as dimethyl sulfide, diethyl sulfide, thiophene, tetrahydrothiophene, dimethyl sulfoxide, sulfolane, and 1,3-propane sultone. A single type of these solvents may be used alone or two or more thereof may be used in combination.

After completion of the hydrolysis and condensation reaction, the reaction solution as is or after being diluted or concentrated can be neutralized, and then treated with an ion-exchange resin to remove the hydrolysis catalyst such as an acid or a base used in the hydrolysis and condensation. Before or after such treatment, alcohol and water by-products, the hydrolysis catalyst that has been used, and the like can be removed from the reaction solution by distillation under reduced pressure or the like.

The hydrolysis-condensation product or modified product thereof (hereinafter, also referred to as polysiloxane) produced in this manner is in the form of a polysiloxane varnish dissolved in an organic solvent, and can be used in that form to prepare a silicon-containing resist underlayer film-forming composition. That is, the reaction solution can be used as is (or after dilution) to prepare a silicon-containing resist underlayer film-forming composition, and at this time, the by-products, the hydrolysis catalyst used for hydrolysis and condensation, and the like may remain in the reaction solution as long as the effects of the present invention are not impaired. For example, the hydrolysis catalyst or nitric acid used for alcohol capping of silanol groups may remain in the polymer varnish solution at an approximate amount from 100 ppm to 5000 ppm.

The resulting polysiloxane varnish may be subjected to solvent substitution or may be appropriately diluted with a solvent. If the storage stability of the resulting polysiloxane varnish is not poor, the organic solvent may be distilled off to achieve a film-forming component concentration of 100%. The term “film-forming component” refers to a component produced by removing the solvent component from all components of the composition.

The organic solvent used for solvent substitution or dilution of the polysiloxane varnish may be the same as or different from the organic solvent used in the hydrolysis and condensation reaction of the hydrolyzable silane. The solvent for dilution is not particularly limited, and one type or two or more types can be optionally selected and used.

### Component [C]: Solvent

In the first embodiment, as the component [C], any solvent can be used without particular limitation as long as the solvent can dissolve the component [A] and, if necessary, other components contained in the silicon-containing resist underlayer film-forming composition, and is miscible therewith.

In the second embodiment, as the component [C], any solvent can be used without particular limitation as long as the solvent can dissolve the component [A′], the component [B], and if necessary, other components contained in the silicon-containing resist underlayer film-forming composition, and is miscible therewith.

The solvent [C] is preferably an alcohol-based solvent, more preferably an alkylene glycol monoalkyl ether, which is an alcohol-based solvent, and even more preferably a propylene glycol monoalkyl ether. Since these solvents are also capping agents for the silanol group of the hydrolysis-condensation product, the silicon-containing resist underlayer film-forming composition can be prepared from a solution produced by preparing the polysiloxane [A] or the polysiloxane [A′] without requiring solvent substitution or the like.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Specific examples of other solvents [C] include methyl cellosolve acetate, ethyl cellosolve acetate, propylene glycol propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and y-butyrolactone. Furthermore, a single type of solvent can be used alone, or two or more can be used in combination.

The silicon-containing resist underlayer film-forming composition of the present invention may contain water as a solvent. When water is contained as the solvent, the content thereof may be, for example, 30 mass % or less, preferably 20 mass % or less, and more preferably 15 mass % or less, with respect to the total mass of the solvent contained in the composition.

### Component [D]: Curing Catalyst

The silicon-containing resist underlayer film-forming composition may be a composition containing no curing catalyst, but the composition thereof preferably contains a curing catalyst (component [D]).

Ammonium salts, phosphines, phosphonium salts, sulfonium salts, and the like can be used as the curing catalyst. The salts described below as examples of the curing catalyst may be added in the form of a salt, or may be formed in the composition (when added, the component is added as a separate compound and forms a salt in the system).

Examples of ammonium salts include quaternary ammonium salts having a structure represented by Formula (D-1):

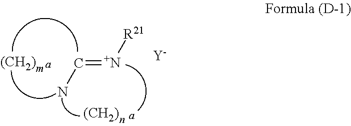

where m^{a} represents an integer from 2 to 11, n^{a} represents an integer of 2 or 3, R²¹ represents an alkyl group, an aryl group, or an aralkyl group, and Y⁻ represents an anion;
quaternary ammonium salts having a structure represented by Formula (D-2):

R²²R²³R²⁴R²⁵N⁺Y⁻ Formula (D-2)
where R²², R²³, R²⁴, and R²⁵ each independently represent an alkyl group, an aryl group, or an aralkyl group, Y⁻ represents an anion, and R²², R²³, R²⁴, and R²⁵ are each bonded to a nitrogen atom;
quaternary ammonium salts having a structure represented by Formula (D-3):

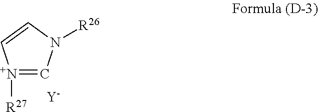

where R²⁶ and R²⁷ each independently represent an alkyl group, an aryl group, or an aralkyl group, and Y⁻ represents an anion;
quaternary ammonium salts having a structure represented by Formula (D-4):

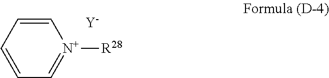

where R²⁸ represents an alkyl group, an aryl group, or an aralkyl group, and Y⁻ represents an anion;
quaternary ammonium salts having a structure represented by Formula (D-5):

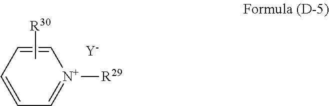

where R²⁹ and R³⁰ each independently represent an alkyl group, an aryl group, or an aralkyl group, and Y⁻ represents an anion); and
tertiary ammonium salts having a structure represented by Formula (D-6):

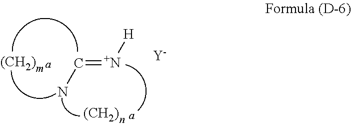

where m^{a} represents an integer from 2 to 11, n^{a} represents an integer of 2 or 3, and Y⁻ represents an anion.

In addition, examples of phosphonium salts include quaternary phosphonium salts represented by Formula (D-7):

R³¹R³²R³³R³⁴P⁺Y⁻ Formula (D-7)
where R³¹, R³², R³³, and R³⁴ each independently represent an alkyl group, an aryl group, or an aralkyl group, Y⁻ represents an anion, and R³¹, R³², R³³, and R³⁴ are each bonded to a phosphorus atom.

Moreover, examples of sulfonium salts include tertiary sulfonium salts represented by Formula (D-8):

R³⁵R³⁶R³⁷S⁺Y⁻ Formula (D-8)
where R³⁵, R³⁶, and R³⁷ each independently represent an alkyl group, an aryl group or an aralkyl group, Y⁻ represents an anion, and R³⁵, R³⁶, and R³⁷ are each bonded to a sulfur atom.

The compound of the Formula (D-1) is a quaternary ammonium salt derived from an amine, m^{a} represents an integer from 2 to 11, and n^{a} represents an integer of 2 or 3. R²¹ of this quaternary ammonium salt represents, for example, an alkyl group having from 1 to 18 carbon atoms or preferably from 2 to 10 carbon atoms, an aryl group having from 6 to 18 carbon atoms, or an aralkyl group having from 7 to 18 carbon atoms, and examples thereof include linear alkyl groups such as an ethyl group, a propyl group, and a butyl group, and a benzyl group, a cyclohexyl group, a cyclohexylmethyl group, and a dicyclopentadienyl group. Examples of the anion (Y⁻) include halide ions such as a chlorine ion (Cl⁻), a bromine ion (Br⁻), and an iodine ion (I⁻), and acid groups such as a carboxylate (—COO⁻), a sulfonate (—SO₃⁻), and an alcoholate (—O⁻).

The compound of Formula (D-2) is a quaternary ammonium salt represented by R²²R²³R²⁴R²⁵N⁺Y⁻. R²², R²³, R²⁴, and R²⁵ of the quaternary ammonium salt are, for example, an alkyl group having from 1 to 18 carbon atoms, such as an ethyl group, a propyl group, a butyl group, a cyclohexyl group, or a cyclohexylmethyl group, an aryl group having from 6 to 18 carbon atoms such as a phenyl group, or an aralkyl group having from 7 to 18 carbon atoms such as a benzyl group. Examples of the anion (Y⁻) include halide ions such as chlorine ion (Cl⁻), a bromine ion (Br⁻), and iodine ion (I⁻), and acid groups such as a carboxylate (—COO⁻), a sulfonate (—SO₃⁻), and alcoholate (—O⁻). The quaternary ammonium salt is available as a commercial product, and examples thereof include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole, the number of carbon atoms of each of R²⁶ and R²⁷ is, for example, from 1 to 18, and the sum of the number of carbon atoms of R²⁶ and R²⁷ is preferably 7 or greater. For example, R²⁶ may be an alkyl group such as a methyl group, an ethyl group, or a propyl group, an aryl group such as a phenyl group, or an aralkyl group such as a benzyl group, and R²⁷ may be an aralkyl group such as a benzyl group or an alkyl group such as an octyl group or an octadecyl group. Examples of the anion (Y⁻) include halide ions such as chlorine ion (Cl⁻), a bromine ion (Br⁻), and iodine ion (I⁻), and acid groups such as a carboxylate (—COO⁻), a sulfonate (—SO₃⁻), and alcoholate (—O⁻). Although this compound is available as a commercial product, it can also be produced by, for example, reacting an imidazole-based compound such as 1-methylimidazole or 1-benzylimidazole with a halogenated aralkyl, a halogenated alkyl, or a halogenated aryl, such as benzyl bromide, methyl bromide or benzene bromide.

The compound of Formula (D-4) is a quaternary ammonium salt derived from pyridine, and R²⁸ is, for example, an alkyl group having from 1 to 18 carbon atoms or preferably from 4 to 18 carbon atoms, an aryl group having from 6 to 18 carbon atoms, or an aralkyl group having from 7 to 18 carbon atoms, and examples thereof include a butyl group, an octyl group, a benzyl group, and a lauryl group. Examples of the anion (Y⁻) include halide ions such as chlorine ion (Cl⁻), a bromine ion (Br⁻), and iodine ion (I⁻), and acid groups such as a carboxylate (—COO⁻), a sulfonate (—SO₃⁻), and alcoholate (—O⁻). Although this compound is available as a commercial product, it can also be produced by, for example, reacting pyridine with a halogenated alkyl or a halogenated aryl, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine represented by picoline or the like, and R²⁹ is, for example, an alkyl group having from 1 to 18 carbon atoms or preferably from 4 to 18 carbon atoms, an aryl group having from 6 to 18 carbon atoms, or an aralkyl group having from 7 to 18 carbon atoms, and examples thereof include a methyl group, an octyl group, a lauryl group, and a benzyl group. R³⁰ is, for example, an alkyl group having from 1 to 18 carbon atoms, an aryl group having from 6 to 18 carbon atoms, or an aralkyl group having from 7 to 18 carbon atoms, and for example, when the compound represented by Formula (D-5) is a quaternary ammonium derived from picoline, R³⁰ is a methyl group. Examples of the anion (Y⁻) include halide ions such as chlorine ion (Cl⁻), a bromine ion (Br⁻), and iodine ion (I⁻), and acid groups such as a carboxylate (—COO⁻), a sulfonate (—SO₃⁻), and alcoholate (—O⁻). Although this compound is available as a commercial product, it can also be produced by, for example, reacting a substituted pyridine such as picoline with a halogenated alkyl or a halogenated aryl, such as methyl bromide, octyl bromide, lauryl chloride, benzyl chloride or benzyl bromide. Examples of this compound include N-benzyl picolinium chloride, N-benzyl picolinium bromide, and N-lauryl picolinium chloride.

The compound of Formula (D-6) is a tertiary ammonium salt derived from an amine, m^{a} represents an integer from 2 to 11, and n^{a} represents 2 or 3. Examples of the anion (Y⁻) include halide ions such as a chlorine ion (Cl⁻), a bromine ion (Br⁻), and an iodine ion (I⁻), and acid groups such as a carboxylate (—COO⁻), a sulfonate (—SO₃⁻), and an alcoholate (—O⁻). This compound can be produced by reacting an amine with a weak acid such as carboxylic acid or phenol. Examples of the carboxylic acid include formic acid and acetic acid, and when formic acid is used, the anion (Y⁻) is (HCOO⁻), and when acetic acid is used, the anion (Y⁻) is (CH₃COO⁻). When phenol is used, the anion (Y⁻) is (C₆H₅O⁻).

The compound of Formula (D-7) is a quaternary phosphonium salt having the structure of R³¹R³²R³³R³⁴P⁺Y⁻. R³¹, R³², R³³ and R³⁴ are each, for example, an alkyl group having from 1 to 18 carbon atoms, such as an ethyl group, a propyl group, a butyl group, or a cyclohexylmethyl, an aryl group having from 6 to 18 carbon atoms such as a phenyl group, or an aralkyl group having from 7 to 18 carbon atoms such as a benzyl group, and preferably three of the four substituents of R³¹ to R³⁴ are unsubstituted phenyl groups or substituted phenyl groups such as a phenyl group and a tolyl group, and the remaining one substituent is an alkyl group having from 1 to 18 carbon atoms, an aryl group having from 6 to 18 carbon atoms, or an aralkyl group having from 7 to 18 carbon atoms. Examples of the anion (Y⁻) include halide ions such as a chlorine ion (Cl⁻), a bromine ion (Br⁻), and an iodine ion (I⁻), and acid groups such as a carboxylate (—COO⁻), a sulfonate (—SO₃⁻), and an alcoholate (—O⁻). This compound is available as a commercial product, and examples thereof include tetraalkyl phosphonium halides, such as tetra-n-butyl phosphonium halide and tetra-n-propyl phosphonium halide; trialkylbenzyl phosphonium halides such as triethylbenzyl phosphonium halide; triphenylmonoalkyl phosphonium halides such as triphenylmethyl phosphonium halide and triphenylethyl phosphonium halide; triphenylbenzyl phosphonium halide; tetraphenyl phosphonium halides; tritolylmonoaryl phosphonium halides; or tritolylmonoalkyl phosphonium halides (wherein, the halogen atom is a chlorine atom or a bromine atom). The compound of Formula (D-7) is particularly preferably a triphenylmonoalkyl phosphonium halide such as triphenylmethyl phosphonium halide and triphenylethyl phosphonium halide; a triphenylmonoaryl phosphonium halide such as triphenylbenzyl phosphonium halide; a tritolylmonoaryl phosphonium halide such as tritolylmonophenyl phosphonium halide; and a tritolylmonoalkyl phosphonium halide such as tritolylmonomethyl phosphonium halide (wherein, the halogen atom is a chlorine atom or a bromine atom).

Examples of the phosphines include primary phosphines such as methylphosphine, ethylphosphine, propylphosphine, isopropylphosphine, isobutylphosphine and phenylphosphine; secondary phosphines such as dimethylphosphine, diethylphosphine, diisopropylphosphine, diisoamylphosphine and diphenylphosphine; and tertiary phosphines such as trimethylphosphine, triethylphosphine, triphenylphosphine, methyldiphenylphosphine and dimethylphenylphosphine.

The compound of Formula (D-8) is a tertiary sulfonium salt having the structure R³⁵R³⁶R³⁷S⁺Y⁻. R³⁵, R³⁶, and R³⁷ are each, for example, an alkyl group having from 1 to 18 carbon atoms, such as an ethyl group, a propyl group, a butyl group, or a cyclohexylmethyl, an aryl group having from 6 to 18 carbon atoms such as a phenyl group, or an aralkyl group having from 7 to 18 carbon atoms such as a benzyl group, and preferably two of the three substituents of R³⁵, R³⁶, and R³⁷ are unsubstituted phenyl groups or substituted phenyl groups such as a phenyl group and a tolyl group, and the remaining one substituent is an alkyl group having from 1 to 18 carbon atoms, an aryl group having from 6 to 18 carbon atoms, or an aralkyl group having from 7 to 18 carbon atoms. Examples of the anion (Y⁻) include halide ions such as a chlorine ion (Cl⁻), a bromine ion (Br⁻), and an iodine ion (I⁻), and acid groups such as a carboxylate (—COO⁻), a sulfonate (—SO₃⁻), an alcoholate (—O⁻), a maleate anion, and a nitrate anion. This compound of Formula (D-8) is available as a commercial product, and examples thereof include trialkylsulfonium halides such as tri-n-butylsulfonium halide and tri-n-propylsulfonium halide, dialkylbenzylsulfonium halides such as diethylbenzylsulfonium halide, diphenylmonoalkylsulfonium halides such as diphenylmethylsulfonium halide and diphenylethylsulfonium halide, triphenylsulfonium halides (wherein the halogen atom is chlorine or bromine), trialkylsulfonium carboxylates such as tri-n-butylsulfonium carboxylate and tri-n-propylsulfonium carboxylate, dialkylbenzylsulfonium carboxylates such as diethylbenzylsulfonium carboxylate, diphenylmonoalkylsulfonium carboxylates such as diphenylmethylsulfonium carboxylate and diphenylethylsulfonium carboxylate, and triphenylsulfonium carboxylates. In addition, a triphenylsulfonium halide and a triphenylsulfonium carboxylate can be preferably used.

Furthermore, a nitrogen-containing silane compound may be added as a curing catalyst. Examples of the nitrogen-containing silane compound include imidazole ring-containing silane compounds such as N-(3-triethoxysilylpropyl)-4,5-dihydroimidazole.

From the viewpoint of more sufficiently achieving the effects of the present invention, the content of the curing catalyst [D] in the silicon-containing resist underlayer film-forming composition of the first embodiment is preferably from 0.1 to 30 parts by mass, more preferably from 0.5 to 25 parts by mass, and even more preferably from 1 to 20 parts by mass, per 100 parts by mass of the polysiloxane [A].

From the viewpoint of more sufficiently achieving the effects of the present invention, the content of the curing catalyst [D] in the silicon-containing resist underlayer film-forming composition of the second embodiment is preferably from 0.1 to 30 parts by mass, more preferably from 0.5 to 25 parts by mass, and even more preferably from 1 to 20 parts by mass, per 100 parts by mass of the polysiloxane [A′].

### Component [E]: Nitric Acid

The silicon-containing resist underlayer film-forming composition preferably contains nitric acid [E].

The nitric acid [E] may be added during preparation of the silicon-containing resist underlayer film-forming composition. Alternatively, the nitric acid [E] may be used as a hydrolysis catalyst or during alcohol capping of silanol groups in the production of the polysiloxane, and the residual nitric acid in the polysiloxane varnish may be treated as the nitric acid [E].

The content (residual nitric acid amount) of the nitric acid [E] may be, for example, from 0.0001 mass % to 1 mass %, from 0.001 mass % to 0.1 mass %, or from 0.005 mass % to 0.05 mass % on the basis of the total mass of the silicon-containing resist underlayer film-forming composition.

### Other Additives

Various additives can be blended into the silicon-containing resist underlayer film-forming composition, depending on the application of the composition.

As the additives, known additives that are blended in materials (compositions) for forming various films such as resist underlayer films, bottom anti-reflective coatings, and pattern reversing films, the films thereof being used in the production of semiconductor devices, can be used, and examples thereof include crosslinking agents, crosslinking catalysts, stabilizers (such as organic acids, water, and alcohols), organic polymers, acid generators, surfactants (such as nonionic surfactants, anionic surfactants, cationic surfactants, silicon-based surfactants, fluorine-based surfactants, and UV-curable surfactants), pH adjusters, metal oxides, rheology modifiers, and adhesion aids.

Various additives are exemplified below, but the present invention is not limited thereto.

### Stabilizer

A stabilizer may be added for purposes such as stabilizing the hydrolysis-condensation product of the hydrolyzable silane, and specific examples thereof include organic acids, water, alcohols, and combinations thereof.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among these, oxalic acid and maleic acid are preferable. When an organic acid is added, the addition amount thereof is from 0.1 to 5.0 mass % with respect to the mass of the hydrolysis-condensation product of the hydrolyzable silane. These organic acids can also act as pH adjusters.

As the water, pure water, ultrapure water, ion-exchanged water, or the like can be used, and in a case in which water is used, the addition amount thereof may be from 1 to 20 parts by mass with respect to 100 parts by mass of the silicon-containing resist underlayer film-forming composition.

The alcohol is preferably one that is easily scattered by heating after application, and examples thereof include methanol, ethanol, propanol, i-propanol, and butanol. When an alcohol is added, the addition amount thereof may be from 1 to 20 parts by mass with respect to 100 parts by mass of the silicon-containing resist underlayer film-forming composition.

### Organic Polymer

The dry etching rate (the amount of decrease in the film thickness per unit time), the attenuation coefficient, the refractive index, and the like of the film (resist underlayer film) formed from the silicon-containing resist underlayer film-forming composition can be adjusted by adding an organic polymer to the composition. The organic polymer is not particularly limited, and is appropriately selected from various organic polymers (condensation-polymerized polymers and addition-polymerized polymers) according to the purpose of addition.

Specific examples thereof include addition-polymerized polymers and condensation-polymerized polymers, such as polyesters, polystyrenes, polyimides, acrylic polymers, methacrylic polymers, polyvinyl ethers, phenol novolacs, naphthol novolacs, polyethers, polyamides, and polycarbonates.

In the present invention, an organic polymer containing an aromatic ring or a heteroaromatic ring such as a benzene ring, a naphthalene ring, an anthracene ring, a triazine ring, a quinoline ring, or a quinoxaline ring, which function as light absorbing sites, may also be suitably used when such a function is required. Specific examples of such an organic polymer include, but are not limited to, addition-polymerized polymers containing, as a structural unit, an addition-polymerizable monomer, such as benzyl acrylate, benzyl methacrylate, phenyl acrylate, naphthyl acrylate, anthryl methacrylate, anthryl methyl methacrylate, styrene, hydroxystyrene, benzyl vinyl ether, and N-phenylmaleimide; and condensation-polymerized polymers such as phenol novolac and naphthol novolac.

When an addition-polymerized polymer is used as the organic polymer, the polymer may be either a homopolymer or a copolymer.

An addition-polymerizable monomer is used for production of the addition-polymerized polymer, and specific examples of such an addition-polymerizable monomer include, but are not limited to, acrylic acid, methacrylic acid, acrylate compounds, methacrylate compounds, acrylamide compounds, methacrylamide compounds, vinyl compounds, styrene compounds, maleimide compounds, maleic anhydrides, and acrylonitriles.

Specific examples of the acrylate compound include, but are not limited to, methyl acrylate, ethyl acrylate, n-hexyl acrylate, i-propyl acrylate, cyclohexyl acrylate, benzyl acrylate, phenyl acrylate, anthryl methyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantayl acrylate, 5-acryloyloxy-6-hydroxynorbornene-2-carboxylic-6-lactone, 3-acryloxypropyl triethoxy silane, and glycidyl acrylate.

Specific examples of the methacrylate compounds include, but are not limited to, methyl methacrylate, ethyl methacrylate, n-hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantayl methacrylate, 5-methacryloyloxy-6-hydroxynorbornene-2-carboxylic-6-lactone, 3-methacryloxypropyl triethoxy silane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methyl methacrylamide, N-ethyl methacrylamide, N-benzyl methacrylamide, N-phenyl methacrylamide, N,N-dimethyl methacrylamide, and N-anthryl methacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetate, vinyl trimethoxysilane, 2-chloroethyl vinyl ether, 2-methoxyethyl vinyl ether, vinyl naphthalene, and vinyl anthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a condensation-polymerized polymer is used as the polymer, examples of such a polymer include polymers resulting from condensation-polymerization of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Other examples of the condensation-polymerized polymer include, but are not limited to, polyesters such as polypyromellitimide, poly(p-phenylene terephthalamide), polybutylene terephthalate, and polyethylene terephthalate; polyamides; and polyimides.

When the organic polymer contains a hydroxy group, this hydroxy group can undergo a crosslinking reaction with a hydrolysis-condensation product or the like.

The weight average molecular weight of the organic polymer may usually be from 1000 to 1000000. When an organic polymer is blended, from the viewpoint of suppressing precipitation in the composition while sufficiently achieving the functional effects of the polymer, the weight average molecular weight thereof may be, for example, from 3000 to 300000, from 5000 to 300000, or from 10000 to 200000.

A single type of such organic polymers may be used alone or two types or more thereof may be used in combination.

When the silicon-containing resist underlayer film-forming composition contains an organic polymer, the content thereof is appropriately determined with consideration of the function and the like of the organic polymer, and thus the content cannot be generally defined. However, with respect to the mass of the polysiloxane [A] or the polysiloxane [A′], the content of the organic polymer may usually be in a range from 1 to 200 mass %, and from viewpoints such as suppressing precipitation in the composition, the content of the organic polymer may be, for example, 100 mass % or less, preferably 50 mass % or less, and more preferably 30 mass % or less, and from viewpoints such as sufficiently achieving the effect of the organic polymer, the content may be, for example, 5 mass % or greater, preferably 10 mass % or greater, and more preferably 30 mass % or greater.

### Acid Generator

Examples of the acid generator include a thermal acid generator and a photoacid generator, and a photoacid generator can be preferably used.

Examples of the photoacid generator include, but are not limited to, onium salt compounds, sulfonimide compounds, and disulfonyl diazomethane compounds. Note that some types of the photoacid generator may also function as a curing catalyst, for example, nitrates, hydrochlorides and carboxylates such as maleates in an onium salt compound described below.

Examples of the thermal acid generator include, but are not limited to, tetramethylammonium nitrate.

Specific examples of the onium salt compound include, but are not limited to, iodonium salt compounds such as diphenyliodonium hexafluorophosphate, diphenyliodonium trifluoromethane sulfonate, diphenyliodonium nonafluoro-n-butane sulfonate, diphenyliodonium perfluoro-n-octane sulfonate, diphenyliodonium camphor sulfonate, bis(4-t-butylphenyl)iodonium camphor sulfonate, and bis(4-t-butylphenyl)iodonium trifluoromethane sulfonate; and sulfonium salt compounds such as triphenylsulfonium hexafluoroantimonate, triphenylsulfonium nonafluoro-n-butane sulfonate, triphenylsulfonium camphorsulfonate, triphenylsulfonium trifluoromethane sulfonate, triphenylsulfonium nitrate (nitrate), triphenylsulfonium trifluoroacetate, triphenylsulfonium maleate, and triphenylsulfonium chloride.

Specific examples of the sulfonimide compound include, but are not limited to, N-(trifluoromethanesulfonyloxy) succinimide, N-(nonafluoro-n-butanesulfonyloxy) succinimide, N-(camphorsulfonyloxy) succinimide, and N-(trifluoromethanesulfonyloxy) naphthalimide.

Specific examples of the disulfonyldiazomethane compound include, but are not limited to, bis(trifluoromethylsulfonyl) diazomethane, bis(cyclohexylsulfonyl) diazomethane, bis(phenylsulfonyl) diazomethane, bis(p-toluenesulfonyl) diazomethane, bis(2,4-dimethylbenzenesulfonyl) diazomethane, and methylsulfonyl-p-toluenesulfonyl diazomethane.

When the silicon-containing resist underlayer film-forming composition contains an acid generator, the content of the acid generator is appropriately determined with consideration of details such as the type of the acid generator, and thus the content cannot be generally defined. However, with respect to the mass of the polysiloxane [A] or the polysiloxane [A′], the content of the acid generator is usually in a range from 0.01 to 5 mass %, and from viewpoints such as suppressing precipitation of the acid generator in the composition, the content of the acid generator is preferably 3 mass % or less and more preferably 1 mass % or less, and from the viewpoint of sufficiently achieving the effect of the acid generator, the content thereof is preferably 0.1 mass % or greater and more preferably 0.5 mass % or greater.

A single type of acid generator may be used alone, or two or more types thereof may be used in combination, and a photoacid generator and a thermal acid generator may be used in combination.

### Surfactant

A surfactant is effective in suppressing the generation of pinholes, striations, and the like when the silicon-containing resist underlayer film-forming composition is applied to a substrate. Examples of the surfactant include nonionic surfactants, anionic surfactants, cationic surfactants, silicon-based surfactants, fluorine-based surfactants, and UV curable surfactants. More specific examples thereof include, but are not limited to, nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty esters such as sorbitan monolaurate, sorbitan monopalmitate, sorbitan monostearate, sorbitan monooleate, sorbitan trioleate, and sorbitan tristearate, and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as Eftop (trade name) EF301, EF303 and EF352 (available from Mitsubishi Materials Electronic Chemicals Co., Ltd. (formerly Tohkem Products Corp.)), Megaface (trade name) F171, F173, R-08, R-30, R-30N and R-40LM (available from DIC Corporation), Fluorad FC430 and FC431 (available from 3M Japan Ltd.), AsahiGuard (trade name) AG710 (available from AGC Inc.), and Surflon (trade name)S-382, SC101, SC102, SC103, SC104, SC105, and SC106 (available from AGC Seimi Chemical Co., Ltd.); and the organosiloxane polymer KP341 (available from Shin-Etsu Chemical Co., Ltd.).

A single type of surfactant may be used alone, or two or more types may be used in combination.

When the silicon-containing resist underlayer film-forming composition contains a surfactant, the content of the surfactant may be usually from 0.0001 to 5 mass %, preferably from 0.001 to 4 mass %, and more preferably from 0.01 to 3 mass %, with respect to the mass of the polysiloxane [A] or the polysiloxane [A′].

### Rheology Modifier

The rheology modifier is added primarily to improve the fluidity of the silicon-containing resist underlayer film-forming composition, and in particular, is added for the purpose of improving the uniformity of the film thickness of the formed film in baking, and of enhancing the filling property of the composition into holes. Specific examples of the rheology modifier include phthalic acid derivatives such as dimethyl phthalate, diethyl phthalate, di-i-butyl phthalate, dihexyl phthalate, and butyl-1-decyl phthalate; adipic acid derivatives such as di-n-butyl adipate, di-i-butyl adipate, di-i-octyl adipate, and octyldecyl adipate; maleic acid derivatives such as di-n-butyl maleate, diethyl maleate, and dinonyl maleate; oleic acid derivatives such as methyl oleate, butyl oleate, and tetrahydrofurfuryl oleate; and stearic acid derivatives such as n-butyl stearate and glyceryl stearate.

When these rheology modifiers are used, the addition amount thereof is usually less than 30 mass % with respect to the total film-forming components of the silicon-containing resist underlayer film-forming composition.

### Adhesion Aid

The adhesion aid is added for the purpose of primarily improving the adhesion between the substrate or the resist and the film (resist underlayer film) formed from the silicon-containing resist underlayer film-forming composition, and particularly for the purpose of suppressing or reducing removal of the resist during development. Specific examples of the adhesion aid include chlorosilanes such as trimethyl chlorosilane, dimethylvinyl chlorosilane, methyldiphenyl chlorosilane, and chloromethyldimethyl chlorosilane; alkoxysilanes such as trimethylmethoxy silane, dimethyldiethoxy silane, methyldimethoxy silane, and dimethylvinylethoxy silane; silazanes such as hexamethyl disilazane, N,N′-bis(trimethylsilyl)urea, dimethyltrimethylsilyl amine, and trimethylsilyl imidazole; other silanes such as y-chloropropyltrimethoxy silane, γ-aminopropyltriethoxy silane, and y-glycidoxypropyltrimethoxy silane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; ureas such as 1,1-dimethylurea and 1,3-dimethylurea; and thiourea compounds.

When these adhesion aids are used, the addition amount thereof is usually less than 5 mass %, and preferably less than 2 mass %, with respect to the film-forming components of the silicon-containing resist underlayer film-forming composition.

### pH Adjuster

Examples of the pH adjuster include acids having one or more carboxylic acid groups, such as the organic acids described above as stabilizers. When a pH adjuster is used, the addition amount thereof may be from 0.01 to 20 parts by mass, from 0.01 to 10 parts by mass, or from 0.01 to 5 parts by mass, per 100 parts by mass of the polysiloxane [A] or the polysiloxane [A′].

### Metal Oxide

Examples of metal oxides that can be added to the silicon-containing resist underlayer film-forming composition include, but are not limited to, oxides of one or a combination of two or more selected from among metals such as tin (Sn), titanium (Ti), aluminum (Al), zirconium (Zr), zinc (Zn), niobium (Nb), tantalum (Ta), and tungsten (W) and metalloids such as boron (B), silicon (Si), germanium (Ge), arsenic (As), antimony (Sb), and tellurium (Te).

The concentration of the film-forming components in the silicon-containing resist underlayer film-forming composition may be, for example, from 0.1 to 50 mass %, from 0.1 to 30 mass %, from 0.1 to 25 mass %, or from 0.5 to 20.0 mass %, with respect to the total mass of the composition.

The content of the polysiloxane [A] or the polysiloxane [A′] in the film-forming components is usually from 20 mass % to 100 mass %, but from the viewpoint of achieving the effects of the present invention with good reproducibility, the lower limit thereof is preferably 50 mass %, more preferably 60 mass %, even more preferably 70 mass %, and still more preferably 80 mass %, and the upper limit thereof is preferably 99 mass %, with the remainder being additives described below.

The silicon-containing resist underlayer film-forming composition preferably has a pH from 2 to 5, and more preferably a pH from 3 to 4.

The silicon-containing resist underlayer film-forming composition of the first embodiment can be produced by mixing the polysiloxane [A], a solvent [C], and if other components are contained as desired, the other components. At this time, a solution containing the polysiloxane [A] may be prepared in advance, and this solution may be mixed with the solvent [C] and other components.

The order of mixing is not particularly limited. And, for example, the solvent [C] may be added to and mixed with the solution containing the polysiloxane [A], and then the other components may be added to the mixture, or the solution containing the polysiloxane [A], the solvent [C], and the other components may be simultaneously mixed.

If necessary, the solvent [C] may be further added at the end, or some components that are relatively soluble in the solvent [C] may be not included in the mixture and instead, added at the end. However, from the viewpoints of suppressing aggregation or separation of the constituent components and preparing a composition having excellent homogeneity with good reproducibility, preferably, a solution in which the polysiloxane [A] is well dissolved is prepared in advance, and this solution is used to prepare the composition. It should be noted that, depending on the type and amount of the solvent [C] and on details such as the amounts and properties of the other components, when these components are mixed with the polysiloxane [A], aggregation or precipitation may occur. In addition, it should be noted that, in a case in which the composition is prepared using a solution in which the polysiloxane [A] is dissolved, the concentration of the solution of the polysiloxane [A] and the usage amount thereof may be determined such that the amount of the polysiloxane [A] in the finally produced composition is the desired amount.

In the preparation of the composition, heating may be appropriately implemented within a range in which the components do not decompose or deteriorate.

The silicon-containing resist underlayer film-forming composition of the second embodiment can be produced by mixing the polysiloxane [A′], the component [B] of the hydrolyzable silane (A) having the specific group, a solvent [C], and if other components are contained as desired, the other components. At this time, a solution containing the polysiloxane [A′] may be prepared in advance, and this solution may be mixed with the component [B] of the hydrolyzable silane (A) having the specific group, the solvent [C], and the other components.

The order of mixing is not particularly limited. For example, the component [B] of the hydrolyzable silane (A) having the specific group, and the solvent [C] may be added to and mixed with the solution containing the polysiloxane [A′], and the other components may be added to the mixture, or the polysiloxane [A′]-containing solution, the component [B] of the hydrolyzable silane (A) having the specific group, the solvent [C], and the other components may be simultaneously mixed.

If necessary, the solvent [C] may be further added at the end, or some components that are relatively soluble in the solvent [C] may be not included in the mixture and instead, added at the end. However, from the viewpoints of suppressing aggregation or separation of the constituent components and preparing a composition having excellent homogeneity with good reproducibility, preferably, a solution in which the polysiloxane [A′] is well dissolved is prepared in advance, and this solution is used to prepare the composition. It should be noted that, depending on the types and amounts of the component [B] of the hydrolyzable silane (A) having a specific group, and the solvent [C] and on details such as the amounts and properties of the other components, when these components are mixed with the polysiloxane [A′], aggregation or precipitation may occur. In addition, it should be noted that, in a case in which the composition is prepared using a solution in which the polysiloxane [A′] is dissolved, the concentration of the solution of the polysiloxane [A′] and the usage amount thereof may be determined such that the amount of the polysiloxane [A′] in the finally produced composition is the desired amount.

In the preparation of the composition, heating may be appropriately implemented within a range in which the components do not decompose or deteriorate.

In the present invention, during the production of the silicon-containing resist underlayer film-forming composition, or after all the components have been mixed, filtration may be implemented using a submicrometer-order filter, or the like. The filter that is used at this time can be made of any material, and for example, a nylon filter or a fluororesin filter can be used.

The silicon-containing resist underlayer film-forming composition of the present invention can be suitably used as a composition for forming a resist underlayer film that is used in a lithography process.

Pattern Forming Method and Method for Manufacturing Semiconductor Element Hereinafter, as one aspect of the present invention, a pattern forming method and a method for manufacturing a semiconductor element will be described, the methods thereof using the silicon-containing resist underlayer film of the present invention, or the silicon-containing resist underlayer film-forming composition of the present invention.

One aspect of the silicon-containing resist underlayer film of the present invention is a cured product of the silicon-containing resist underlayer film-forming composition of the present invention.

The semiconductor processing substrate of the present invention has a semiconductor substrate and a silicon-containing resist underlayer film.

The silicon-containing resist underlayer film is the resist underlayer film of the present invention, or is a cured resist underlayer film of the silicon-containing resist underlayer film-forming composition of the present invention.

The method for manufacturing a semiconductor element of the present invention includes;
forming an organic underlayer film on a substrate;
forming a resist underlayer film on the organic underlayer film using the silicon-containing resist underlayer film-forming composition of the present invention; and
forming a resist film on the resist underlayer film.

The pattern forming method of the present invention includes:
forming an organic underlayer film on a semiconductor substrate;
applying the silicon-containing resist underlayer film-forming composition of the present invention onto the organic underlayer film and baking the silicon-containing resist underlayer film-forming composition applied thereon to form a resist underlayer film;
applying a composition for forming a resist film onto the resist underlayer film to form a resist film;
exposing and developing the resist film to form a resist pattern;
etching the resist underlayer film using the resist pattern as a mask; and
etching the organic underlayer film using the patterned resist underlayer film as a mask.

The silicon-containing resist underlayer film-forming composition of the present invention is applied by an appropriate application method such as a spinner or a coater onto a substrate [for example, a semiconductor substrate such as a silicon wafer coated with a silicon oxide film, a silicon nitride film, or a silicon oxynitride film, a silicon nitride substrate, a quartz substrate, a glass substrate (including alkali-free glass, low-alkali glass, and crystallized glass), a glass substrate on which an indium tin oxide (ITO) film or an indium zinc oxide (IZO) film is formed, a plastic (such as polyimide or PET) substrate, a substrate coated with a low-dielectric constant material (low-k material), or a flexible substrate] that is used for manufacturing a precision integrated circuit, and subsequently, the coated substrate is baked using a heating means such as a hot plate to form the composition into a cured product, and thereby a resist underlayer film is formed. Hereinafter, in the present specification, the resist underlayer film refers to a silicon-containing resist underlayer film of the present invention, or to a film formed from the silicon-containing resist underlayer film-forming composition of the present invention.

Baking conditions are appropriately selected from the group consisting of a baking temperature from 40° C. to 400° C., or from 80° C. to 250° C., and a f baking time from 0.3 minutes to 60 minutes. Preferably, the baking temperature is from 150° C. to 250° C., and the baking time is from 0.5 minutes to 2 minutes.

The film thickness of the resist underlayer film formed here is, for example, from 10 nm to 1000 nm, or from 20 nm to 500 nm, or from 50 nm to 300 nm, or from 100 nm to 200 nm, or from 10 nm to 150 nm.

As the silicon-containing resist underlayer film-forming composition that is used in forming a resist underlayer film, a silicon-containing resist underlayer film-forming composition that is filtered through a nylon filter can be used. Here, the silicon-containing resist underlayer film-forming composition that is filtered through a nylon filter refers to a composition that is filtered through a nylon filter in an intermediate stage during the production of the silicon-containing resist underlayer film-forming composition or after all the components have been mixed.

In the present invention, an organic underlayer film is formed on a substrate, after which the resist underlayer film is formed thereon, or in some cases, the organic underlayer film is not provided.

The organic underlayer film used here is not particularly limited, and can be optionally selected from those that have been commonly used in lithography processes.

When an aspect is adopted in which an organic underlayer film is provided on a substrate, a resist underlayer film is provided on the organic underlayer film, and a below-described resist film is then provided on the resist underlayer film, the pattern width of a photoresist film is narrowed, and even when the photoresist film is thinly coated to reduce pattern collapse, the substrate can be processed by selecting an appropriate etching gas, which will be described later. For example, the resist underlayer film can be processed by using, as the etching gas, a fluorine-based gas having a sufficiently fast etching rate with respect to the photoresist film, the organic underlayer film can be processed by using, as the etching gas, an oxygen-based gas having a sufficiently fast etching rate with respect to the resist underlayer film, and the substrate can be processed by using, as the etching gas, a fluorine-based gas having a sufficiently fast etching rate with respect to the organic underlayer film.

The substrate and the application method that can be used in this case are the same as those described above.

Next, for example, a layer (resist film) of a photoresist material is formed on the resist underlayer film. The resist film can be formed by a known method, that is, by applying a coating-type resist material (composition for forming a resist film) onto the resist underlayer film and then baking the coating-type resist material applied thereon.

The thickness of the resist film is, for example, from 10 nm to 10000 nm, or from 100 nm to 2000 nm, or from 200 nm to 1000 nm, or from 30 nm to 200 nm.

The photoresist material that is used for the resist film formed on the resist underlayer film is not particularly limited as long as the photoresist material is sensitive to light used for exposure (for example, a KrF excimer laser or an ArF excimer laser), and any of a negative photoresist material and a positive photoresist material can be used. Examples of the photoresist material include: a positive photoresist material containing a novolac resin and 1,2-naphthoquinone diazide sulfonate; a chemically amplified photoresist material containing a photoacid generator and a binder having a group that can be decomposed by an acid to increase the alkali dissolution rate; a chemically amplified photoresist material containing a photoacid generator, an alkali-soluble binder, and a low molecular weight compound that can be decomposed by an acid to improve the alkali dissolution rate of the photoresist material; and a chemically amplified photoresist material containing a photoacid generator, a binder having a group that can be decomposed by an acid to increase the alkali dissolution rate, and a low molecular weight compound that can be decomposed by an acid to improve the alkali dissolution rate of the photoresist material.

Specific examples of commercially available photoresist material products include, but are not limited to, APEX-E (trade name) available from Shipley Co., Ltd., PAR710 (trade name) available from Sumitomo Chemical Co., Ltd., AR2772JN (trade name) available from JSR Corporation, and SEPR430 (trade name) available from Shin-Etsu Chemical Co., Ltd. Other examples include fluorine atom-containing polymer-based photoresist materials like those described in Proc. SPIE, Vol. 3999, 330-334 (2000), Proc. SPIE, Vol. 3999, 357-364 (2000), and Proc. SPIE, Vol. 3999, 365-374 (2000).

As the resist film formed on the resist underlayer film, a resist film for electron beam lithography (also referred to as an electron beam resist film) or a resist film for EUV lithography (also referred to as an EUV resist film) can be used instead of the photoresist film. That is, the silicon-containing resist underlayer film-forming composition of the present invention can be used for forming a resist underlayer film for electron beam lithography or for forming a resist underlayer film for EUV lithography. In particular, the silicon-containing resist underlayer film-forming composition of the present invention is preferable as a composition for forming a resist underlayer film for EUV lithography.

As the electron beam resist material for forming the electron beam resist film, any of a negative type material and a positive type material can be used. Specific examples thereof include: a chemically amplified resist material containing an acid generator and a binder having a group that is decomposed by an acid to change the alkali dissolution rate; a chemically amplified resist material containing an alkali-soluble binder, an acid generator, and a low molecular weight compound that is decomposed by an acid to change the alkali dissolution rate of the resist material; a chemically amplified resist material containing an acid generator, a binder having a group that is decomposed by an acid to change the alkali dissolution rate, and a low molecular weight compound that is decomposed by an acid to change the alkali dissolution rate of the resist material; a non-chemically amplified resist material containing a binder having a group that is decomposed by an electron beam to change the alkali dissolution rate; and a non-chemically amplified resist material containing a binder having a moiety that is cleaved by an electron beam to change the alkali dissolution rate. Even when these electron beam resist materials are used, a resist film pattern can be formed in the same manner as in a case in which a photoresist material is used with an electron beam being used as the irradiation source.

A methacrylate resin-based resist material or a metal oxide resist material can be used as the EUV resist material for forming the EUV resist film.

Examples of the metal oxide resist material include a coating composition containing a metal oxo/hydroxo network having organic ligands through metal carbon bonds and/or metal carboxylate bonds as described in JP 2019-113855 A.

Next, the resist film formed on the upper layer of the resist underlayer film is subjected to exposure through a predetermined mask (reticle). For the exposure, a KrF excimer laser (wavelength of 248 nm), an ArF excimer laser (wavelength of 193 nm), a F₂ excimer laser (wavelength of 157 nm), extreme ultraviolet (EUV) radiation (wavelength of 13.5 nm), an electron beam, or the like can be used.

After exposure, post exposure baking may be implemented as necessary. The post exposure baking is carried out under conditions appropriately selected from a heating temperature from 70° C. to 150° C. and a heating time from 0.3 minutes to 10 minutes.

Subsequently, development is implemented using a developer (for example, an alkaline developer). Through this, for example, when a positive photoresist film is used, the photoresist film of the exposed portion is removed, and thereby a pattern is formed in the photoresist film.

Examples of the developer (alkaline developer) can include aqueous alkaline solutions (alkaline developers), such as aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and aqueous solutions of amines such as ethanolamine, propylamine, and ethylenediamine. Further, a surfactant or the like may be added to these developers. The conditions for development are appropriately selected from a temperature in a range from 5 to 50° C. and a time in a range from 10 seconds to 600 seconds.

In the present invention, an organic solvent can be used as the developer, and development is carried out with a developer (solvent) after exposure. Through this, for example, when a negative photoresist film is used, the photoresist film of an unexposed portion is removed to form a pattern in the photoresist film.

Examples of the developer (organic solvent) include, methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxy propionate, ethyl-3-methoxy propionate, ethyl-3-ethoxy propionate, and propyl-3-methoxy propionate. Further, a surfactant or the like may be added to these developers. As the conditions of the development, the temperature is appropriately selected from a range from 5° C. to 50° C. and the time is appropriately selected from a range from 10 seconds to 600 seconds.

The resist underlayer film (intermediate layer) is removed using the pattern of the photoresist film (upper layer) thus formed as a protective film, and subsequently, the organic underlayer film (lower layer) is removed using a film composed of the patterned photoresist film and the patterned resist underlayer film (intermediate layer) as protective films. Finally, the substrate is processed using the patterned resist underlayer film (intermediate layer) and the patterned organic underlayer film (lower layer) as protective films.

Removal (patterning) of the resist underlayer film (intermediate layer), which is carried out using the pattern of the resist film (upper layer) as a protective film, is implemented by dry etching using a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

Note that a halogen-based gas is preferably used for dry etching of the resist underlayer film. In dry etching using a halogen-based gas, it is basically difficult to remove a resist film (photoresist film) made of an organic substance. On the other hand, a resist underlayer film that contains a large amount of silicon atoms is quickly removed by a halogen-based gas. Therefore, a decrease in the thickness of the photoresist film due to dry etching of the resist underlayer film can be suppressed. Furthermore, as a result, the photoresist film can be used as a thin film. Therefore, dry etching of the resist underlayer film is preferably carried out using a fluorine-based gas, and examples of the fluorine-based gas include, but are not limited to, tetrafluoromethane (CF₄), perfluorocyclobutane (C₄F₈), perfluoropropane (C₃F₈), trifluoromethane, and difluoromethane (CH₂F₂).

When the organic underlayer film is present between the substrate and the resist underlayer film, subsequently, removal (patterning) of the organic underlayer film (lower layer), which is implemented using, as protective films, (if present, the patterned resist film (upper layer) and) a film including the patterned resist film (upper layer) and the patterned resist underlayer film (intermediate layer), is preferably carried out by dry etching using an oxygen-based gas (such as oxygen gas or an oxygen/carbonyl sulfide (COS) mixed gas). This is because the resist underlayer film of the present invention, which contains a large amount of silicon atoms, is difficult to remove by dry etching with an oxygen-based gas.

Subsequently, processing (patterning) of the (semiconductor) substrate, which is implemented using the patterned resist underlayer film (intermediate layer) and, if desired, the patterned organic underlayer film (lower layer) as protective films, is preferably carried out by dry etching using a fluorine-based gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

After removal (patterning) of the organic underlayer film or after processing (patterning) of the substrate, the resist underlayer film may be removed. The resist underlayer film can be removed by dry etching or wet etching (wet method).

The resist underlayer film is preferably dry etched using a fluorine-based gas like those given as examples with respect to patterning, and examples of the fluorine-based gas include, but are not limited to, tetrafluoromethane (CF₄), perfluorocyclobutane (C₄F₈), perfluoropropane (C₃F₈), trifluoromethane, and difluoromethane (CH₂F₂).

Examples of the chemical liquid used for wet etching the resist underlayer film include dilute hydrofluoric acid (hydrofluoric acid), buffered hydrofluoric acid (a mixed solution of HF and NH₄F), an aqueous solution (SC-2 chemical liquid) containing hydrochloric acid and hydrogen peroxide, an aqueous solution (SPM chemical liquid) containing sulfuric acid and hydrogen peroxide, an aqueous solution (FPM chemical liquid) containing hydrofluoric acid and hydrogen peroxide, and alkaline solutions such as an aqueous solution (SC-1 chemical liquid) containing ammonia and hydrogen peroxide. Examples of the alkaline solution include the abovementioned ammonia-hydrogen peroxide solution (SC-1 chemical liquid) produced by mixing ammonia, hydrogen peroxide, and water, as well as aqueous solutions containing from 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, diazabicycloundecene (DBU), diazabicyclononene (DBN), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, hydrazines, ethylenediamines, or guanidine. These chemical liquids may be mixed and used.

An organic-based bottom anti-reflective coating can be formed on the upper layer of the resist underlayer film before the formation of the resist film. The bottom anti-reflective coating composition to be used is not particularly limited, and for example, a bottom anti-reflective coating composition can be optionally selected from those used in lithography processes in the related art, and a bottom anti-reflective coating can be formed by a method used in the related art, such as coating with a spinner or a coater and baking.

The substrate to be coated with the silicon-containing resist underlayer film-forming composition may have an organic or inorganic bottom anti-reflective coating formed on the surface thereof by a CVD method or the like, and a resist underlayer film can also be formed thereon. In a case in which an organic underlayer film is formed on a substrate and then a resist underlayer film of an embodiment of the present invention is formed thereon, the substrate to be used may have an organic or inorganic bottom anti-reflective coating formed on the surface thereof by a CVD method or the like.

The resist underlayer film formed from the silicon-containing resist underlayer film-forming composition may also absorb light used in a lithography process, depending on the wavelength of the light. In such a case, the film can function as a bottom anti-reflective coating having an effect of reducing reflected light from the substrate.

Furthermore, the resist underlayer film can also be used as, for example, a layer for reducing interaction between a substrate and a resist film (photoresist film or the like), a layer having a function of reducing an adverse effect on the substrate from a material used in the resist film or a substance generated during exposure of the resist film, a layer having a function of reducing diffusion, into the resist film, of a substance generated from the substrate during heating and baking, or a barrier layer for reducing an effect of the resist film being poisoned by a semiconductor substrate dielectric layer.

The resist underlayer film can be applied to a substrate in which via holes used in a dual damascene process are formed, and can be used as a hole filling material (embedding material) that can fill holes without leaving any gaps. The resist underlayer film can also be used as a flattening material for flattening the surface of a semiconductor substrate having unevenness.

Further, as an underlayer film of an EUV resist film, the resist underlayer film of an embodiment of the present invention not only functions as a hard mask, but can also, for example, reduce the reflection of undesirable exposure light such as ultraviolet (UV) light and deep ultraviolet (DUV) light (ArF light, KrF light) from a substrate or an interface during EUV exposure (wavelength 13.5 nm) without intermixing with the EUV resist film. Therefore, the silicon-containing resist underlayer film-forming composition of the present invention can be suitably used for forming an underlayer bottom anti-reflective coating of an EUV resist film. That is, when the composition is formed as an underlayer of an EUV resist film, the underlayer can efficiently reduce reflection. In a case in which the composition is used as an EUV resist underlayer film, the process can be carried out in the same manner as for an underlayer film for a photoresist.

By using a semiconductor processing substrate provided with a semiconductor substrate and the above-described resist underlayer film of the present invention, the semiconductor substrate can be suitably processed.

Furthermore, the method for manufacturing a semiconductor element includes, as described above, forming an organic underlayer film, forming a resist underlayer film on the organic underlayer film using the silicon-containing resist underlayer film-forming composition of an embodiment of the present invention, and forming a resist film on the resist underlayer film. And thus, processing of a high precision semiconductor substrate can be realized with good reproducibility, and therefore stable manufacturing of semiconductor elements can be anticipated.

### EXAMPLES

Hereinafter, the present invention will be described more specifically with reference to synthesis examples and examples, but the present invention is not limited to only the following examples.

In the examples, the devices and conditions used to analyze the physical properties of the samples were as follows.

### (1) Molecular Weight Measurement

The molecular weight of the polysiloxane used in the present invention is a molecular weight determined in terms of polystyrene by GPC analysis.

The GPC analysis was implemented using, for example, a GPC apparatus (product name: HLC-8220GPC, available from Tosoh Corporation) and a GPC column (product: Shodex (trade name) KF803L, KF802, KF801, available from Showa Denko K.K.) under measurement conditions including a column temperature of 40° C., tetrahydrofuran as an eluent (elution solvent), a flow rate (flow speed) of 1.0 mL/min, and polystyrene (available from Showa Denko K.K.) as a standard sample.

### (2)¹H-NMR

Evaluations were conducted using a nuclear magnetic resonance 1H-NMR device (400 MHz) available from JEOL Ltd. and d6-Acetone as a solvent.

### (3) Residual Nitric Acid Amount

The amount of nitric acid remaining in the system was measured through an ion chromatography evaluation.

### [1] Synthesis of Polymer (Hydrolysis-Condensation Product)

### Synthesis Example 1

A 300 mL flask was charged with 16.44 g of tetraethoxysilane, 12.67 g of methyltriethoxysilane, 2.92 g of 4-nitro-N-(3-(triethoxysilyl)propyl)benzamide, and 48.05 g of propylene glycol monoethyl ether, after which 19.91 g of a 0.1 M nitric acid aqueous solution were added dropwise to the resulting mixed solution while stirring with a magnetic stirrer.

After the dropwise addition, the flask was transferred to an oil bath adjusted to 60° C., and the contents were reacted for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3200 in terms of polystyrene as measured by GPC. Also, the amount of Si atoms capped by the propylene glycol monoethyl ether was determined through ¹H-NMR to be 3 mol %. In addition, the amount of residual nitric acid in the polymer solution was 0.08%.

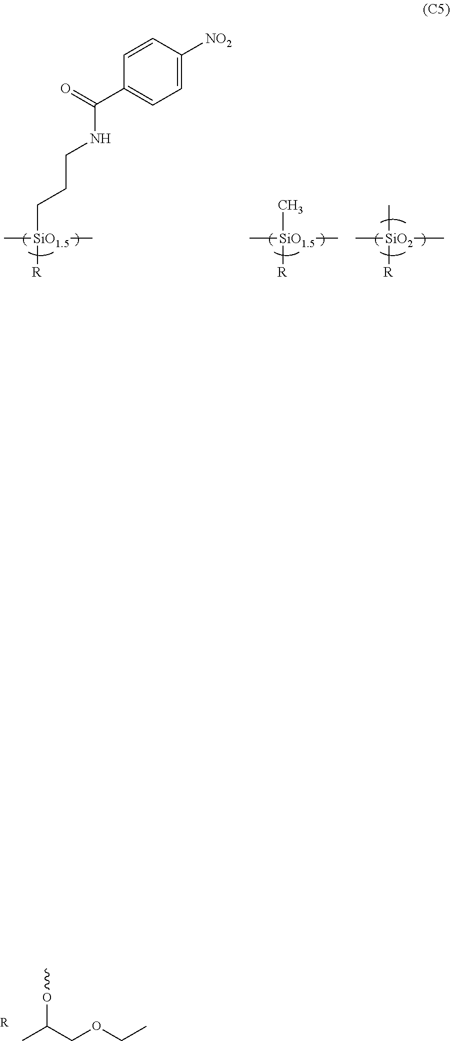

### Synthesis Example 2

A 300 mL flask was charged with 15.28 g of tetraethoxysilane, 9.16 g of methyltriethoxysilane, 8.15 g of 4-nitro-N-(3-(triethoxysilyl)propyl)benzamide, and 48.89 g of propylene glycol monoethyl ether, after which 18.5 g of a 0.1 M nitric acid aqueous solution were added dropwise to the resulting mixed solution while stirring with a magnetic stirrer.

After the dropwise addition, the flask was transferred to an oil bath adjusted to 60° C., and the contents were reacted for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3000 in terms of polystyrene as measured by GPC. Also, the amount of Si atoms capped by the propylene glycol monoethyl ether was determined through ¹H-NMR to be 2 mol %. In addition, the amount of residual nitric acid in the polymer solution was 0.08%.

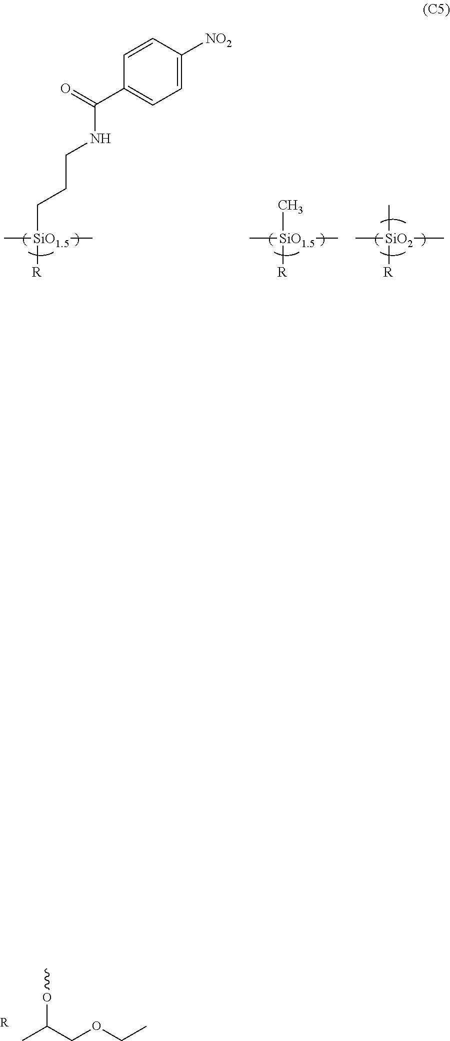

### Synthesis Example 3

A 300 mL flask was charged with 15.7 g of tetraethoxysilane, 10.76 g of methyltriethoxysilane, 3.12 g of diallyl isocyanurate propyl triethoxy silane, 2.79 g of 4-nitro-N-(3-(triethoxysilyl)propyl)benzamide, and 48.6 g of propylene glycol monoethyl ether, after which 19.0 g of a nitric acid aqueous solution (0.1 mol/L) were added dropwise to the resulting mixed solution while stirring with a magnetic stirrer.

After the dropwise addition, the flask was transferred to an oil bath adjusted to 60° C., and the contents were reacted for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 2800 in terms of polystyrene as measured by GPC. Also, the amount of Si atoms capped by the propylene glycol monoethyl ether was determined through ¹H-NMR to be 2 mol %. In addition, the amount of residual nitric acid in the polymer solution was 0.09%.

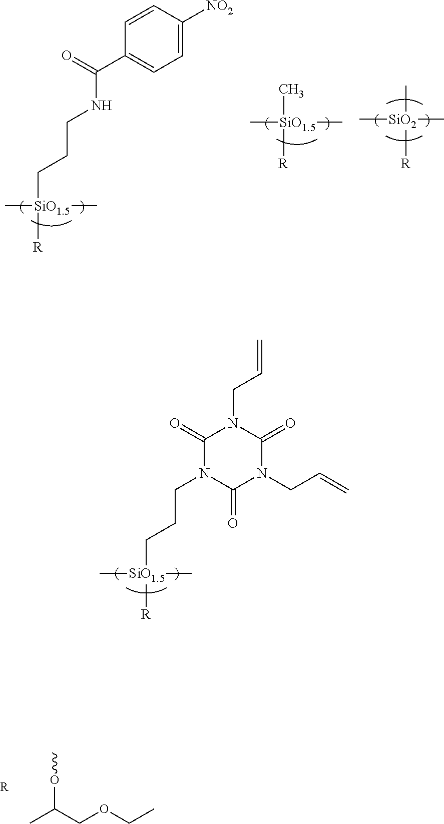

### Synthesis Example 4

A 300 mL flask was charged with 16.17 g of tetraethoxysilane, 11.07 g of methyltriethoxysilane, 2.05 g of thiocyanate propyl triethoxy silane, 2.88 g of 4-nitro-N-(3-(triethoxysilyl)propyl)benzamide, and 48.2 g of propylene glycol monoethyl ether, after which 19.6 g of a nitric acid aqueous solution (0.1 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3300 in terms of polystyrene as measured by GPC. Also, the amount of Si atoms capped by the propylene glycol monoethyl ether was determined through ¹H-NMR to be 3 mol %. In addition, the amount of residual nitric acid in the polymer solution was 0.1%.

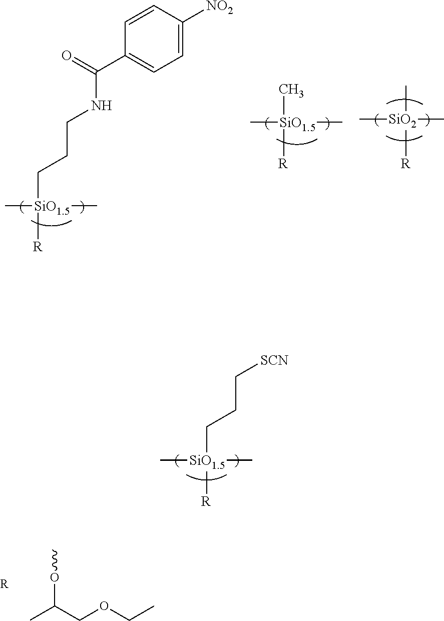

### Synthesis Example 5

A 300 mL flask was charged with 15.92 g of tetraethoxysilane, 10.90 g of methyltriethoxysilane, 2.63 g of triethoxy((2-methoxy-4-(methoxymethyl)phenoxy)methyl)silane, 2.83 g of 4-nitro-N-(3-(triethoxysilyl)propyl)benzamide, and 48.4 g of propylene glycol monoethyl ether, and 18.8 g of a nitric acid aqueous solution (0.1 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3500 in terms of polystyrene as measured by GPC. Also, the amount of Si atoms capped by the propylene glycol monoethyl ether was determined through ¹H-NMR to be 3 mol %. In addition, the amount of residual nitric acid in the polymer solution was 0.09%.

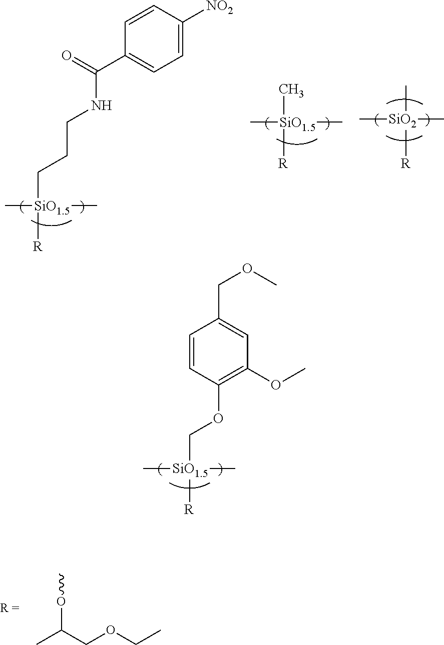

### Synthesis Example 6

A 300 mL flask was charged with 16.19 g of tetraethoxysilane, 11.09 g of methyltriethoxysilane, 1.99 g of bicyclo[2.2.1]hept-5-en-2-yl-triethoxysilane, 2.88 g of 4-nitro-N-(3-(triethoxysilyl)propyl)benzamide, and 48.2 g of propylene glycol monoethyl ether, after which 19.6 g of a nitric acid aqueous solution (0.1 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3000 in terms of polystyrene as measured by GPC. Also, the amount of Si atoms capped by the propylene glycol monoethyl ether was determined through ¹H-NMR to be 4 mol %. In addition, the amount of residual nitric acid in the polymer solution was 0.1%.

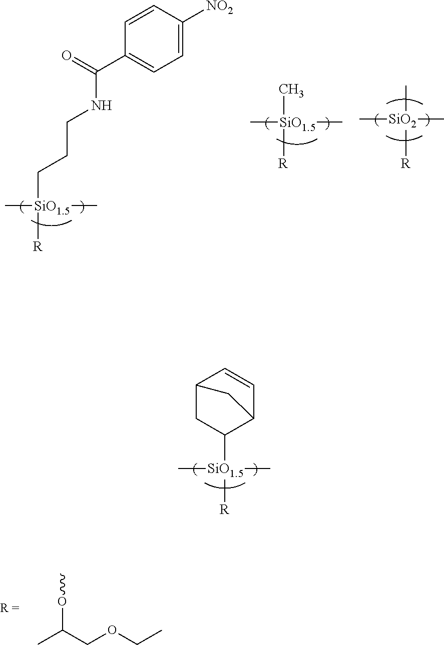

### Synthesis Example 7

A 300 mL flask was charged with 16.4 g of tetraethoxysilane, 12.36 g of methyltriethoxysilane, 2.92 g of 4-nitro-N-(3-(triethoxysilyl)propyl)benzamide, and 48.1 g of propylene glycol monoethyl ether, after which 0.36 g of dimethylaminopropyl trimethoxysilane and 19.9 g of a nitric acid aqueous solution (0.2 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol, methanol, and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3200 in terms of polystyrene as measured by GPC. Also, the amount of Si atoms capped by the propylene glycol monoethyl ether was determined through ¹H-NMR to be 3 mol %. In addition, the amount of residual nitric acid in the polymer solution was 0.16%.

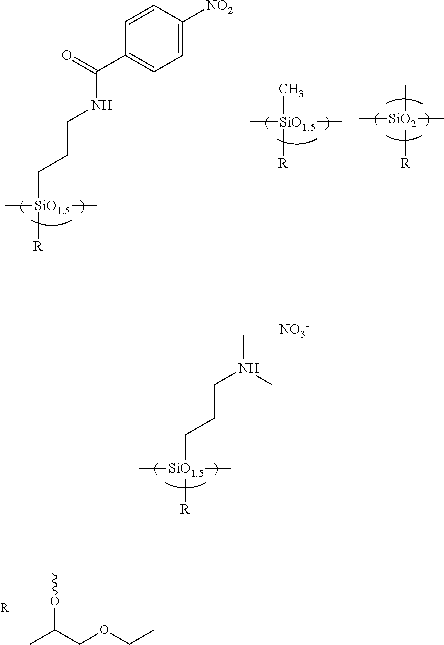

### Synthesis Example 8

A 300 mL flask was charged with 16.28 g of tetraethoxysilane, 12.26 g of methyltriethoxysilane, 2.90 g of 4-nitro-N-(3-(triethoxysilyl)propyl)benzamide, and 48.2 g of propylene glycol monoethyl ether, after which 0.67 g of 2,4-dinitro-N-(3-triethoxysilyl)propyl)aniline and 19.7 g of a nitric acid aqueous solution (0.2 mol/L) were added dropwise to the resulting mixed solution while the resulting mixed solution was being stirred with a magnetic stirrer.

After the dropwise addition, the flask was transferred to an oil bath adjusted to 60° C., and was then refluxed for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3000 in terms of polystyrene as measured by GPC. Also, the amount of Si atoms capped by the propylene glycol monoethyl ether was determined through ¹H-NMR to be 4 mol %. In addition, the amount of residual nitric acid in the polymer solution was 0.15%.

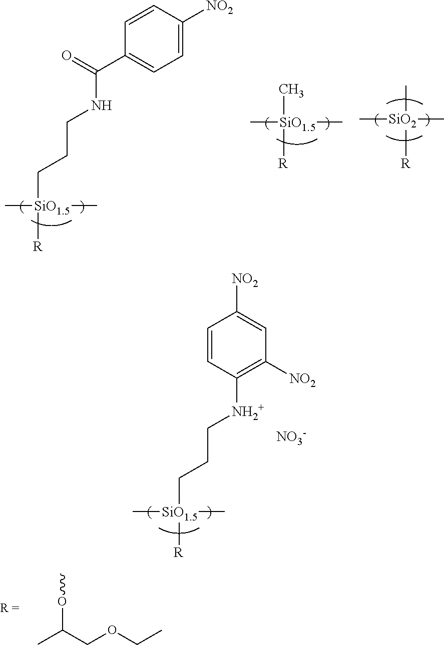

### Synthesis Example 9

A 300 mL flask was charged with 16.34 g of tetraethoxysilane, 12.31 g of methyltriethoxysilane, 3.07 g of 4-methoxy-N-(3-(triethoxysilyl)propyl)benzene sulfonamide, and 48.1 g of propylene glycol monoethyl ether, after which 0.36 g of dimethylaminopropyl trimethoxysilane and 19.8 g of a nitric acid aqueous solution (0.2 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol, methanol, and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3200 in terms of polystyrene as measured by GPC. Also, the amount of Si atoms capped by the propylene glycol monoethyl ether was determined through ¹H-NMR to be 3 mol %. In addition, the amount of residual nitric acid in the polymer solution was 0.16%.

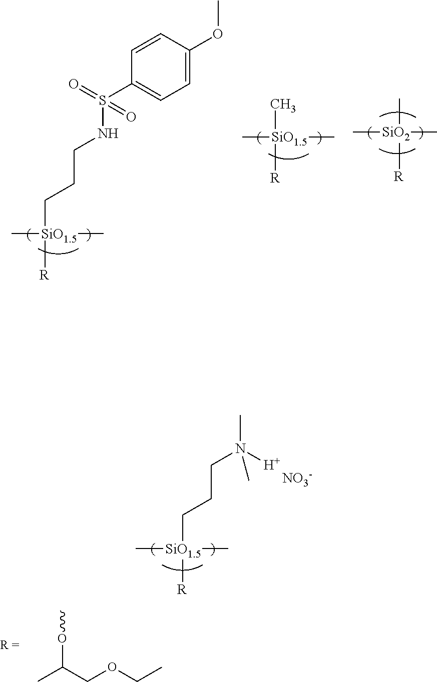

### Synthesis Example 10

A 300 mL flask was charged with 16.39 g of tetraethoxysilane, 12.35 g of methyltriethoxysilane, 2.96 g of triethoxy(3-((4-methoxyphenyl)sulfonyl)propylsilane, and 48.1 g of propylene glycol monoethyl ether, after which 0.36 g of dimethylaminopropyl trimethoxysilane and 19.9 g of a nitric acid aqueous solution (0.2 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol, methanol, and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 2900 in terms of polystyrene as measured by GPC. Also, the amount of Si atoms capped by the propylene glycol monoethyl ether was determined through ¹H-NMR to be 3 mol %. In addition, the amount of residual nitric acid in the polymer solution was 0.15%.

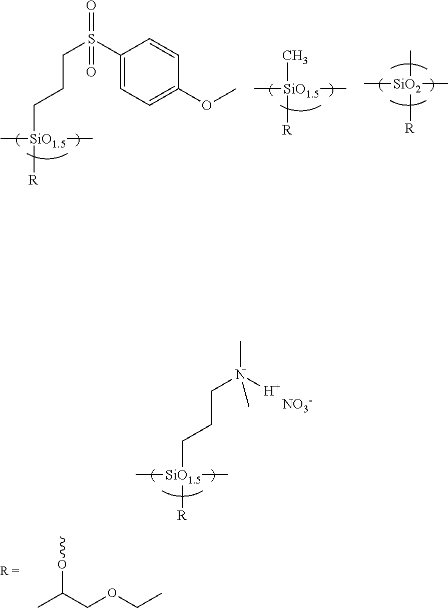

### Synthesis Example 11

A 300 mL flask was charged with 16.65 g of tetraethoxysilane, 12.54 g of methyltriethoxysilane, 2.38 g of trimethoxy(phenanthrenyl)silane, and 47.9 g of propylene glycol monoethyl ether, after which 0.36 g of dimethyl aminopropyl trimethoxysilane and 20.2 g of a nitric acid aqueous solution (0.2 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol, methanol, and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 2800 in terms of polystyrene as measured by GPC. Also, the amount of Si atoms capped by the propylene glycol monoethyl ether was determined through ¹H-NMR to be 4 mol %. In addition, the amount of residual nitric acid in the polymer solution was 0.14%.

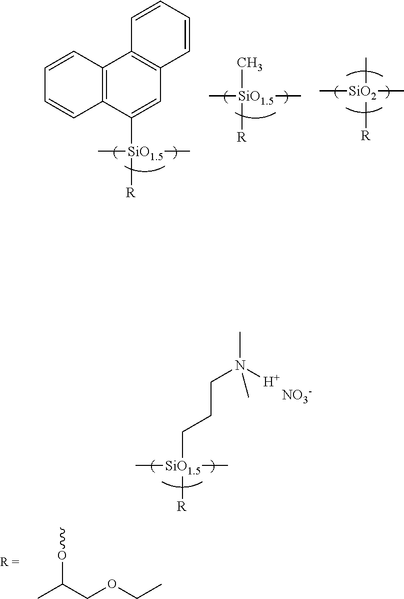

### Comparative Synthesis Example 1

A 300 mL flask was charged with 23.35 g of tetraethoxysilane, 8.57 g of methyltriethoxysilane, and 47.9 g of propylene glycol monoethyl ether, after which 20.2 g of a nitric acid aqueous solution (0.1 mol/L) were added dropwise to the resulting mixed solution while the resulting mixed solution was being stirred with a magnetic stirrer.

After the dropwise addition, the flask was transferred to an oil bath adjusted to 60° C., and the contents were reacted for 20 hours. Subsequently, the reaction by-products including ethanol and water were distilled off under reduced pressure to concentrate the mixed solution, and a hydrolysis-condensation product (polymer) solution was produced.

Propylene glycol monoethyl ether was further added to the resulting solution to adjust the concentration to 20 mass % in terms of solid residue at 140° C. as a solvent proportion of 100% propylene glycol monoethyl ether, and the solution was filtered through a nylon filter (pore size of 0.1 μm).

The resulting polymer contained a polysiloxane having a structure represented by the following formula, and the weight average molecular weight Mw thereof was 3300 in terms of polystyrene as measured by GPC. Also, the amount of Si atoms capped by the propylene glycol monoethyl ether was determined through ¹H-NMR to be 4 mol %. In addition, the amount of residual nitric acid in the polymer solution was 0.08%.

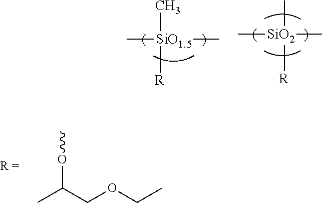

### [2] Preparation of Resist Underlayer Film-Forming Composition

A polysiloxane (polymer) produced in an above-described synthesis example, a stabilizer (additive 1), a curing catalyst (additive 2), and a solvent were mixed at the proportions described in Table 1, and the mixture was filtered through a 0.1 μm fluororesin filter, and thereby resist underlayer film-forming compositions were respectively prepared. Each addition amount in Table 1 is described in parts by mass.

Note that the composition of the hydrolysis-condensation product (polymer) was prepared as a solution containing the hydrolysis-condensation product produced in the respective synthesis example, but the addition proportion of the polymers in Table 1 indicates the addition amount of the polymer itself, not the addition amount of the polymer solution.

The meanings of the abbreviations in Table 1 are as follows.

### Solvent

DIW: ultrapure water
PGEE: propylene glycol monoethyl ether
PGME: propylene glycol monomethyl ether

### Additive 1 (Stabilizer)

MA: maleic acid

### Additive 2 (Curing Catalyst)

TPSNO3: triphenylsulfonium nitrate
TPSML: triphenylsulfonium maleate
TPSTfAc: triphenylsulfonium trifluoroacetate
IMTEOS: triethoxysilylpropyl-4,5-dihydroimidazole
TPSAc: triphenylsulfonium acetate
BTEAC: benzyltriethylammonium chloride salt
TPSCl: triphenylsulfonium chloride salt

TABLE 1

| | Polymer | Additive 1 | Additive 2 | Solvent | | |
|---|---|---|---|---|---|---|
| Example 1 | Synthesis Example 1 | MA | TPSNO3 | PGEE | PGME | DIW |
| (parts by mass) | 1 | 0.01 | 0.05 | 80 | 8 | 12 |
| Example 2 | Synthesis Example 2 | MA | TPSML | PGEE | PGME | DIW |
| (parts by mass) | 1 | 0.01 | 0.05 | 80 | 8 | 12 |
| Example 3 | Synthesis Example 3 | MA | TPSTfAc | PGEE | PGME | DIW |
| (parts by mass) | 1 | 0.01 | 0.05 | 80 | 8 | 12 |
| Example 4 | Synthesis Example 4 | MA | IMTEOS | PGEE | PGME | DIW |
| (parts by mass) | 1 | 0.01 | 0.01 | 80 | 8 | 12 |
| Example 5 | Synthesis Example 5 | MA | TPSAc | PGEE | PGME | DIW |
| (parts by mass) | 1 | 0.01 | 0.05 | 80 | 8 | 12 |
| Example 6 | Synthesis Example 6 | MA | BTEAC | PGEE | PGME | DIW |
| (parts by mass) | 1 | 0.01 | 0.05 | 80 | 8 | 12 |
| Example 7 | Synthesis Example 7 | MA | TPSNO3 | PGEE | PGME | DIW |
| (parts by mass) | 1 | 0.01 | 0.05 | 80 | 8 | 12 |
| Example 8 | Synthesis Example 8 | MA | TPSCl | PGEE | PGME | DIW |
| (parts by mass) | 1 | 0.01 | 0.05 | 80 | 8 | 12 |
| Example 9 | Synthesis Example 9 | MA | TPSNO3 | PGEE | PGME | DIW |
| (parts by mass) | 1 | 0.01 | 0.05 | 80 | 8 | 12 |
| Example 10 | Synthesis Example 10 | MA | TPSTfAc | PGEE | PGME | DIW |
| (parts by mass) | 1 | 0.01 | 0.05 | 80 | 8 | 12 |
| Example 11 | Synthesis Example 11 | MA | TPSCl | PGEE | PGME | DIW |
| (parts by mass) | 1 | 0.01 | 0.05 | 80 | 8 | 12 |
| Comparative | Comparative | MA | IMTEOS | PGEE | PGME | DIW |
| Example 1 | Synthesis Example 1 | | | | | |
| (parts by mass) | 1 | 0.01 | 0.01 | 80 | 8 | 12 |

* Examples 1 to 11 and Comparative Example 1 further contained the nitric acid contained in the polymer solutions prepared in Synthesis Examples 1 to 11 and Comparative Synthesis Example 1.

### [3] Preparation of Composition for Forming Organic Underlayer Film

Carbazole (6.69 g, 0.040 mol, available from Tokyo Chemical Industry Co., Ltd.), 9-fluorenone (7.28 g, 0.040 mol, available from Tokyo Chemical Industry Co., Ltd.), and p-toluenesulfonic acid monohydrate (0.76 g, 0.0040 mol, available from Tokyo Chemical Industry Co., Ltd.) were added to a 100 mL four-neck flask under a nitrogen stream, and 1,4-dioxane (6.69 g, available from Kanto Chemical Co., Inc.) was added thereto, stirred, heated to 100° C., and dissolved to initiate polymerization. After 24 hours, the mixture was allowed to cool to 60° C.

The cooled reaction mixture was diluted by adding chloroform (34 g, available from Kanto Chemical Co., Inc.), and the diluted mixture was added to methanol (168 g, available from Kanto Chemical Co., Inc.) and allowed to precipitate.

The resulting precipitates were collected by filtration, and the collected solids were dried in a vacuum dryer at 80° C. for 24 hours, and 9.37 g of a targeted polymer (hereinafter, abbreviated as PCzFL) represented by Formula (X) were produced.

Note that ¹H-NMR measurement results of the PCzFL were as follows.

¹H-NMR (400 MHz, DMSO-d6): δ (ppm) 7.03 to 7.55 (br, 12H), δ7.61 to 8.10 (br, 4H), δ11.18 (br, 1H)

Further, the weight average molecular weight Mw of the PCzFL was 2800 in terms of polystyrene as determined by GPC, and the polydispersity Mw/Mn was 1.77.

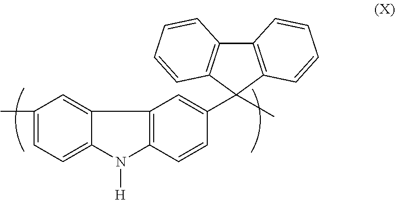

A mixture was produced by mixing 20 g of PCzFL, 3.0 g of tetramethoxymethyl glycol uril (available from Nihon Cytec Industries Inc. (formerly Mitsui Cytec, Ltd.), trade name: Powderlink 1174) as a crosslinking agent, 0.30 g of pyridinium p-toluenesulfonate as a catalyst, and 0.06 g of Megaface R-30 (available from DIC Corporation, trade name) as a surfactant, and the mixture was dissolved in 88 g of propylene glycol monomethyl ether acetate to thereby prepare a solution. Subsequently, the resulting solution was filtered using a polyethylene microfilter having a pore diameter of 0.10 μm, and then further filtered using a polyethylene microfilter having a pore diameter of 0.05 μm to prepare a composition for forming an organic underlayer film.

### [4] Solvent Resistance and Developer Solubility Test

Each of the compositions prepared in Examples 1 to 11 and Comparative Example 1 was applied onto a respective silicon wafer using a spinner. Each coated silicon wafer was heated on a hotplate at 215° C. for 1 minute to form a Si-containing resist underlayer film, and the thickness of the resulting underlayer film was measured. The film thickness was approximately 20 nm.

Subsequently, a mixed solvent (7/3 (V/V)) of propylene glycol monomethyl ether/propylene glycol monomethylether acetate was applied onto each Si-containing resist underlayer film, and then spin-dried. The film thickness of the underlayer film after application was measured, and the percentage (%) of change in the film thickness after application of the mixed solvent was calculated using the film thickness before application of the mixed solvent as a reference (100%). A film thickness change of 1% or less between before and after application of the mixed solvent was evaluated as “good”, and a film thickness change greater than 1% was evaluated as “uncured”.

In addition, an alkaline developer (2.38% aqueous solution of tetramethylammonium hydroxide (TMAH)) was applied to each Si-containing resist underlayer film formed on the silicon wafer by the same method, and then spin-dried, the thickness of the underlayer film after application was measured, and the percentage (%) of change in the film thickness after application of the developer was calculated using the thickness before application of the developer as a reference (100%). A film thickness change of 1% or less between before and after the application of the developer was evaluated as “good”, and a film thickness change of greater than 1% was evaluated as “uncured”.

The results obtained are presented in Table 2.

TABLE 2

| | Solvent | Developer |
|---|---|---|
| | Resistance | Resistance |
| Example 1 | Good | Good |
| Example 2 | Good | Good |
| Example 3 | Good | Good |
| Example 4 | Good | Good |
| Example 5 | Good | Good |
| Example 6 | Good | Good |
| Example 7 | Good | Good |
| Example 8 | Good | Good |
| Example 9 | Good | Good |
| Example 10 | Good | Good |
| Example 11 | Good | Good |
| Comparative | Good | Good |
| Example 1 | | |

### [5] Measurement of Optical Absorption Coefficient in Wavelength Range of 220 to 300 Nm

Each of the compositions prepared in Examples 1 to 11 and Comparative Example 1 was applied onto a respective silicon wafer using a spinner. Each coated silicon wafer was then heated on a hotplate at 215° C. for 1 minute to form a Si-containing resist underlayer film having a film thickness of approximately 20 nm. The optical absorption coefficient (k value, also referred to as the attenuation coefficient) of each of these resist underlayer films at wavelengths from 220 nm to 300 nm was measured using a spectroscopic ellipsometer (VUV-VASE VU-302 available from the J.A. Woollam Company). The highest k value in the wavelength range from 220 nm to 300 nm is presented in Table 3.

TABLE 3

| | Optical Absorption Coefficient |
|---|---|
| | (Maximum value in range from |
| | 220 nm to 300 nm) |
| Example 1 | 0.05 |
| Example 2 | 0.05 |
| Example 3 | 0.05 |
| Example 4 | 0.05 |
| Example 5 | 0.05 |
| Example 6 | 0.05 |
| Example 7 | 0.05 |
| Example 8 | 0.06 |
| Example 9 | 0.07 |
| Example 10 | 0.07 |
| Example 11 | 0.17 |
| Comparative | 0 |
| Example 1 | |

### [6] Formation of Resist Pattern by EUV Exposure: Line and Space Patterning Through Positive Alkaline Development

The composition for forming the organic underlayer film was spin-coated on a silicon wafer and heated on a hotplate at 215° C. for 1 minute to form an organic underlayer film (layer A) (film thickness: 90 nm).

The composition produced in Example 1 was spin-coated thereon and heated on a hotplate at 215° C. for 1 minute to form a resist underlayer film (layer B) (20 nm).

Furthermore, an EUV resist solution (methacrylate resin-based resist) was spin coated thereon and heated at 110° C. for 1 minute to form an EUV resist film (layer C), which was subsequently subjected to exposure using an EUV lithography device (NXE 3400) available from ASML under the conditions including NA=0.33, σ=0.63/0.84, and a dipole.

After the exposure, post-exposure baking (PEB, 105° C. for 1 minute) was implemented, and the resulting product was cooled to room temperature on a cooling plate. Then, development was carried out using a 2.38% TMAH developer for 30 seconds, and rinsing was performed, resulting in a resist pattern.

By the same procedure, resist patterns were formed using each of the compositions produced in Examples 2 to 11 and Comparative Example 1.

Then, each of the resulting patterns was evaluated for whether a 14 nm line pattern with a 32 nm pitch can be formed by observing cross-sections of the patterns to confirm the pattern shape.

During the observation of the pattern shape, a state in which the shape was found to be between “footing” and “undercut” and no significant residue was found in the space portion was evaluated as “good”, and an unfavorable state in which the resist pattern collapsed was evaluated as “collapsed”. The obtained results are presented in Table 4.

TABLE 4

| | Pattern Shape |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Example 11 | Good |
| Comparative | Collapsed |
| Example 1 | |

1. A silicon-containing resist underlayer film having a maximum optical absorption coefficient (k value) in a wavelength range from 220 nm to 300 nm of 0.05 or greater.

2. The silicon-containing resist underlayer film according to claim 1, comprising at least one of a nitrophenyl group, a methoxyphenyl sulfonyl group, or a phenanthryl group.

3. The silicon-containing resist underlayer film according to claim 1, wherein the silicon-containing resist underlayer film is a resist underlayer film for use in extreme ultraviolet (EUV) lithography.

4. A silicon-containing resist underlayer film-forming composition comprising:
a polysiloxane as a component [A]; and
a solvent as a component [C];
the polysiloxane comprising a constituent unit derived from a hydrolyzable silane (A) having at least one of a nitrophenyl group, a methoxyphenyl sulfonyl group, or a phenanthryl group.

5. A silicon-containing resist underlayer film-forming composition comprising:
a polysiloxane as a component [A′];
a hydrolyzable silane (A) as a component [B], the hydrolyzable silane (A) having at least one of a nitrophenyl group, a methoxyphenyl sulfonyl group, or a phenanthryl group; and
a solvent as a component [C].

6. The silicon-containing resist underlayer film-forming composition according to claim 4, wherein the hydrolyzable silane (A) is a compound represented by Formula (A-1): 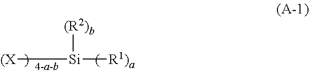
where
a represents an integer from 1 to 3;
b represents an integer from 0 to 2;
a+b represents an integer from 1 to 3;
R¹ represents a group having at least one of a nitrophenyl group, a methoxyphenyl sulfonyl group, or a phenanthryl group, and R¹ may have an ionic bond;
R² represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group (with the proviso that a methoxyphenyl sulfonyl group is excluded), or an organic group having a cyano group, or a combination of two or more thereof;
X represents an alkoxy group, an aralkyloxy group, an acyloxy group, or a halogen atom; and
when a plurality of R¹ is present, the plurality of R¹ may be the same or different,
when a plurality of R² is present, the plurality of R² may be the same or different, and
when a plurality of X is present, the plurality of X may be the same or different.

7. The silicon-containing resist underlayer film-forming composition according to claim 6, wherein R¹ in the Formula (A-1) is represented by Formula (A-2a), Formula (A-2b), or Formula (A-2c): 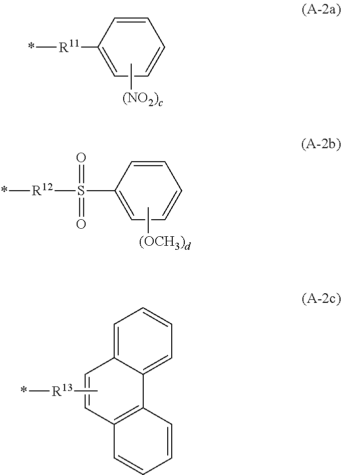
where,
in Formula (A-2a),
R¹¹ represents a single bond or a divalent organic group that may have an ionic bond, and c represents an integer from 1 to 5;
in Formula (A-2b),
R¹² represents a divalent organic group that may have an ionic bond, and d represents an integer from 1 to 5; and
in Formula (A-2c),
R¹³ represents a single bond or a divalent organic group that may have an ionic bond; and
* represents a bond.

8. The silicon-containing resist underlayer film-forming composition according to claim 4, wherein the polysiloxane that is the component [A] is a polysiloxane modified product in which some of silanol groups are alcohol-modified or acetal-protected.

9. The silicon-containing resist underlayer film-forming composition according to claim 5, wherein the polysiloxane that is the component [A′] is a polysiloxane modified product in which some of silanol groups are alcohol-modified or acetal-protected.

10. The silicon-containing resist underlayer film-forming composition according to claim 4, wherein the component [C] comprises an alcohol-based solvent.

11. The silicon-containing resist underlayer film-forming composition according to claim 10, wherein the component [C] comprises a propylene glycol monoalkyl ether.

12. The silicon-containing resist underlayer film-forming composition according to claim 4, further comprising a curing catalyst as a component [D].

13. The silicon-containing resist underlayer film-forming composition according to claim 4, further comprising nitric acid as a component [E].

14. The silicon-containing resist underlayer film-forming composition according to claim 4, wherein the component [C] contains water.

15. The silicon-containing resist underlayer film-forming composition according to claim 4, wherein the composition is for forming a resist underlayer film for use in extreme ultraviolet (EUV) lithography.

16. A silicon-containing resist underlayer film comprising a cured product of the silicon-containing resist underlayer film-forming composition described in claim 4.

17. A semiconductor processing substrate comprising:
a semiconductor substrate; and
the silicon-containing resist underlayer film described in claim 1.

18. A semiconductor processing substrate comprising:
a semiconductor substrate; and
the silicon-containing resist underlayer film described in claim 16.

19. A method for manufacturing a semiconductor element, the method comprising:
forming an organic underlayer film on a substrate;
forming a resist underlayer film on the organic underlayer film using the silicon-containing resist underlayer film-forming composition described in claim 4; and
forming a resist film on the resist underlayer film.

20. The method for manufacturing a semiconductor element according to claim 19, wherein the resist film is formed from a resist for EUV lithography.

21. The method for manufacturing a semiconductor element according to claim 19, wherein in the forming of the resist underlayer film, a silicon-containing resist underlayer film-forming composition that has been filtered through a nylon filter is used.

22. A pattern forming method comprising:
forming an organic underlayer film on a semiconductor substrate;
applying the silicon-containing resist underlayer film-forming composition described in claim 4 onto the organic underlayer film and baking the silicon-containing resist underlayer film-forming composition applied thereon to form a resist underlayer film;
applying a resist film-forming composition onto the resist underlayer film to form a resist film;
exposing and developing the resist film to form a resist pattern;
etching the resist underlayer film using the resist pattern as a mask; and
etching the organic underlayer film using the patterned resist underlayer film as a mask.

23. The pattern forming method according to claim 22, further comprising:
removing the resist underlayer film by a wet method using a chemical liquid after the etching the organic underlayer film.

24. The pattern forming method according to claim 22, wherein the resist film is formed from a resist for EUV lithography.

25. The silicon-containing resist underlayer film-forming composition according to claim 5, wherein the hydrolyzable silane (A) is a compound represented by Formula (A-1): 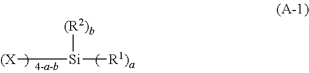
where
a represents an integer from 1 to 3;
b represents an integer from 0 to 2;
a+b represents an integer from 1 to 3;
R¹ represents a group having at least one of a nitrophenyl group, a methoxyphenyl sulfonyl group, or a phenanthryl group, and R¹ may have an ionic bond;
R² represents an optionally substituted alkyl group, an optionally substituted aryl group (with the proviso that a phenanthryl group is excluded), an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, an organic group having an alkoxy group, an organic group having a sulfonyl group (with the proviso that a methoxyphenyl sulfonyl group is excluded), or an organic group having a cyano group, or a combination of two or more thereof;
X represents an alkoxy group, an aralkyloxy group, an acyloxy group, or a halogen atom; and
when a plurality of R¹ is present, the plurality of R¹ may be the same or different,
when a plurality of R² is present, the plurality of R² may be the same or different, and
when a plurality of X is present, the plurality of X may be the same or different.

26. The silicon-containing resist underlayer film-forming composition according to claim 25, wherein R¹ in the Formula (A-1) is represented by Formula (A-2a), Formula (A-2b), or Formula (A-2c): 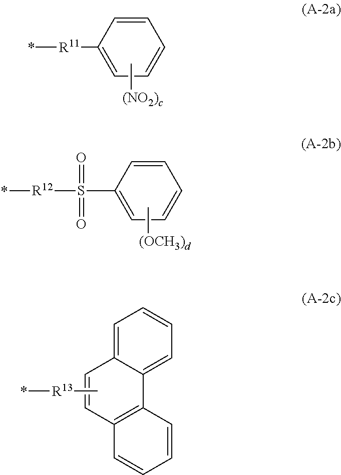
where,
in Formula (A-2a),
R¹¹ represents a single bond or a divalent organic group that may have an ionic bond, and c represents an integer from 1 to 5;
in Formula (A-2b),
R¹² represents a divalent organic group that may have an ionic bond, and d represents an integer from 1 to 5; and
in Formula (A-2c),
R¹³ represents a single bond or a divalent organic group that may have an ionic bond; and
* represents a bond.

27. A silicon-containing resist underlayer film comprising a cured product of the silicon-containing resist underlayer film-forming composition described in claim 5.

28. A method for manufacturing a semiconductor element, the method comprising:
forming an organic underlayer film on a substrate;
forming a resist underlayer film on the organic underlayer film using the silicon-containing resist underlayer film-forming composition described in claim 5; and
forming a resist film on the resist underlayer film.

29. A pattern forming method comprising:
forming an organic underlayer film on a semiconductor substrate;
applying the silicon-containing resist underlayer film-forming composition described in claim 5 onto the organic underlayer film and baking the silicon-containing resist underlayer film-forming composition applied thereon to form a resist underlayer film;
applying a resist film-forming composition onto the resist underlayer film to form a resist film;
exposing and developing the resist film to form a resist pattern;
etching the resist underlayer film using the resist pattern as a mask; and
etching the organic underlayer film using the patterned resist underlayer film as a mask.
